(19) United States
(12) Patent Application Publication
(10) Pub. No.: US 2024/0260415 A1
(43) Pub. Date: Aug. 1, 2024

(54) ORGANIC LIGHT EMITTING DISPLAY APPARATUS

(71) Applicant: LG Display Co., Ltd., Seoul (KR)

(72) Inventor: JiYoung AHN, Paju-si (KR)

(73) Assignee: LG Display Co., Ltd., Seoul (KR)

(21) Appl. No.: 18/399,107

(22) Filed: Dec. 28, 2023

(30) Foreign Application Priority Data
Jan. 30, 2023 (KR) 10-2023-0012108

(51) Int. Cl. H10K 59/80; H10K 59/38

(52) U.S. Cl. CPC H10K 59/878; H10K 59/38; H10K 59/873

(57) ABSTRACT

An organic light emitting display apparatus includes a plurality of pixels each including a plurality of color subpixels and a white subpixel, where each pixel includes an emission area disposed on a substrate. The display apparatus further includes a planarization layer including a light extraction pattern which is at the emission area of each of the plurality of color subpixels and the white subpixel and includes a plurality of concave portions and a convex portion, a light emitting device layer on the light extraction pattern, a color filter layer disposed between the substrate and the light extraction pattern to overlap the emission area of each of the plurality of color subpixels, and a light separation portion disposed between the substrate and the light extraction pattern to overlap the emission area of each of the plurality of color subpixels.

### CROSS-REFERENCE TO RELATED APPLICATIONS

This application claims priority to Korean Patent Application No. 10-2023-0012108 filed in the Republic of Korea on Jan. 30, 2023, the entire contents of which is hereby expressly incorporated by reference into the present application.

### BACKGROUND

### Technical Field

The present disclosure relates to an organic light emitting display apparatus.

### Discussion of the Related Art

An organic light emitting display apparatus has a high response speed and has low power consumption. Unlike a liquid crystal display device, the organic light emitting display apparatus is a self-emissive display apparatus and does not require a separate light source. Thus, there is no problem in the viewing angle, whereby the organic light emitting display apparatus is subject to a next generation flat panel display apparatus.

The organic light emitting display apparatus displays an image through light emission of an organic light emitting layer including an emission layer interposed between two electrodes.

However, since some of the light emitted from the organic emission layer is not emitted to the outside due to total reflection or the like at the interface between the organic light emitting layer and the electrode and/or total reflection at the interface between the substrate and the air layer, the light extraction efficiency can reduced. Accordingly, in the organic light emitting display apparatus, research for improving brightness that can be reduced due to low light extraction efficiency and for reducing power consumption is pursued.

### SUMMARY OF THE DISCLOSURE

Accordingly, the present disclosure is directed to providing an organic light emitting display apparatus that substantially obviates one or more problems due to limitations and disadvantages of the related art.

An aspect of the present disclosure is to providing an organic light emitting display apparatus that can enhance light extraction efficiency of light that is emitted from an emission layer.

Another aspect of the present disclosure is to providing an organic light emitting display apparatus in which a black visibility characteristic or a black color (or black rising) phenomenon that can be caused by the reflection of external light can be reduced and the occurrence of rainbow Mura and circular ring Mura can be minimized or reduced.

The objects of the present disclosure are not limited to the aforesaid, but other objects not described herein will be clearly understood by those skilled in the art from descriptions below.

To achieve these and other aspects of the inventive concepts of the present disclosure, as embodied and broadly described herein, in one or more aspects, an organic light emitting display apparatus comprises a plurality of pixels each including a plurality of color subpixels and a white subpixel each including an emission area on a substrate, a planarization layer including a light extraction pattern which is at the emission area of each of the plurality of color subpixels and the white subpixel and includes a plurality of concave portions and a convex portion, a light emitting device layer on the light extraction pattern, a color filter layer between the substrate and the light extraction pattern to overlap the emission area of each of the plurality of color subpixels, and a light separation portion between the substrate and the light extraction pattern to overlap the emission area of each of the plurality of color subpixels, the color filter layer comprises a first filter region and a second filter region having different thicknesses at the light separation portion.

Specific details according to various examples of the present specification other than the means for solving the above-mentioned limitations are included in the description and drawings below.

An organic light emitting display apparatus according to an embodiment of the present disclosure can enhance the light extraction efficiency of light emitted from an organic emission layer, and thus, can implement high efficiency and high luminance to extend a lifetime of the organic emission layer and can decrease power consumption, thereby implementing low power.

Moreover, in an organic light emitting display apparatus according to an embodiment of the present disclosure, a black visibility characteristic or a black color (or black rising) phenomenon that can be caused by the reflection of external light can be reduced, and the occurrence of rainbow Mura and circular ring Mura can be minimized or reduced, thereby implementing real black in a non-driving or off state.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with aspects of the disclosure.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure and together with the description serve to explain principles of the disclosure.

FIG. 1 is a diagram for describing an organic light emitting display apparatus according to an embodiment of the present disclosure.

FIG. 2 is a plan view illustrating a pixel according to an embodiment of the present disclosure.

FIG. 3 is a cross-sectional view illustrating a cross-sectional structure of one subpixel according to an embodiment of the present disclosure.

FIG. 4 is an enlarged view of a region ‘A’ illustrated in FIG. 2.

FIG. 5 is a diagram illustrating a light separation portion according to an embodiment of the present disclosure.

FIG. 6 is a cross-sectional view illustrating a light separation portion at a plurality of color subpixels illustrated in FIG. 5.

FIG. 7 is a diagram illustrating a light separation portion according to another embodiment of the present disclosure.

FIG. 8 is a cross-sectional view illustrating a cross-sectional structure of first, third, and fourth subpixels illustrated in FIG. 7.

FIG. 9 is a cross-sectional view illustrating a light separation portion at first to fourth subpixels illustrated in FIG. 7.

FIG. 10 is a cross-sectional view illustrating a light separation portion at first to fourth subpixels illustrated in FIG. 7.

FIG. 11 is a diagram illustrating a light separation portion according to another embodiment of the present disclosure.

FIG. 12 is a cross-sectional view taken along line I-I′ illustrating a light separation portion at each of first to fourth subpixels illustrated in FIG. 11.

FIG. 13 is a diagram illustrating a light separation portion according to another embodiment of the present disclosure.

FIG. 14 is a cross-sectional view illustrating a cross-sectional structure of first, third, and fourth subpixels illustrated in FIG. 13.

FIG. 15 is a cross-sectional view illustrating a cross-sectional structure of first to fourth subpixels illustrated in FIG. 13.

FIG. 16 is a diagram illustrating a light separation portion according to another embodiment of the present disclosure.

FIG. 17 is a cross-sectional view taken along line II-II′ illustrating a light separation portion at each of first to fourth subpixels illustrated in FIG. 16.

FIG. 18 is a diagram illustrating a light separation portion according to another embodiment of the present disclosure.

FIG. 19 is a cross-sectional view taken along line III-III′ illustrating a light separation portion at each of first to fourth subpixels illustrated in FIG. 18.

FIG. 20 is a diagram illustrating a light separation portion according to another embodiment of the present disclosure.

FIG. 21 is a diagram illustrating a light separation portion according to another embodiment of the present disclosure.

FIG. 22 is a diagram illustrating a light separation portion according to another embodiment of the present disclosure.

FIG. 23 is a diagram illustrating a light separation portion according to another embodiment of the present disclosure.

FIG. 24 is an enlarged view of a region ‘B’ illustrated in FIG. 23.

FIG. 25 is another enlarged view of a region ‘B’ illustrated in FIG. 23.

FIG. 26 is an enlarged view of a region ‘B’ illustrated in FIG. 23.

FIG. 27 is a diagram illustrating a light separation portion according to another embodiment of the present disclosure.

FIG. 28 is a diagram illustrating a light separation portion according to another embodiment of the present disclosure.

FIG. 29 is a diagram illustrating a light separation portion according to another embodiment of the present disclosure.

FIG. 30 is a diagram illustrating the enlargement of the subpixel illustrated in FIG. 29.

FIG. 31 is another diagram illustrating the enlargement of the subpixel illustrated in FIG. 29.

FIG. 32 is a plan view illustrating a pixel according to another embodiment of the present disclosure.

FIG. 33 is an enlarged view of a region ‘C’ illustrated in FIG. 32.

FIG. 34A is a diagram illustrating a rotation structure of a first light extraction pattern illustrated in FIG. 32.

FIG. 34B is a diagram illustrating a rotation structure of a second light extraction pattern illustrated in FIG. 32.

FIG. 34C is a diagram illustrating a rotation structure of a third light extraction pattern illustrated in FIG. 32.

FIG. 34D is a diagram illustrating a rotation structure of a fourth light extraction pattern illustrated in FIG. 32.

### DETAILED DESCRIPTION OF THE EMBODIMENTS

Advantages and features of the present disclosure, and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art. Furthermore, the present disclosure is only defined by the scopes of the appended claims.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known technology is determined to unnecessarily obscure the important point of the present disclosure, the detailed description will be omitted.

In a case where ‘comprise’, ‘have’, and ‘include’ described in the present disclosure are used, another part can be added unless ‘only-’ is used. The terms in a singular form can include plural forms unless noted to the contrary.

In construing an element, the element is construed as including an error range although there is no explicit description.

In describing a positional relationship, for example, when a position relation between two parts is described as ‘on’, ‘over’, ‘under’, and ‘next’, one or more other parts can be disposed between the two parts unless a more limiting term, such as “just” or “direct(ly)” is used.

Spatially relative terms, such as “below,” “beneath,” “lower,” “above,” “upper,” and the like, can be used to easily describe the relationship of one element or elements and another element or elements as illustrated in the drawings.

Spatially relative terms can be understood as terms including different directions of the device in use or operation, in addition to the direction illustrated in the drawings. For example, when the device in the drawings is turned over, elements described as “below” or “beneath” of other elements can be placed “above” of other elements. Thus, the exemplary term “below” or “beneath” can include both a downward direction and an upward direction.

It will be understood that, although the terms “first”, “second”, and the like can be used herein to describe various elements, these elements should not be limited by these terms. These terms are only used to distinguish one element from another and may not define any order or sequence. For example, a first element could be termed a second element, and, similarly, a second element could be termed a first element, without departing from the scope of the present disclosure.

In describing elements of the present disclosure, the terms “first”, “second”, “A”, “B”, “(a)”, “(b)”, etc. can be used. These terms are intended to identify the corresponding elements from the other elements, and basis, order, or number of the corresponding elements should not be limited by these terms. The expression that an element or a layer is “connected”, “coupled” or “adhered” to another element or layer means the element or layer can not only be directly connected or adhered to another element or layer, but also be indirectly connected or adhered to another element or layer with one or more intervening elements or layers “disposed” or “interposed” between the elements or layers, unless otherwise specified.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present disclosure can be partially or overall coupled to or combined with each other and can be variously inter-operated with each other and driven technically as those skilled in the art can sufficiently understand. The embodiments of the present disclosure can be carried out independently from each other or can be carried out together in a co-dependent relationship.

Hereinafter, embodiments of the present disclosure will be described in detail with reference to the accompanying drawings. For convenience of description, a scale of each of elements shown in the accompanying drawings differs from a real scale, and thus, is not limited to a scale shown in the drawings. All the components of each organic light emitting display apparatus according to all embodiments of the present disclosure are operatively coupled and configured.

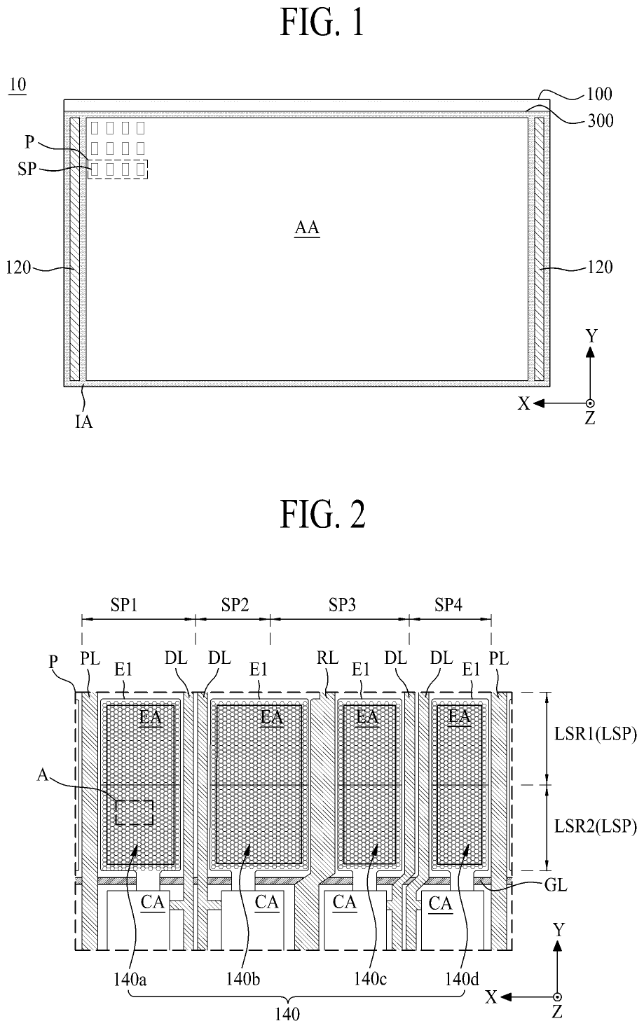

FIG. 1 is a diagram for describing an organic light emitting display apparatus according to an embodiment of the present disclosure.

Referring to FIG. 1, the organic light emitting display apparatus according to the embodiment of the present disclosure can comprise a display panel 10 including a substrate 100 and a counter substrate 300 bonded to each other.

The substrate 100 includes a thin film transistor, and the substrate 100 can be a transparent glass substrate or a transparent plastic substrate. The substrate 100 can include a display area AA and a non-display area (non-active or inactive area) IA.

The display area AA is an area for displaying an image. The display area AA can be a pixel array area, an active area, a pixel array portion, or a screen. The display area AA can include a plurality of pixels P.

The plurality of pixels P can be disposed along a first direction (e.g., X in FIG. 1) and a second direction (e.g., Y crossing the first direction X in FIG. 1). The plurality of pixels P can each be defined as a unit area from which light is actually emitted. Each of the plurality of pixels P can include a plurality of adjacent subpixels SP. For example, the first direction X can be a first lengthwise direction, a long-side lengthwise direction, a widthwise direction, or a first horizontal direction of the substrate 100. The second direction Y can be a second lengthwise direction, a short-side lengthwise direction, a lengthwise direction, a second horizontal direction, or a vertical direction of the substrate 100.

The non-display area IA is an area in which an image is not displayed. The non-display area IA can be a peripheral circuit area, a signal supply area, a non-active area, or a bezel area. The non-display area IA can be configured to surround the display area AA entirely or only in part. One or more non-display areas IA can be provided adjacent to the display area AA. The display panel 10 or substrate 100 can further include a peripheral circuit portion 120 disposed at the non-display area IA. The peripheral circuit portion 120 can include a gate driving circuit connected with a plurality of subpixels SP.

The counter substrate (or opposite substrate) 300 can be configured to overlap the display area AA. The counter substrate 300 can be disposed to be opposite-bonded to the substrate 100 by an adhesive member (or a transparent adhesive), or can be provided as a type where an organic material or an inorganic material is stacked on the substrate 100. The counter substrate 300 can be an upper substrate, a second substrate, or an encapsulation substrate and can encapsulate the substrate 100.

FIG. 2 is a plan view illustrating a pixel according to an embodiment of the present disclosure. FIG. 2 illustrates a plan structure of a pixel shown in FIG. 1.

Referring to FIGS. 1 and 2, in the organic light emitting display apparatus (or organic light emitting display panel) according to an embodiment of the present disclosure, each of the plurality of pixel P can include four subpixels SP1, SP2, SP3, and SP4.

Each of the plurality of pixel P according to an embodiment of the present disclosure can include first to fourth subpixels SP1, SP2, SP3, and SP4 adjacent to each other along the first direction X. For example, each of the plurality of pixels P can include a first subpixel SP1 of red, a second subpixel SP2 of white, a third subpixel SP3 of blue, and a fourth subpixel SP4 of green, but embodiments according to present disclosure are not limited thereto. Each of the first to fourth subpixels SP1, SP2, SP3, and SP4 can be configured to have different sizes (or areas) from each other. For example, each of the first to fourth subpixels SP1, SP2, SP3, and SP4 can include a plurality of color subpixels corresponding to the first, third, and fourth subpixels SP1, SP3, and SP4, and a white subpixel corresponding to the second subpixel SP2.

Each of the first to fourth subpixels SP1, SP2, SP3, and SP4 can include an emission area EA and a circuit area CA. The emission area EA can be disposed on one side (or an upper side) of the subpixel area. The emission area EA of each of the first to fourth subpixels SP1, SP2, SP3, and SP4 can have different sizes (or areas) from each other. For example, the emission area EA can be an opening region or a light emitting region.

The emission area EA of each of the first to fourth subpixels SP1, SP2, SP3, and SP4 can have different sizes (or areas) from each other along the first direction X. According to an embodiment of the present disclosure, the emission area EA of the second subpixel SP2 can have the largest size, the emission area EA of the fourth subpixel SP4 can have the smallest size, the emission area EA of the first subpixel SP1 can be a smaller than the emission area EA of the second subpixel SP2, and the emission area EA of the first subpixel SP1 can be a larger than the emission area EA of each of the third and fourth subpixels SP3 and SP4. Moreover, the emission area EA of the third subpixel SP3 can have a larger size than the emission area EA of the fourth subpixel SP4. However, embodiments according to present disclosure are not limited thereto.

The circuit area CA of each of the first to fourth subpixels SP1, SP2, SP3, and SP4 can be spatially separated from the emission area EA within the subpixel area. For example, the circuit area CA can be disposed at the other side (or a lower side) of the subpixel area, but embodiments according to present disclosure are not limited thereto. For example, at least a portion of the circuit area CA can overlap the emission area EA within the subpixel area. For example, the circuit area CA can overlap an entire emission area EA within the subpixel area or can be disposed below (or under) the emission area EA within the subpixel area. For example, the circuit area CA can be a non-emission area or a non-opening region.

Each of the plurality of pixel P according to another embodiment of the present disclosure can further include a light transmitting portion (or a transparent portion) disposed around at least one of the emission area EA and the circuit area CA of each of the first to fourth subpixels SP1, SP2, SP3, and SP4. For example, each of the plurality of pixel P can include an emission area for subpixel corresponding to each of the plurality of subpixels SP1, SP2, SP3, and SP4, and the light transmitting portion disposed around each of the plurality of subpixels SP1, SP2, SP3, and SP4, in this case, the organic light emitting display apparatus can implement a transparent light emitting display apparatus due to light transmission of the light transmitting portion.

According to an embodiment of the present disclosure, two data lines DL extending in parallel to each other along the second direction Y can be disposed between the first subpixel SP1 and the second subpixel SP2 and between the third subpixel SP3 and the fourth subpixel SP4, respectively. A gate line GL extending along the first direction X can be disposed between the emission area EA and the circuit area CA in each of the first to fourth subpixels SP1, SP2, SP3, and SP4. A pixel power line PL extending along the second direction Y can be disposed at one side of the first subpixel SP1 or the fourth subpixel SP4. A reference line RL extending along the second direction Y can be disposed between the second subpixel SP2 and the third subpixel SP3. The reference line RL can be used as a sensing line for externally sensing a variation in characteristics of a driving thin film transistor disposed in the circuit area CA of the pixel P and/or a variation in characteristics of a light emitting device layer disposed at the circuit area CA in a sensing driving mode of the pixel P.

Each of the first to fourth subpixels SP1, SP2, SP3, and SP4 of the plurality of pixel P according to an embodiment of the present disclosure can include a light extraction pattern 140.

The light extraction pattern 140 can be formed or configured to have a flexural (or concave-convex) shape. The light extraction pattern 140 can irradiate light, emitted from the emission area EA, toward a light output surface, and thus, can increase the light extraction efficiency of the light emitted from the emission area EA.

The light extraction pattern 140 can include first to fourth light extraction patterns 140a to 140d.

The first light extraction pattern 140a can be disposed or configured at the first subpixel SP1 of each of the plurality of pixels P. The second light extraction pattern 140b can be disposed or configured at the second subpixel SP2 of each of the plurality of pixels P. The third light extraction pattern 140c can be disposed or configured at the third subpixel SP3 of each of the plurality of pixels P. The fourth light extraction pattern 140d can be disposed or configured at the fourth subpixel SP4 of each of the plurality of pixels P.

Each of the first to fourth light extraction patterns 140a to 140d can be formed or configured to have a flexural (or concave-convex) shape. According to an embodiment of the present disclosure, the first to fourth light extraction patterns 140a to 140d can be configured to have a same size and a same shape. According to another embodiment of the present disclosure, one or more of the first to fourth light extraction patterns 140a to 140d can be configured to have different sizes and/or different shapes.

In a non-driving or off state of the organic light emitting display apparatus or the display panel 10, external light input from the outside to the light extraction pattern 140 can be doubly reflected by the light extraction pattern 140 and can be output to the outside through the light output surface. Reflected light occurring due to the light extraction pattern 140 can cause radial-shaped circular ring Mura (or circular ring smear pattern) and/or rainbow Mura (or rainbow smear pattern) which are/is spread in a radial shape while having rainbow color, due to a dispersion characteristic of light based on a diffraction characteristic. The reflected light occurring due to the light extraction pattern 140 can cause radial-shaped circular ring Mura and/or rainbow Mura which are/is spread in a radial shape, due to the multi-interference and/or constructive interference of light caused by a difference between wavelength-based refraction angles, causing a reduction in black visibility characteristic of the organic light emitting display apparatus or the display panel 10.

According to an embodiment of the present disclosure, when the regularity of reflection light reflected from the light extraction patterns 140 of each of the plurality of pixels P is high, a probability of the occurrence of constructive interference (or light interference) occurring between reflection lights can be relatively high. Accordingly, a diffraction pattern (or diffraction pattern distribution) can occur due to the constructive interference of reflection lights. On the other hand, when the reflection light reflected from the light extraction pattern 140 of each of the plurality of pixels P is low in regularity or does not have regularity, a probability of the occurrence of constructive interference occurring between reflected lights can decrease or a probability of the occurrence of destructive interference can increase due to the irregularity of the reflection light, and thus, can prevent or minimize the occurrence of radial-shaped rainbow Mura and/or radial-shaped circular ring Mura which are/is spread in a radial shape, due to the constructive interference of reflected light.

According to an embodiment of the present disclosure, one or more of the first to fourth subpixels SP1 to SP4 can include a light separation portion LSP which changes an amplitude and/or a phase of reflection light reflected from the light extraction pattern 140 to decrease or minimize the regularity of the reflection light. For example, the light separation portion LSP can be a phase grating, a phase grating pattern, an amplitude grating, an amplitude/phase grating, an amplitude grating pattern, an amplitude/phase grating pattern, a multi-domain, or a subdomain.

The light separation portion LSP according to an embodiment of the present disclosure can be configured at each of the plurality of color subpixels SP1, SP3, and SP4 configured at each of the plurality of pixels P. For example, the light separation portion LSP can be configured between the substrate 100 and the light extraction pattern 140 to overlap an emission area EA of each of a plurality of subpixels SP1, SP3, and SP4 provided in each of the plurality of pixels P. For example, the light separation portion LSP can be configured between the substrate 100 and the light extraction pattern 140 to overlap an emission area EA of each of the first, third, and fourth subpixels SP1, SP3, and SP4 configured at each of the plurality of pixels P.

The organic light emitting display apparatus or the light separation portion LSP according to an embodiment of the present disclosure can include a plurality of light separation regions LSR1 and LSR2 configured at each of the first, third, and fourth subpixels SP1, SP3, and SP4 of each of the plurality of pixels P. For example, the light separation portion LSP of each of the first, third, and fourth subpixels SP1, SP3, and SP4 of each of the plurality of pixels P can include a plurality of light separation regions LSR1 and LSR2 provided between the light extraction pattern 140 and the substrate 100. For example, the light separation portion LSP or the emission area EA of each of the first, third, and fourth subpixels SP1, SP3, and SP4 configured at each of the plurality of pixels P can include the plurality of light separation regions LSR1 and LSR2 provided between the light extraction pattern 140 and the substrate 100. For example, the plurality of light separation regions LSR1 and LSR2 can be disposed along one direction of a first direction X, a second direction Y intersecting with the first direction X, and a diagonal direction between the first direction X and the second direction Y, within the emission area EA of corresponding subpixels SP1, SP3, and SP4. For example, the plurality of light separation regions LSR1 and LSR2 can be alternately disposed along one direction of a first direction X, a second direction Y intersecting with the first direction X, and a diagonal direction between the first direction X and the second direction Y, within the emission area EA of corresponding subpixels SP1, SP3, and SP4.

The organic light emitting display apparatus or the light separation portion LSP according to an embodiment of the present disclosure can include a first light separation region LSR1 and a second light separation region LSR2 configured at each of the first, third, and fourth subpixels SP1, SP3, and SP4 of each of the plurality of pixels P. For example, the light separation portion LSP of each of the first, third, and fourth subpixels SP1, SP3, and SP4 of each of the plurality of pixels P can include the first light separation region LSR1 and the second light separation region LSR2 configured between the light extraction pattern 140 and the substrate 100. For example, the light separation portion LSP or the emission area EA of each of the first, third, and fourth subpixels SP1, SP3, and SP4 configured at each of the plurality of pixels P can include the first light separation region LSR1 and the second light separation region LSR2, which are configured between the light extraction pattern 140 and the substrate 100.

The first light separation region LSR1 and the second light separation region LSR2 can be separated or spatially separated from each other within the emission area EA of corresponding subpixels SP1, SP3, and SP4. The first light separation region LSR1 and the second light separation region LSR2 can be disposed along one direction of the first direction X, the second direction Y intersecting with the first direction X, and the diagonal direction between the first direction X and the second direction Y, within the emission area EA of corresponding subpixels SP1, SP3, and SP4. For example, the first light separation region LSR1 and the second light separation region LSR2 can be disposed along the second direction Y. For example, the first light separation region LSR1 and the second light separation region LSR2 can include first and second division regions of a subpixel spatially divided along the second direction Y.

According to an embodiment of the present disclosure, the plurality of light separation regions LSR1 and LSR2 or the first light separation region LSR1 and the second light separation region LSR2 can be configured to change one or more of a phase, an amplitude, and a light path of reflection light reflected from the light extraction pattern 140. Therefore, the plurality of light separation regions LSR1 and LSR2 or the first light separation region LSR1 and the second light separation region LSR2 can decrease or minimize the regularity of the reflection light reflected from the light extraction pattern 140 to increase the randomness of the reflection light, and thus, can reduce a probability of occurrence of constructive interference (or light interference) occurring between reflection lights or can increase a probability of occurrence of destructive interference.

Therefore, the irregularity or randomness of a diffraction pattern of reflection light reflected from the light extraction pattern 140 can increase based on the plurality of light separation regions LSR1 and LSR2 or the first light separation region LSR1 and the second light separation region LSR2, and thus, the occurrence of rainbow Mura where reflection light is spread in a radial shape and/or circular ring Mura where reflection light is spread in a radial shape can be prevented or minimized based on the diffraction characteristic of the reflection light reflected from the light extraction pattern 140 at the display area AA. For example, a black visibility characteristic or a black color (or black rising) phenomenon caused by the reflection of external light can be reduced in a non-driving or off state of the organic light emitting display apparatus or the display panel 10, thereby implementing real black (or true black).

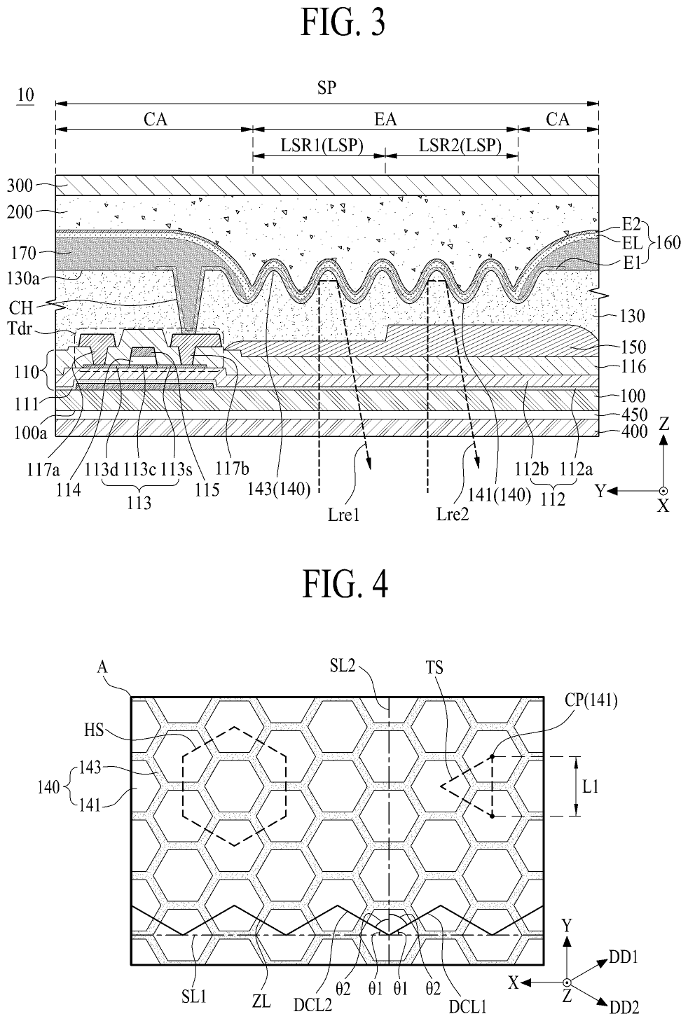

FIG. 3 is a cross-sectional view illustrating a cross-sectional structure of one subpixel according to an embodiment of the present disclosure.

Referring to FIGS. 2 and 3, the organic light emitting display apparatus or display panel 10 according to an embodiment of the present disclosure can comprise a substrate 100.

The substrate 100 includes a thin film transistor, and the substrate 100 can be a first substrate, a base substrate, a lower substrate, a transparent glass substrate, a transparent plastic substrate, or a base member.

The display panel 10 or the substrate 100 can include a pixel circuit layer 110, a planarization layer 130, and a light emitting device layer 160. The pixel circuit layer 110 can include a buffer layer 112 and a pixel circuit.

The buffer layer 112 can be disposed at an entirety of a first surface (or a front surface) of the substrate 100. The buffer layer 112 can be an insulating layer, an insulating material layer, or an inorganic insulating layer. The buffer layer 112 can prevent or at least reduce materials contained in the substrate 100 from spreading to a transistor layer during a high-temperature process in the manufacturing of the thin film transistor, or can prevent external water or moisture from permeating into the light emitting device layer 160.

The buffer layer 112 according to an embodiment of the present disclosure can include a first buffer layer 112a and a second buffer layer 112b. For example, the buffer layer 112 can include the first buffer layer 112a and the second buffer layer 112b, which have different refractive indexes and/or dielectric constants. For example, the buffer layer 112 can include the first buffer layer 112a and the second buffer layer 112b each having a refractive index difference of 0.1 or more.

The first buffer layer 112a can be disposed at all a first surface (or a front surface) of the substrate 100. For example, the first buffer layer 112a can be disposed to cover the first surface of the substrate 100. For example, the first buffer layer 112a can be configured with an insulating material having a first refractive index. For example, the first buffer layer 112a can be a first insulating layer, a lower insulating layer, a first inorganic layer, a first inorganic insulating layer, or a lower inorganic layer. For example, the first buffer layer 112a can be configured as any one material of silicon oxide (SiOx), silicon nitride (SiNx), silicon oxynitride (SiONx), and titanium oxide (TiOx), but embodiments according to present disclosure are not limited thereto. For example, the first buffer layer 112a can be configured as the silicon nitride (SiNx), but embodiments according to present disclosure are not limited thereto.

The second buffer layer 112b can be stacked on the first buffer layer 112a. For example, the second buffer layer 112b can be disposed on (or over) the first surface of the substrate 100 to cover the first buffer layer 112a. The second buffer layer 112b can be configured as a material which differs from that of the first buffer layer 112a. For example, the first buffer layer 112a and the second buffer layer 112b can be configured to have different refractive indexes and/or dielectric constants. For example, the second buffer layer 112b can be configured as an insulating material having a second refractive index which differs from the first refractive index. For example, the second buffer layer 112b can be a second insulating layer, an upper insulating layer, a second inorganic layer, a second inorganic insulating layer, or an upper inorganic layer. For example, the second buffer layer 112b can be configured as any one material of silicon oxide (SiOx), silicon nitride (SiNx), silicon oxynitride (SiONx), and titanium oxide (TiOx), but embodiments according to present disclosure are not limited thereto. For example, the second buffer layer 112b can be configured as the silicon oxide (SiOx), but embodiments according to present disclosure are not limited thereto.

The pixel circuit can include a driving thin film transistor Tdr disposed at a circuit area CA of each subpixel SP. The driving thin film transistor Tdr can include an active layer 113, a gate insulating layer 114, a gate electrode 115, a passivation layer 116, a drain electrode 117a, and a source electrode 117b.

The active layer 113 can be disposed on (or over) the buffer layer 112. The active layer 113 can be configured with a semiconductor material based on any one of amorphous silicon, polycrystalline silicon, oxide, and organic materials. The active layer 113 can include a channel region 113c, a drain region 113d, and a source region 113s.

The gate insulating layer 114 can be formed at an island shape on (or over) the channel region 113c of the active layer 113, or can be formed on (or over) the entire front surface of the buffer layer 112 or substrate 100 including the active layer 113.

The gate electrode 115 can be disposed on (or over) the gate insulating layer 114 to overlap the channel region 113c of the active layer 113.

The passivation layer 116 can be formed on (or over) the gate electrode 115, and the drain region 113d and the source region 113s of the active layer 113. The passivation layer 116 can be formed at an entire front surface of the buffer layer 112. The passivation layer 116 can be formed at an entire front surface of the second buffer layer 112b. For example, the passivation layer 116 can be configured with an inorganic material. For example, the passivation layer 116 can be an interlayer insulating layer.

The drain electrode 117a can be disposed on (or over) the passivation layer 116 to be electrically connected to the drain region 113d of the active layer 113. The source electrode 117b can be disposed on (or over) the passivation layer 116 to be electrically connected to the source region 113s of the active layer 113.

The pixel circuit can further include at least one capacitor and at least one switching thin film transistors which are disposed at the circuit area CA together with the driving thin film transistor Tdr.

The organic light emitting display apparatus according to an embodiment of the present disclosure can further include a light shielding layer 111 provided below (or under) at least one active layer 113 of the driving thin film transistor Tdr, a first switching thin film transistor, and a second switching thin film transistor. The light shielding layer 111 can be configured to reduce or prevent a change in a threshold voltage of the thin film transistor caused by external light.

The planarization layer 130 can be provided over the pixel circuit layer 110. The planarization layer 130 can be formed at the entire display area AA and the remaining portions of the non-display area IA except the pad area. For example, the planarization layer 130 can include an extension portion (or expansion portion) extended or expanded from the display area AA to the remaining portions of the non-display area IA except the pad area. Accordingly, the planarization layer 130 can have a relatively large size than the display area AA.

The planarization layer 130 according to an embodiment of the present disclosure can be formed to have a relatively large thickness so that the planarization layer 130 can provide a planarized surface 130a over the pixel circuit layer 110. For example, the planarization layer 130 can be formed of an organic material such as one of photo acrylic, benzocyclobutene, polyimide, and fluorine resin, or the like.

The planarization layer 130 can include a light extraction pattern 140 disposed at each subpixel SP. The light extraction pattern 140 can be formed at the planarization layer 130 to overlap the emission area EA of each subpixel SP.

The light extraction pattern 140 can be formed at the planarization layer 170 to have a curved portion (or non-flat portion). The light extraction pattern 140 can be formed at the planarization layer 130 to have a curved shape (or an uneven shape). The light extraction pattern 140 can have a size larger than the emission area EA. For example, the light extraction pattern 140 can be a light extraction pattern, a light extraction pattern portion, a curved pattern portion, an uneven pattern portion, a micro lens, or a light scattering portion.

The light extraction pattern 140 or the first to fourth light extraction patterns 140a, 140b, 140c, and 140d according to an embodiment of the present disclosure can include a plurality of concave portions 141, and a convex portion 143 disposed around each of the plurality of concave portions 141.

Each of the plurality of concave portions 141 can be implemented to be concave from the upper surface (or a flat surface) 130a of the planarization layer 130. The plurality of concave portions 141 can have a same height with respect to the upper surface 130a of the planarization layer 130, but some of the plurality of concave portions 141 can have different depths. For example, a bottom surface of each of the plurality of concave portions 141 can be positioned between the upper surface 130a of the planarization layer 130 and the substrate 100.

The convex portion 143 can be formed to be connected between the plurality of concave portions 141. The convex portion 143 can be provided at the planarization layer 130 that overlaps the emission area EA to have a shape that can maximize an external extraction efficiency of light generated from the subpixel SP based on an effective emission area of the light emitting device layer 160. The convex portion 143 can change a propagation path of light emitted from the light emitting device layer 160 toward the light extraction surface 100a and extracts the light totally reflected within the light emitting device layer 160 toward the light extraction surface 100a, and thus, degradation of the light extraction efficiency caused by the light which is trapped within the light emitting device layer 160 can prevent or minimize.

A top portion of the convex portion 143 according to an embodiment of the present disclosure can be adjacent to the light emitting device layer 160 and can have a sharp structure and a convex curved shape, so as to increase the light extraction efficiency. For example, the top portion of the convex portion 143 can include a dome or bell structure having a convex cross-sectional shape.

The convex portion 143 according to an embodiment of the present disclosure can include an inclined portion having a curved shape between a bottom portion and the top portion (or peak portion). The inclined portion of the convex portion 143 can form or configure the concave portion 141. For example, the inclined portion of the convex portion 143 can be an inclined surface or a curved portion. The inclined portion of the convex portion 143 according to an embodiment of the present disclosure can have a cross-sectional structure having Gaussian curve. In this case, the inclined portion of the convex portion 143 can have a tangent slope which increases progressively from the bottom portion to the top portion, and then decreases progressively.

The light emitting device layer 160 can be disposed on (or over) the light extraction pattern 140 overlapping the emission area EA of each subpixel SP. For example, the light emitting device layer 160 can directly contact a surface of the light extraction pattern 140.

The light emitting device layer 160 according to an embodiment of the present disclosure can include a first electrode E1, an emission layer EL, and a second electrode E2. For example, the first electrode E1, the emission layer EL, and the second electrode E2 can be configured to emit the light toward the substrate 100 according to a bottom emission type, but embodiments according to present disclosure are not limited thereto.

The first electrode E1 can be formed on (or over) the planarization layer 130, and can be electrically connected to a source electrode 117b (or a drain electrode 117a) of the driving thin film transistor Tdr. One end of the first electrode E1 which is close to the circuit area CA can be electrically connected to the source electrode 117b (or a drain electrode 117a) of the driving thin film transistor Tdr via an electrode contact hole CH provided at the planarization layer 130 and the passivation layer 116.

The first electrode E1 directly contacts the light extraction pattern 140 and thus, can have a shape conforming to the shape of the light extraction pattern 140. As the first electrode E1 is formed (or deposited) over the planarization layer 130 to have a relatively small thickness, the first electrode E1 can have a surface morphology conforming to a surface morphology of the light extraction pattern 140 including the convex portion 143 and the plurality of concave portions 141. For example, the first electrode E1 is formed in a conformal shape based on the surface shape (morphology) of the light extraction pattern 140 by a deposition process of a transparent conductive material, whereby the first electrode E1 can have a cross-sectional structure whose shape is a same as the light extraction pattern 140.

The emission layer EL can be formed on (or over) the first electrode E1 and can directly contact the first electrode E1. As the emission layer EL is formed (or deposited) on (or over) the first electrode E1 to have a relatively large thickness in comparison to the first electrode E1, the emission layer EL can have a surface morphology which is equal or different from the surface morphology in each of the plurality of concave portions 141 and the convex portion 143 or the surface morphology of the first electrode E1. According to an embodiment of the present disclosure, the emission layer EL is formed in a conformal shape based on the surface shape (morphology) of the first electrode E1, in this case, the emission layer EL can have a cross-sectional structure whose shape is a same as the first electrode E1. According to another embodiment of the present disclosure, the emission layer EL can be formed in a non-conformal shape which does not conform to the surface shape (or morphology) of the first electrode E1, in this case, the emission layer EL can have a cross-sectional structure whose shape can be different from the first electrode E1.

The emission layer EL according to an embodiment of the present disclosure has a thickness that gradually increases toward the bottom surface of the convex portion 143 or the concave portion 141. For example, the emission layer EL can have the thinnest thickness at the inclined surface (or curved surface) between the convex portion 143 and the concave portion 141, but embodiments according to present disclosure are not limited thereto.

The emission layer EL according to an embodiment of the present disclosure includes two or more organic light emitting layers to emit white light. As an example, the emission layer EL can include a first organic light emitting layer and a second organic light emitting layer to emit white light by mixing a first light and a second light.

The second electrode E2 can be formed on (or over) the emission layer EL and can directly contact the emission layer EL. The second electrode E2 can be formed (or deposited) on (or over) the emission layer EL to have a relatively thin thickness compared to the emission layer EL. The second electrode E2 can be formed (or deposited) on (or over) the emission layer EL to have a relatively thin thickness, and thus can have a surface morphology corresponding to the surface morphology of the emission layer EL. For example, the second electrode E2 can have a cross-sectional structure whose shape can be equal or different from the light extraction pattern 140.

The second electrode E2 according to an embodiment of the present disclosure can include a metal material having a high reflectance to reflect the incident light emitted from the emission layer EL toward the substrate 100. For example, the second electrode E2 can include a single-layered structure or multi-layered structure of any one material selected from aluminum (Al), argentums (Ag), molybdenum (Mo), aurum (Au), magnesium (Mg), calcium (Ca), or barium (Ba), or alloy of two or more materials selected from aluminum (Al), argentums (Ag), molybdenum (Mo), aurum (Au), magnesium (Mg), calcium (Ca), or barium (Ba). The second electrode E2 can be a cathode electrode.

The traveling path of the light generated from the emission layer EL can change toward the light extraction surface (or a light emitting surface) 110a by the concave portion 141 and/or the convex portion 143 of the light extraction pattern 140, to thereby increase the external extraction efficiency of the light emitted from the emission layer EL.

The organic light emitting display apparatus or the display panel 10 according to an embodiment of the present disclosure can further include a bank layer 170. The bank layer 170 can be disposed on (or over) the planarization layer 130 and an edge portion of the first electrode E1. The bank layer 170 can be configured in a transparent material or an opaque material. For example, the bank layer 170 can be a transparent bank layer or a black bank layer. For example, the bank layer 170 can include a photosensitizer including a black pigment, in this case, the bank layer 170 can function as a light blocking member between adjacent subpixels SP.

The organic light emitting display apparatus or the display panel 10 according to an embodiment of the present disclosure can further include a color filter layer 150.

The color filter layer 150 can be disposed between the substrate 100 and the light extraction pattern 140. The color filter layer 150 can be disposed between the substrate 100 and the light extraction pattern 140 to overlap at least one emission area EA. The color filter layer 150 according to an embodiment of the present disclosure can be disposed between the passivation layer 116 and the planarization layer 130 to overlap with the emission area EA. The color filter layer 150 according to another embodiment of the present disclosure can be disposed between the substrate 100 and the passivation layer 116.

The color filter layer 150 can have a size which is greater wider than the emission area EA. The color filter layer 150 can have a size which is greater than the emission area EA and smaller than the light extraction pattern 140 of the planarization layer 130, but embodiments according to present disclosure are not necessarily limited to thereto, and the color filter layer 150 can have a size which is greater than the light extraction pattern 140 of the planarization layer 130. For example, an edge portion of the color filter layer 150 can overlap the bank layer 170. For example, the color filter layer 150 can have a size which is greater than a size corresponding to an entire area of each subpixel SP, thereby reducing light leakage between adjacent subpixels SP.

The color filter layer 150 can be configured to transmit only the wavelength of a color set in the subpixel SP. For example, when one pixel P is configured with the first to fourth subpixels SP1, SP2, SP3, and SP4, the color filter layer 150 can include a red color filter disposed in the first subpixel SP1, a blue color filter disposed in the third subpixel SP3, and a green color filter disposed in the fourth subpixel SP4. The second subpixel SP2 may not include a color filter layer or can include a transparent material to compensate a step difference between adjacent subpixels, thereby emitting white light.

The organic light emitting display apparatus or the display panel 10 according to an embodiment of the present disclosure can further include a light separation portion LSP which is configured between the substrate 100 and the light extraction pattern 140 to overlap the emission area EA.

The light separation portion LSP can be formed or configured in the color filter layer 150 to overlap the emission area EA. For example, the light separation portion LSP can be formed or configured based on a thickness (or a height) of the color filter layer 150.

The light separation portion LSP according to an embodiment of the present disclosure can include the plurality of light separation regions LSR1 and LSR2 or the first light separation region LSR1 and the second light separation region LSR2, which are provided between the substrate 100 and the light extraction pattern 140 to overlap the emission area EA. The first light separation region LSR1 and the second light separation region LSR2 can be disposed along the second direction Y.

The first and second light separation regions (or the plurality of light separation regions) LSR1 and LSR2 can be formed or configured based on a thickness (or height) difference of the color filter layer 150. The first and second light separation regions (or the plurality of light separation regions) LSR1 and LSR2 can be formed or configured by the color filter layer 150 having different thicknesses (or heights). For example, the color filter layer 150 can be configured to have different thicknesses (or heights) at the first and second light separation regions (or the plurality of light separation regions) LSR1 and LSR2.

According to an embodiment of the present disclosure, reflection light which is reflected from the light extraction pattern 140 and passes through the first and second light separation regions (or the plurality of light separation regions) LSR1 and LSR2 can be changed in amplitude and phase of a wavelength (or an optical wave), based on a thickness of the color filter layer 150. For example, in reflection light passing through the color filter layer 150 which is relatively thin, an amplitude of a wavelength (or an optical wave) can increase. For example, in reflection light passing through the color filter layer 150 which is relatively thick, an amplitude of a wavelength (or an optical wave) can decrease.

According to an embodiment of the present disclosure, first reflection light Lre1 reflected from the light extraction pattern 140 to the first light separation region LSR1 and second reflection light Lre2 reflected from the light extraction pattern 140 to the second light separation region LSR2 can have an amplitude difference of a wavelength (or an optical wave) and/or a phase difference of a wavelength (or an optical wave), and thus, the reflection lights Lre1 and Lre2 reflected from the light extraction pattern 140 can be optically divided (or separated) by the first light separation region LSR1 and the second light separation region LSR2, thereby increasing the irregularity or randomness of a diffraction pattern of the reflection light reflected from the light extraction pattern 140.

The organic light emitting display apparatus or the display panel 10 according to an embodiment of the present disclosure can further include an encapsulation portion 200.

The encapsulation portion 200 can be formed on (or over) the substrate 100 to surround the light emitting device layer 160. The encapsulation portion 200 can be formed on (or over) the second electrode E2. For example, the encapsulation portion 200 can surround the display area AA. The encapsulation portion 200 can protect the thin film transistor and the emission layer EL or the like from external impact and prevent oxygen or/and water (or moisture) and particles from being permeated into the emission layer EL.

The encapsulation portion 200 according to an embodiment of the present disclosure can include a plurality of inorganic encapsulation layer. Furthermore, the encapsulation portion 200 can further include at least one organic encapsulation layer interposed between the plurality of inorganic encapsulation layer. The encapsulation portion 200 according to another embodiment of the present disclosure can be changed to a filler surrounding (or completely surrounding) an entire display area AA. In this case, the counter substrate 300 can be bonded to the substrate 100 by using the filler. The filler can include a getter material that absorbs oxygen or/and water (or moisture) or the like.

The organic light emitting display apparatus or the display panel 10 according to an embodiment of the present disclosure can further include a counter substrate 300.

The counter substrate 300 can be coupled to the encapsulation portion 200. The counter substrate 300 can be made of a plastic material, a glass material, or a metal material. For example, when the encapsulation portion 200 includes the plurality of inorganic encapsulation layers, the counter substrate 300 can be omitted.

Alternatively, when the encapsulation portion 200 is changed to the filler, the counter substrate 300 can be combined with the filler, in this case, the counter substrate 300 can be made of a plastic material, a glass material, or a metal material.

The organic light emitting display apparatus or display panel 10 according to an embodiment of the present disclosure can further include a polarizing member 400.

The polarizing member 400 can be configured to block the external light reflected by the light extracting pattern 140 and the pixel circuit, or the like. For example, the polarizing member 400 can be a circular polarizing member or a circular polarizing film. The polarizing member 400 can be disposed at or coupled to the light extraction surface 100a of the substrate 100 by using a coupling member (or a transparent adhesive member) 450. For example, the polarizing member 400 can be omitted.

As described above, the organic light emitting display apparatus or display panel 10 according to an embodiment of the present disclosure includes the light extracting pattern 140 disposed or configured at the emission area EA of the subpixel SP, thereby improving light extraction efficiency by changing a path of light generated from the emission layer EL by the light extracting pattern 140. Thus, it is possible to realize high efficiency and high luminance so that the lifespan of the emission layer can be extended, and low power consumption can be realized.

Moreover, the organic light emitting display apparatus or the display panel 10 according to an embodiment of the present disclosure can include the first light separation region LSR1 and the second light separation region LSR2, which are disposed or configured at the emission area EA of the subpixel SP, and thus, the occurrence of rainbow Mura where reflection light is spread in a radial shape and/or circular ring Mura where reflection light is spread in a radial shape can be prevented or minimized based on the diffraction characteristic of reflection light reflected from the light extraction pattern 140 of the display area AA. For example, a black visibility characteristic or a black color (or black rising) phenomenon caused by the reflection of external light can be reduced in a non-driving or off state of the organic light emitting display apparatus or the display panel 10, thereby implementing real black (or true black).

FIG. 4 is an enlarged view of a region ‘A’ illustrated in FIG. 2. FIG. 4 is a plan view illustrating a portion of the light extraction pattern illustrated in FIG. 2.

Referring to FIGS. 2 and 4, in the light extraction pattern 140 according to an embodiment of the present disclosure, each of the plurality of concave portions 141 can be disposed in parallel to have a predetermined interval along a second direction Y and can be disposed to be staggered with one another along a first direction X. Thus, the light extraction pattern 140 can include a larger number of concave portions 141 per unit area, thereby increasing the external extraction efficiency of the light emitted from the light emitting device layer 160.

According to an embodiment of the present disclosure, a center portion CP of each of the plurality of concave portions 141 disposed along the first direction X can be positioned or aligned at a first straight line SL1 parallel to the first direction X. In addition, each center portion CP of a plurality of concave portions 141 disposed along the second direction Y can be positioned or aligned at a second straight line SL2 parallel to the second direction Y. For example, the first straight line SL1 can be a horizontal line or a first horizontal line, and the second straight line SL2 can be a vertical line or a second horizontal line.

According to another embodiment of the present disclosure, the plurality of concave portions 141 are disposed in the form of a lattice (or a grid) such that each of a plurality of concave portions 141 disposed at even-numbered horizontal lines parallel to the first direction X can be disposed between a plurality of concave portions 141 disposed at adjacent odd-numbered horizontal lines along the second direction Y. Accordingly, the plurality of concave portions 141 disposed along the second direction Y can be positioned or aligned at a zigzag line ZL having a zigzag shape along the first direction X (or the second direction Y).

According to an embodiment, the center portion CP of each of the adjacent three concave portions 141 can be aligned to form a triangular shape TS. In addition, the center portion CP of each of the six concave portions 141 disposed around one concave portion 141 or surrounding one concave portion 141 can have a 6-angular shape HS in two-dimensions (or in a plan view). For example, each of the plurality of concave portions 141 can be disposed or arranged in a honeycomb structure, a hexagonal structure, or a circular structure in two-dimensions (or in a plan view.

According to an embodiment of the present disclosure, when the plurality of concave portions 141 are arranged (or disposed) in a honeycomb structure, diagonal center lines DCL1 and DCL2 passing through center portions CP of concave portions arranged (or disposed) along diagonal directions DD1 and DD2 between the first direction X and the second direction Y can be respectively inclined from the first straight line SL1 and a second straight line SL2. For example, a first angle θ1 between the diagonal center lines DCL1 and DCL2 and the first straight line SL1 can be about 30 degrees, and a second angle θ2 between the diagonal center lines DCL1 and DCL2 and the second straight line SL2 can be about 60 degrees.

According to an embodiment of the present disclosure, a pitch (or a distance) L1 between the plurality of concave portions 141 can be equal or different from each other. The pitch L1 between the plurality of concave portions 141 can be a distance (or an interval) between the center portions CP of the two adjacent concave portions 141.

The convex portion 143 can be configured to individually surround each of the plurality of concave portions 141. Accordingly, the light extraction pattern 140 can include a plurality of concave portions 141 surrounded by the convex portions 143. The convex portion 143 surrounding one concave portion 141 can have a hexagonal shape (or a honeycomb shape) in two-dimensions (or in a plan view), but embodiments according to the present disclosure are not limited thereto.

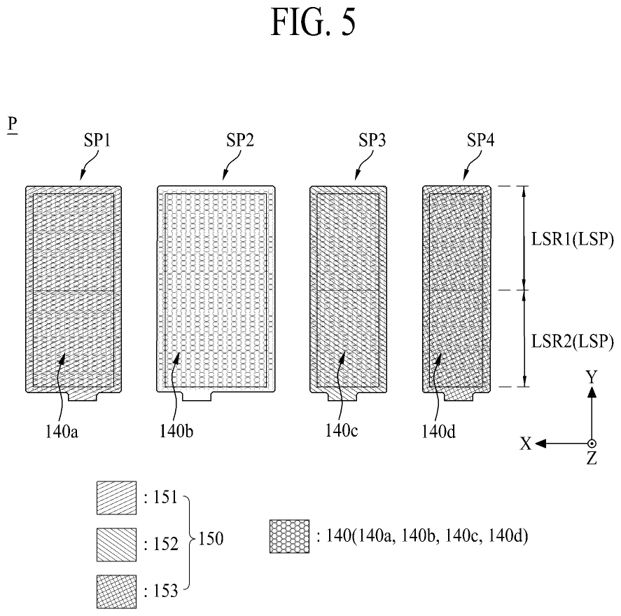

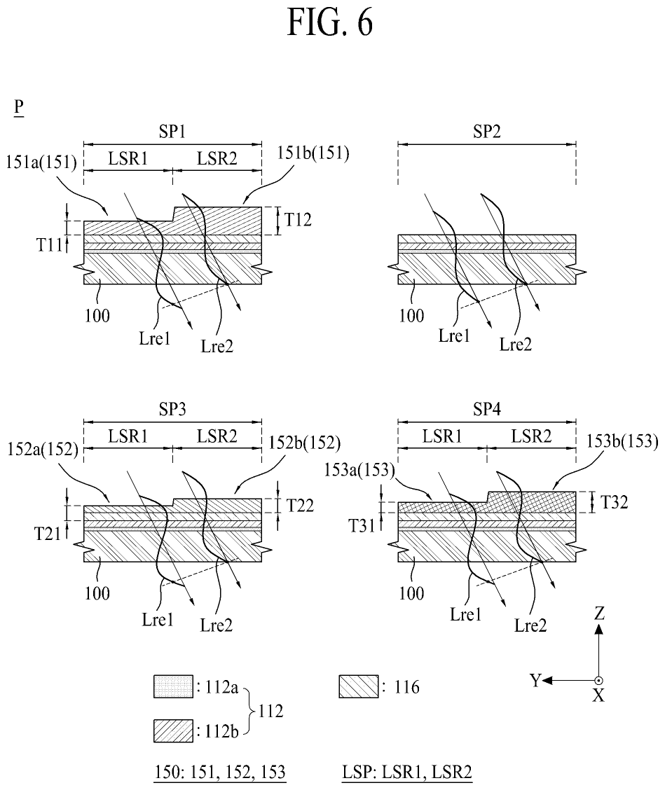

FIG. 5 is a diagram illustrating a light separation portion according to an embodiment of the present disclosure. FIG. 6 is a cross-sectional view illustrating a light separation portion at a plurality of color subpixels illustrated in FIG. 5.

Referring to FIGS. 5 and 6, a light separation portion LSP according to an embodiment (or a first embodiment) of the present disclosure can include a first light separation region LSR1 and a second light separation region LSR2, which are disposed at first, third, and fourth subpixels (or a plurality of color subpixels) SP1, SP3, and SP4 of each of a plurality of pixels P.

With respect to a second direction Y, the first light separation region LSR1 can be an upper region (or a top region) of each of first, third, and fourth subpixels SP1, SP3, and SP4, and the second light separation region LSR2 can be a lower region (or a bottom region) of each of the first, third, and fourth subpixels SP1, SP3, and SP4. For example, the emission area EA of each of the first, third, and fourth subpixels SP1, SP3, and SP4 can have an upward-downward two-division structure (or a vertical two-division structure) by the first light separation region LSR1 and the second light separation region LSR2. For example, the first light separation region LSR1 and the second light separation region LSR2 can have a same size (or area), but embodiments of the present disclosure are not limited thereto. For example, the first light separation region LSR1 and the second light separation region LSR2 can be divided based on a thickness of a color filter layer 150.

The color filter layer 150 can be configured to have different thicknesses at the first light separation region LSR1 and the second light separation region LSR2 of each of the first, third, and fourth subpixels SP1, SP3, and SP4. The color filter layer 150 at the first light separation region LSR1 of each of the first, third, and fourth subpixels SP1, SP3, and SP4 can have different thicknesses. The color filter layer 150 at the second light separation region LSR2 of each of the first, third, and fourth subpixels SP1, SP3, and SP4 can have different thicknesses from each other.

The color filter layer 150 can include a first filter region and a second filter region, which have different thicknesses from each other at the first light separation region LSR1 and the second light separation region LSR2 of each of the first, third, and fourth subpixels SP1, SP3, and SP4. The first filter region at each of the first, third, and fourth subpixels SP1, SP3, and SP4 can have different thicknesses from each other. The second filter region at each of the first, third, and fourth subpixels SP1, SP3, and SP4 can have different thicknesses from each other.

The first filter region and the second filter region of the color filter layer 150 can be configured to contact the passivation layer 116. For example, the passivation layer 116 can include a first surface adjacent to the substrate 100 and a second surface opposite to the first surface. For example, the first filter region and the second filter region of the color filter layer 150 can be configured to contact the second surface of the passivation layer 116.

The color filter layer 150 according to an embodiment of the present disclosure can include a first color filter layer 151, a second color filter layer 152, and a third color filter layer 153.

The first color filter layer 151 can be disposed at the first subpixel SP1. For example, the first color filter layer 151 can be a red color filter layer. The first color filter layer 151 can have different thicknesses at the first light separation region LSR1 and the second light separation region LSR2. For example, the first color filter layer 151 can include a first filter region 151a and a second filter region 151b, which have different thicknesses at the first light separation region LSR1 and the second light separation region LSR2. For example, the first filter region 151a of the first color filter layer 151 can have a first thickness T11. The second filter region 151b of the first color filter layer 151 can have a second thickness T12 which differs from the first thickness T11 or is thicker than the first thickness T11. Accordingly, reflection lights Lre1 and Lre2 which are reflected from a first light extraction pattern 140a of the first subpixel SP1 and respectively pass through the first light separation region LSR1 and the second light separation region LSR2 of the first color filter layer 151 can be optically divided (or separated) based on an amplitude and/or phase difference caused by a thickness T11 and T12 difference of the first filter region 151a and the second filter region 151b.

The second color filter layer 152 can be disposed at the third subpixel SP3. For example, the second color filter layer 152 can be a blue color filter layer. The second color filter layer 152 can have different thicknesses at the first light separation region LSR1 and the second light separation region LSR2. For example, the second color filter layer 152 can include a first filter region 152a and a second filter region 152b, which have different thicknesses at the first light separation region LSR1 and the second light separation region LSR2. For example, the first filter region 152a of the second color filter layer 152 can have a first thickness T21. The second filter region 152b of the second color filter layer 152 can have a second thickness T22 which differs from the first thickness T21 or is thicker than the first thickness T21. Accordingly, reflection lights Lre1 and Lre2 which are reflected from a third light extraction pattern 140c of the third subpixel SP3 and respectively pass through the first light separation region LSR1 and the second light separation region LSR2 of the second color filter layer 152 can be optically divided (or separated) based on an amplitude and/or phase difference caused by a thickness T21 and T22 difference of the first filter region 152a and the second filter region 152b.

The third color filter layer 153 can be disposed at the fourth subpixel SP4. For example, the third color filter layer 153 can be a green color filter layer. The third color filter layer 153 can have different thicknesses at the first light separation region LSR1 and the second light separation region LSR2. For example, the third color filter layer 153 can include a first filter region 153a and a second filter region 153b, which have different thicknesses at the first light separation region LSR1 and the second light separation region LSR2. For example, the first filter region 153a of the third color filter layer 153 can have a first thickness T31. The second filter region 153b of the third color filter layer 153 can have a second thickness T32 which differs from the first thickness T31 or is thicker than the first thickness T31. Accordingly, reflection lights Lre1 and Lre2 which are reflected from a fourth light extraction pattern 140d of the fourth subpixel SP4 and respectively pass through the first light separation region LSR1 and the second light separation region LSR2 of the third color filter layer 153 can be optically divided (or separated) based on an amplitude and/or phase difference caused by a thickness T31 and T32 difference of the first filter region 153a and the second filter region 153b.

In each of the first color filter layer 151, the second color filter layer 152, and the third color filter layer 153, first thicknesses T11, T21, and T31 of the first filter regions 151a, 152a, and 153a can be different from each other, and second thicknesses T12, T22, and T32 of the second filter regions 151b, 152b, and 153b can be different from each other. For example, the first thickness T11 of the first filter region 151a at the first color filter layer 151 can be thickest, and the first thickness T31 of the first filter region 153a at the third color filter layer 153 can be thinnest. For example, the second thickness T12 of the second filter region 151b at the first color filter layer 151 can be thickest, and the second thickness T32 of the second filter region 153b at the third color filter layer 153 can be thinnest. Accordingly, reflection lights Lre1 and Lre2 which are reflected from the light extraction pattern 140 at the pixel P can be optically divided (or separated) based on an amplitude and/or phase difference caused by a thickness T11, T21, T31, T12, T22, and T32 difference of the first filter regions 151a, 152a, and 153a and the second filter regions 151b, 152b, and 153b at each of the first, third, and fourth subpixels SP1, SP3, and SP4.

According to an embodiment of the present disclosure, because the color filter layer 150 is not disposed at the second subpixel SP2 of the pixel P, reflection lights Lre1 and Lre2 reflected from the second light extraction pattern 140b of the second subpixel SP2 may not be optically divided (or separated) and can be output to the outside of the substrate 100, and reflection lights Lre1 and Lre2 reflected from the first, third, and fourth light extraction patterns 140a, 140c, and 140d of the first, third, and fourth subpixels SP1, SP3, and SP4 can be optically divided (or separated) by the light separation portion LSP and can be output to the outside of the substrate 100. Therefore, due to the optical division (or separation) of the reflection lights Lre1 and Lre2 reflected from the first, third, and fourth light extraction patterns 140a, 140c, and 140d, the irregularity or randomness of diffraction patterns of the reflection lights Lre1 and Lre2 reflected from the light extraction pattern 140 of the pixel P can increase, and thus, a probability of occurrence of constructive interference (or light interference) occurring between the reflection lights Lre1 and Lre2 reflected from the light extraction pattern 140 of the pixel P can decrease or a probability of occurrence of destructive interference can increase.

In FIG. 5, the first light separation region LSR1 and the second light separation region LSR2 of the light separation portion LSP are disposed along the second direction Y, but embodiments of the present disclosure are not limited thereto. For example, the first light separation region LSR1 and the second light separation region LSR2 of the light separation portion LSP in each of the first, third, and fourth subpixels (or the plurality of color subpixels) SP1, SP3, and SP4 can be disposed along a first direction X or a diagonal direction. Accordingly, the first light separation region LSR1 and the second light separation region LSR2 of the light separation portion LSP at each of the first, third, and fourth subpixels (or the plurality of color subpixels) SP1, SP3, and SP4 can be disposed along one direction of the first direction X, the second direction Y intersecting with the first direction X, and the diagonal direction between the first direction X and the second direction Y.

As described above, the light separation portion LSP according to an embodiment of the present disclosure can include the color filter layer 150 configured with different thicknesses T11, T21, T31, T12, T22, and T32 at the first light separation region LSR1 and the second light separation region LSR2, and thus, the irregularity or randomness of diffraction patterns of the reflection lights Lre1 and Lre2 can increase by optically dividing (or separating) the reflection lights Lre1 and Lre2 reflected from the light extraction pattern 140, and thus, the occurrence of rainbow Mura where reflection light is spread in a radial shape and/or circular ring Mura where reflection light is spread in a radial shape can be prevented or minimized based on a diffraction characteristic of reflection light reflected from the light extraction pattern 140.

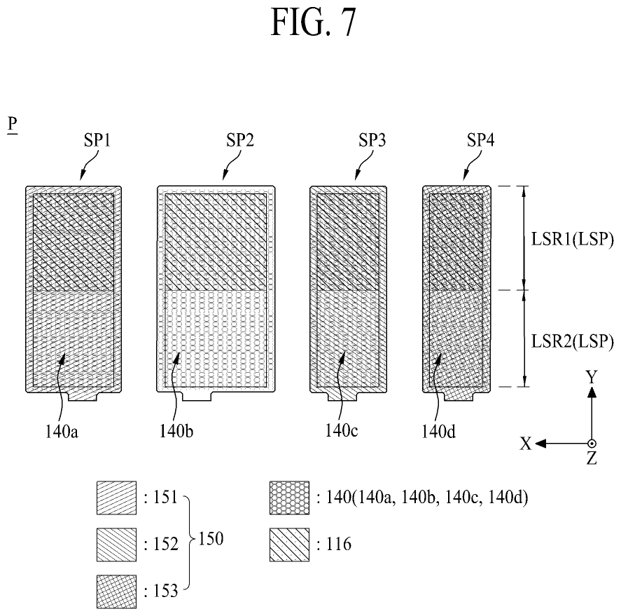

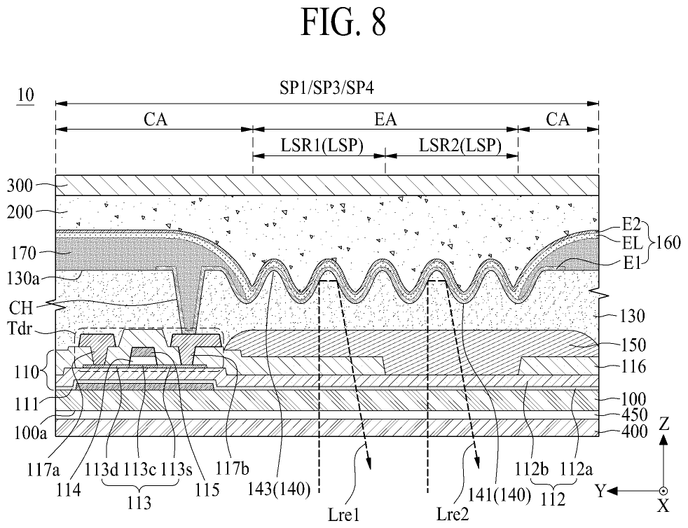

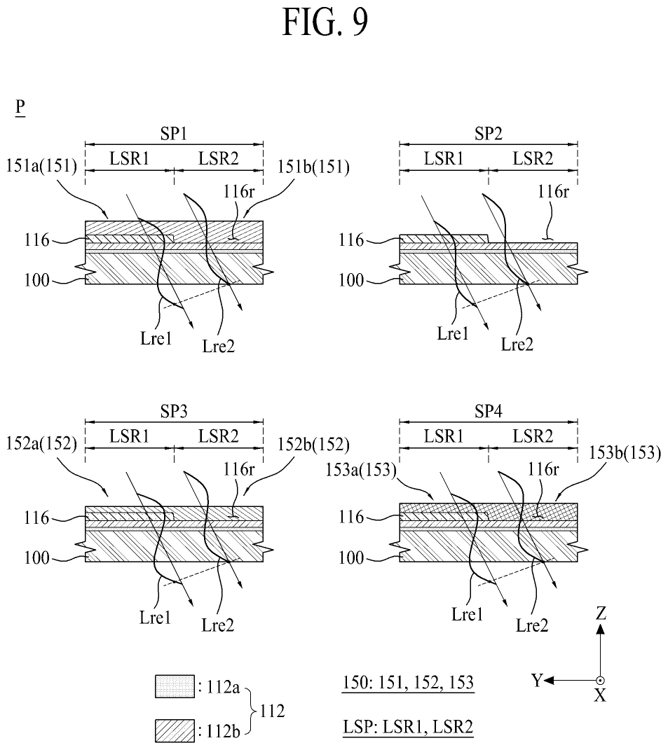

FIG. 7 is a diagram illustrating a light separation portion according to another embodiment of the present disclosure. FIG. 8 is a cross-sectional view illustrating a cross-sectional structure of the first, third, and fourth subpixels illustrated in FIG. 7. FIG. 9 is a cross-sectional view illustrating the light separation portion in the first, third, and fourth subpixels illustrated in FIG. 7.

Particularly, FIGS. 7 to 9 illustrate an embodiment implemented by modifying the light separation portion in the organic light emitting display apparatus or the display panel described above with reference to FIGS. 1 to 6. Therefore, in the following description, descriptions of the other elements except a light separation portion and relevant elements can be the same as the descriptions of FIGS. 1 and 6, and thus, repeated descriptions thereof are omitted or will be briefly given.

Referring to FIGS. 7 to 9, a light separation portion LSP according to another embodiment (or a second embodiment) of the present disclosure can include a first light separation region LSR1 and a second light separation region LSR2, which are additionally configured between a substrate 100 and a light extraction pattern 140 to overlap an emission area of a second subpixel (or a white subpixel) SP2 of each of a plurality of pixels P. For example, the light separation portion LSP can include the first light separation region LSR1 and the second light separation region LSR2, which are configured between the substrate 100 and the light extraction pattern 140 to overlap an emission area of each of first to fourth subpixels SP1, SP2, SP3, and SP4 of each of the plurality of pixels P.

In each of first to fourth subpixels SP1, SP2, SP3, and SP4, the first light separation region LSR1 and the second light separation region LSR2 can be disposed along the second direction Y. For example, the first light separation region LSR1 and the second light separation region LSR2 can have a same size (or area), but embodiments of the present disclosure are not limited thereto. For example, the first light separation region LSR1 and the second light separation region LSR2 can have different refractive indexes, but embodiments of the present disclosure are not limited thereto. For example, the first light separation region LSR1 and the second light separation region LSR2 can have a refractive index difference of 0.1 or more therebetween, but embodiments of the present disclosure are not limited thereto.

The first light separation region LSR1 and the second light separation region LSR2 of the light separation portion LSP at each of the first, third, and fourth subpixels (or a plurality of color subpixels) SP1, SP3, and SP4 can be formed or configured at a passivation layer 116 and a color filter layer 150 between the substrate 100 and the light extraction pattern 140. The first light separation region LSR1 and the second light separation region LSR2 of the light separation portion LSP at the second subpixel (or a white color subpixel) SP2 can be formed or configured at the passivation layer 116 between the substrate 100 and the light extraction pattern 140.

In each of first to fourth subpixels SP1, SP2, SP3, and SP4, the passivation layer 116 can be disposed at the first light separation region LSR1 and may not be disposed at the second light separation region LSR2. For example, the first light separation region LSR1 can be a region where the passivation layer 116 is disposed, and the second light separation region LSR2 can be a region (or a removal region) 116r from which the passivation layer 116 has been removed. For example, the first light separation region LSR1 can be a region where the passivation layer 116 is disposed, and the second light separation region LSR2 can be the region 116r where the passivation layer 116 is not disposed. The passivation layer 116 disposed at the first light separation region LSR1 of each of the first to fourth subpixels SP1, SP2, SP3, and SP4 can have the same thickness. For example, the first light separation region LSR1 can be a disposition region of the passivation layer 116, and the second light separation region LSR2 can be a non-disposition region of the passivation layer 116.

The color filter layer 150 can be disposed or configured in a region where the passivation layer is disposed and the region 116r where the passivation layer 116 is not disposed, at each of the first, third, and fourth subpixels SP1, SP3, and SP4, and thus, can have different thicknesses from each other at the first light separation region LSR1 and the second light separation region LSR2 of the light separation portion LSP. The color filter layer 150 disposed on the passivation layer 116 can have a first thickness. For example, the color filter layer 150 disposed in the region 116r where the passivation layer 116 is not disposed can have a second thickness which is thicker than the first thickness by a thickness of the passivation layer 116. For example, the passivation layer 116 and the color filter layer 150 can have a refractive index difference of 0.1 or more therebetween.

The first color filter layer 151 of the color filter layer 150 disposed at the first subpixel SP1 can include a first filter region 151a and a second filter region 151b, which have different thicknesses at the first light separation region LSR1 and the second light separation region LSR2. The first filter region 151a of the first color filter layer 151 can be disposed on the passivation layer 116, or can be disposed at a region where the passivation layer 116 is disposed. The second filter region 151b of the first color filter layer 151 can be disposed at the region 116r where the passivation layer 116 is not disposed. The first light separation region LSR1 of the first subpixel SP1 can include the first filter region 151a of the first color filter layer 151 and the passivation layer 116. The second light separation region LSR2 of the first subpixel SP1 can include the second filter region 151b of the first color filter layer 151 and the region 116r where the passivation layer 116 is not disposed.

According to another embodiment of the present disclosure, in the first subpixel SP1, first reflection light Lre1 reflected from the first light extraction pattern 140a to the first light separation region LSR1 can pass through the first filter region 151a of the first color filter layer 151 and the passivation layer 116, and thus, an amplitude and/or a phase can be changed based on a thickness of the first filter region 151a and a wavelength (or a path length of optical wave) can be shortened or a velocity can be reduced, based on a refractive index of the passivation layer 116. Second reflection light Lre2 reflected from the first light extraction pattern 140a to the second light separation region LSR2 can pass through the second filter region 151b of the first color filter layer 151 and the region 116r where the passivation layer 116 is not disposed, and thus, an amplitude and/or a phase can be changed based on a thickness of the second filter region 151b. Accordingly, the reflection light Lre1 and the reflection light Lre2 can be optically divided (or separated) due to one or more of an amplitude difference, a phase difference, and a path difference, and thus, a probability of occurrence of constructive interference (or light interference) occurring between the reflection light Lre1 and the reflection light Lre2 can decrease or a probability of occurrence of destructive interference can increase.

The second color filter layer 152 of the color filter layer 150 disposed at the third subpixel SP3 can include a first filter region 152a and a second filter region 152b, which have different thicknesses at the first light separation region LSR1 and the second light separation region LSR2. The first filter region 152a of the second color filter layer 152 can be disposed on the passivation layer 116, or can be disposed at a region where the passivation layer 116 is disposed. The second filter region 152b of the second color filter layer 152 can be disposed at the region 116r where the passivation layer 116 is not disposed. The first light separation region LSR1 of the third subpixel SP3 can include the first filter region 152a of the second color filter layer 152 and the passivation layer 116. The second light separation region LSR2 of the third subpixel SP3 can include the second filter region 152b of the second color filter layer 152 and the region 116r where the passivation layer 116 is not disposed. Accordingly, the reflection light Lre1 and the reflection light Lre2 reflected from the third light extraction pattern 140c to the first and second light separation regions LSR1 and LSR2 can be optically divided (or separated) due to one or more of an amplitude difference, a phase difference, and a path difference, and thus, a probability of occurrence of constructive interference (or light interference) occurring between the reflection light Lre1 and the reflection light Lre2 can decrease or a probability of occurrence of destructive interference can increase.

The third color filter layer 153 of the color filter layer 150 disposed at the fourth subpixel SP4 can include a first filter region 153a and a second filter region 153b, which have different thicknesses at the first light separation region LSR1 and the second light separation region LSR2. The first filter region 153a of the third color filter layer 153 can be disposed on the passivation layer 116, or can be disposed at a region where the passivation layer 116 is disposed. The second filter region 153b of the third color filter layer 153 can be disposed at the region 116r where the passivation layer 116 is not disposed. The first light separation region LSR1 of the fourth subpixel SP4 can include the first filter region 153a of the third color filter layer 153 and the passivation layer 116. The second light separation region LSR2 of the fourth subpixel SP4 can include the second filter region 153b of the third color filter layer 153 and the region 116r where the passivation layer 116 is not disposed. Accordingly, the reflection light Lre1 and the reflection light Lre2 reflected from the fourth light extraction pattern 140d to the first and second light separation regions LSR1 and LSR2 can be optically divided (or separated) due to one or more of an amplitude difference, a phase difference, and a path difference, and thus, a probability of occurrence of constructive interference (or light interference) occurring between the reflection light Lre1 and the reflection light Lre2 can decrease or a probability of occurrence of destructive interference can increase.

According to another embodiment of the present disclosure, in the second subpixel SP2, first reflection light Lre1 reflected from the second light extraction pattern 140b to the first light separation region LSR1 can pass through the passivation layer 116, and thus, a path and/or a phase can be changed and a wavelength (or a path length of optical wave) can be shortened or a velocity can be reduced, based on a refractive index of the passivation layer 116. Second reflection light Lre2 reflected from the second light extraction pattern 140b to the second light separation region LSR2 can pass through the region 116r where the passivation layer 116 is not disposed, and thus, a path and/or a phase may not be changed. Accordingly, the reflection light Lre1 and the reflection light Lre2 can be optically divided (or separated) due to a phase difference and/or a path difference, and thus, a probability of occurrence of constructive interference (or light interference) occurring between the reflection light Lre1 and the reflection light Lre2 can decrease or a probability of occurrence of destructive interference can increase.

As described above, the light separation portion LSP according to another embodiment of the present disclosure can include the color filter layer 150 configured with different thicknesses at the first light separation region LSR1 and the second light separation region LSR2 and the passivation layer 116 which is not disposed at the second light separation region LSR2, and thus, the irregularity or randomness of diffraction patterns of the reflection lights Lre1 and Lre2 can increase by optically dividing (or separating) the reflection lights Lre1 and Lre2 reflected from the light extraction pattern 140, and thus, the occurrence of rainbow Mura where reflection light is spread in a radial shape and/or circular ring Mura where reflection light is spread in a radial shape can be better prevented or more minimized based on a diffraction characteristic of each of the reflection lights reflected from the light extraction patterns 140.

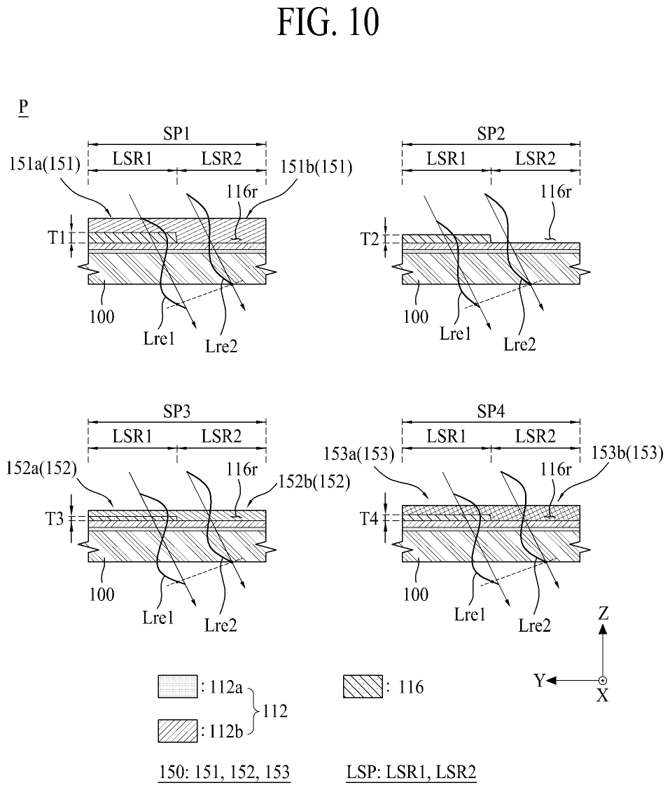

FIG. 10 is a cross-sectional view illustrating a light separation portion at first to fourth subpixels illustrated in FIG. 7. Particularly, FIG. 10 illustrates an embodiment implemented by modifying a passivation layer of a light separation portion described above with reference to FIGS. 7 to 9. Therefore, in the following description, descriptions of the other elements except a passivation layer of a light separation portion and relevant elements can be the same as the descriptions of FIGS. 7 to 9, and thus, repeated descriptions thereof are omitted or will be briefly given.

Referring to FIG. 10, in each of first to fourth subpixels SP1, SP2, SP3, and SP4, a passivation layer 116 of a first light separation region of a light separation portion LSP can have different thicknesses T1, T2, T3, and T4. For example, the passivation layer 116 at each of first to fourth subpixels SP1, SP2, SP3, and SP4 can be configured to have different thicknesses from each other based on a main wavelength of light emitted from a corresponding subpixel SP1, SP2, SP3, and SP4.

The passivation layer 116 disposed at a first light separation region LSR1 of the first subpixel SP1 can have a first thickness T1. The passivation layer 116 disposed at a first light separation region LSR1 of the second subpixel SP2 can have a second thickness T2. The passivation layer 116 disposed at a first light separation region LSR1 of the third subpixel SP3 can have a third thickness T3. The passivation layer 116 disposed at a first light separation region LSR1 of the fourth subpixel SP4 can have a fourth thickness T4. For example, the first thickness T1 can be thicker than each of second to fourth thicknesses T2, T3, and T4, and the third thickness T3 can be thinner than the second and fourth thicknesses T2 and T4. The second thickness T2 and the fourth thickness T4 can have a same thickness or different thicknesses within a range which is thinner than the first thickness T1 and thicker than the third thickness T3.

According to an embodiment of the present disclosure, the passivation layer 116 disposed at the first light separation region LSR1 of each of the first to fourth subpixels SP1, SP2, SP3, and SP4 can be configured to have a thickness T1, T2, T3, and T4 corresponding to a path difference ΔX, except an integer multiple of a wavelength 2, of a path difference ΔX between the first reflection light Lre1 passing through the light separation region LSR1 and the second reflection light Lre2 passing through the light separation region LSR2, based on the following Equation 1.

$$\\ \begin{matrix}0.1 \times λ < Δ X < 9.9 \times λ & [ Equation 1 ]\end{matrix}$$

In Equation 1, λ (lambda) can denote a wavelength and can be 450 nm to 700 nm (nanometer). In Equation 1, as ΔX gets close to 0.5 (λ/2), destructive interference between the first reflection light Lre1 passing through the first light separation region LSR1 and the second reflection light Lre2 passing through the second light separation region LR2 can increase.

According to an embodiment of the present disclosure, a path difference ΔX between the first reflection light Lre1 passing through the first light separation region LSR1 including the passivation layer 116 having a refractive index of 1.5 and the second reflection light Lre2 passing through the second light separation region LSR2 including a second filter region of a color filter layer 150 having a refractive index of 1.6 without passing through the passivation layer 116 can be 70 nm to 100 nm, but embodiments according to present disclosure are not limited thereto.

As described above, the light separation portion LSP according to another embodiment of the present disclosure can have or provide the same effect as that of the light separation portion LSP described above with reference to FIGS. 7 to 9, and the destructive interference of reflection lights Lre1 and Lre2 reflected from the light extraction pattern 140 can more increase based on thicknesses T1, T2, T3, and T4 of the passivation layer 116 disposed in the first light separation region LSR1 of the subpixels SP1, SP2, SP3, and SP4, and thus, the occurrence of rainbow Mura where reflection light is spread in a radial shape and/or circular ring Mura where reflection light is spread in a radial shape can be prevented or minimized based on a diffraction characteristic of reflection light reflected from the light extraction pattern 140.

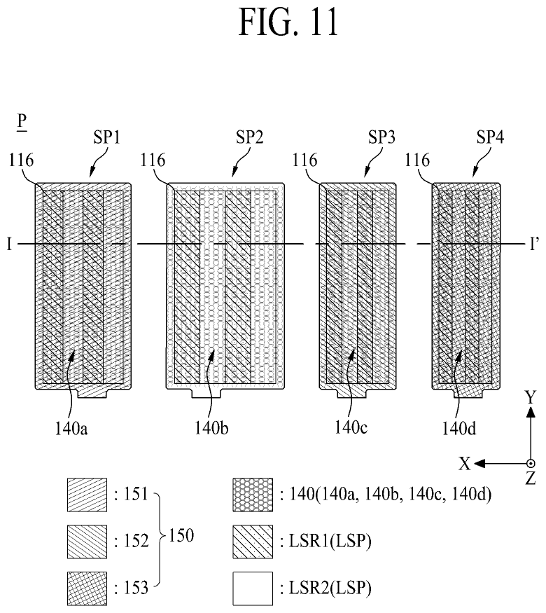

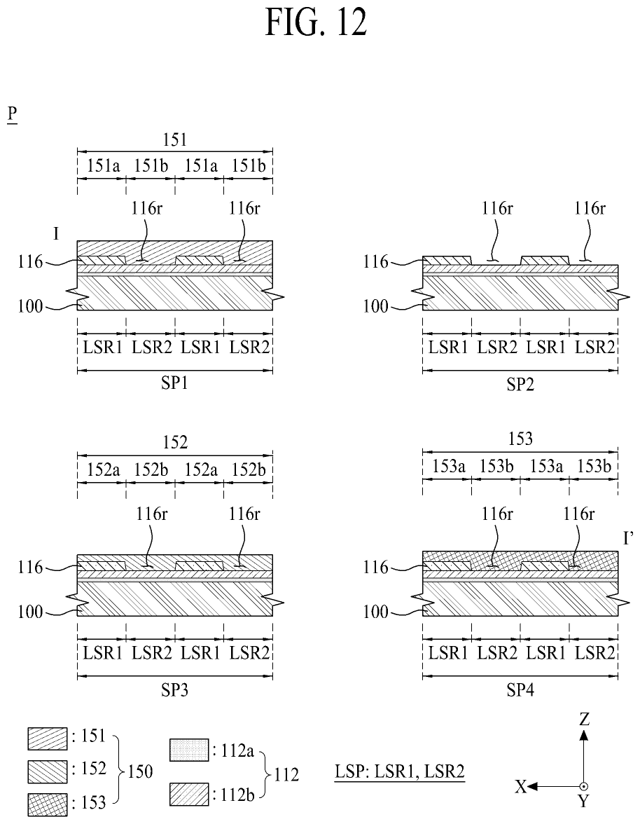

FIG. 11 is a diagram illustrating a light separation portion according to another embodiment of the present disclosure. FIG. 12 is a cross-sectional view taken along line I-I′ illustrating a light separation portion at each of first to fourth subpixels illustrated in FIG. 11. Particularly, FIGS. 11 and 12 illustrate an embodiment implemented by modifying a light separation portion described above with reference to FIGS. 7 to 9. Therefore, in the following description, descriptions of the other elements except a light separation portion and relevant elements can be the same as the descriptions of FIGS. 7 to 9, and thus, repeated descriptions thereof are omitted or will be briefly given.

Referring to FIGS. 11 and 12, a light separation portion LSP according to another embodiment (or a third embodiment) of the present disclosure can include one or more first light separation regions LSR1 and one or more second light separation regions LSR2, which are disposed in first to fourth subpixels (or a plurality of subpixels) SP1, SP2, SP3, and SP4 of each of a plurality of pixels P.

In each of first to fourth subpixels SP1, SP2, SP3, and SP4, the one or more first light separation region LSR1 and the one or more second light separation region LSR2 can be disposed along a second direction Y. For example, when the light separation portion LSP includes a plurality of first light separation regions LSR1 and a plurality of second light separation regions LSR2, the plurality of first light separation regions LSR1 and the plurality of second light separation regions LSR2 can be alternately disposed along a first direction X. For example, the one or more first light separation region LSR1 and the one or more second light separation region LSR2 can have a same size (or area), but embodiments of the present disclosure are not limited thereto. For example, the one or more first light separation region LSR1 and the one or more second light separation region LSR2 can have different refractive indexes, but embodiments of the present disclosure are not limited thereto. For example, the one or more first light separation region LSR1 and the one or more second light separation region LSR2 can have a refractive index difference of 0.1 or more therebetween, but embodiments of the present disclosure are not limited thereto.

In each of first to fourth subpixels SP1, SP2, SP3, and SP4, the passivation layer 116 can be disposed at the one or more first light separation region LSR1 and may not be disposed at the one or more second light separation region LSR2. For example, the one or more first light separation region LSR1 can be a region where the passivation layer 116 is disposed, and the one or more second light separation region LSR2 can be a region 116r from which the passivation layer 116 has been removed. For example, the one or more first light separation region LSR1 can be a region where the passivation layer 116 is disposed, and the one or more second light separation region LSR2 can be the region 116r where the passivation layer 116 is not disposed. For example, the one or more first light separation region LSR1 can be a disposition region of the passivation layer 116, and the one or more second light separation region LSR2 can be a non-disposition region of the passivation layer 116.

The passivation layer 116 disposed at the one or more first light separation region LSR1 at each of the first to fourth subpixels SP1, SP2, SP3, and SP4 according to an embodiment of the present disclosure can have the same thickness, but embodiments of the present disclosure are not limited thereto. For example, the passivation layer 116 disposed at the one or more first light separation regions LSR1 at each of the first to fourth subpixels SP1, SP2, SP3, and SP4, as described above with reference to FIG. 10, can have different thicknesses.

The color filter layer 150 can be disposed or configured in a region where the passivation layer is disposed and the region 116r where the passivation layer 116 is not disposed, at each of the first, third, and fourth subpixels SP1, SP3, and SP4. Therefore, the color filter layer 150 can have different thicknesses from each other at the one or more first light separation region LSR1 and the one or more second light separation region LSR2.

According to an embodiment of the present disclosure, the color filter layer 150 can include a first filter region and a second filter region, which have different thicknesses in the one or more first light separation regions LSR1 and the one or more second light separation regions LSR2 at each of the first, third, and fourth subpixels SP1, SP3, and SP4. For example, the first filter region of the color filter layer 150 disposed on the passivation layer 116 in the one or more first light separation regions LSR1 can have a first thickness. The second filter region of the color filter layer 150 disposed in the region 116r where the passivation layer 116 is not disposed in the one or more second light separation regions LSR2 can have a second thickness which is thicker than the first thickness of the first filter region by a thickness of the passivation layer 116. The first filter regions of the first, third, and fourth subpixels SP1, SP3, and SP4 can have different thicknesses from each other. The second filter regions at each of the first, third, and fourth subpixels SP1, SP3, and SP4 can have different thicknesses from each other.

In the first subpixel SP1, the one or more first light separation regions LSR1 can include the passivation layer 116 and a first filter region 151a of the first color filter 151. The one or more second light separation regions LSR2 can include the region 116r where the passivation layer 116 is not disposed and a second filter region 151b of the first color filter 151. Accordingly, the second filter region 151b of the first color filter 151 at the one or more second light separation regions LSR2 can be configured to have a thickness which is thicker than the first filter region 151a of the first color filter 151 at the one or more first light separation regions LSR1.

In the first subpixel SP1, the one or more first light separation regions LSR1 can include the passivation layer 116. The one or more second light separation regions LSR2 can include the region 116r where the passivation layer 116 is not disposed. For example, the one or more second light separation regions LSR2 can include the region 116r where the passivation layer 116 is not disposed and a planarization layer. For example, the passivation layer 116 at the one or more first light separation regions LSR1 and the planarization layer at the one or more second light separation regions LSR2 can have a refractive index difference of 0.1 or more therebetween.

In the third subpixel SP3, the one or more first light separation regions LSR1 can include the passivation layer 116 and a first filter region 152a of the second color filter 152. The one or more second light separation regions LSR2 can include the region 116r where the passivation layer 116 is not disposed and a second filter region 152b of the second color filter 152. Accordingly, the second filter region 152b of the second color filter 152 at the one or more second light separation regions LSR2 can be configured to have a thickness which is thicker than the first filter region 152a of the second color filter 152 at the one or more first light separation regions LSR1.

In the fourth subpixel SP4, the one or more first light separation regions LSR1 can include the passivation layer 116 and a first filter region 153a of the third color filter 153. The one or more second light separation regions LSR2 can include the region 116r where the passivation layer 116 is not disposed and a second filter region 153b of the third color filter 153. Accordingly, the second filter region 153b of the third color filter 153 at the one or more second light separation regions LSR2 can be configured to have a thickness which is thicker than the first filter region 153a of the third color filter 153 at the one or more first light separation regions LSR1.

As described above, the light separation portion LSP according to another embodiment of the present disclosure can include the color filter layer 150 configured with different thicknesses at the first light separation region LSR1 and the second light separation region LSR2 and the passivation layer 116 which is not disposed at the second light separation region LSR2, and thus, the irregularity or randomness of diffraction patterns of the reflection lights Lre1 and Lre2 can increase by optically dividing (or separating) the reflection lights Lre1 and Lre2 reflected from the light extraction pattern 140, and thus, the occurrence of rainbow Mura where reflection light is spread in a radial shape and/or circular ring Mura where reflection light is spread in a radial shape can be better prevented or more minimized based on a diffraction characteristic of each of the reflection lights reflected from the light extraction patterns 140.

As described above, the light separation portion LSP according to another embodiment of the present disclosure can have or provide the same effect as that of the light separation portion LSP described above with reference to FIGS. 7 to 10, and can optically and multiply divide (or separate) reflection light, reflected from the light extraction pattern 140, through a plurality of first light separation regions LSR1 and a plurality of second light separation regions LSR2, thereby more increasing the irregularity or randomness of a diffraction pattern of reflection light, and thus, the occurrence of rainbow Mura where reflection light is spread in a radial shape and/or circular ring Mura where reflection light is spread in a radial shape can be prevented or minimized based on a diffraction characteristic of reflection light reflected from the light extraction pattern 140.

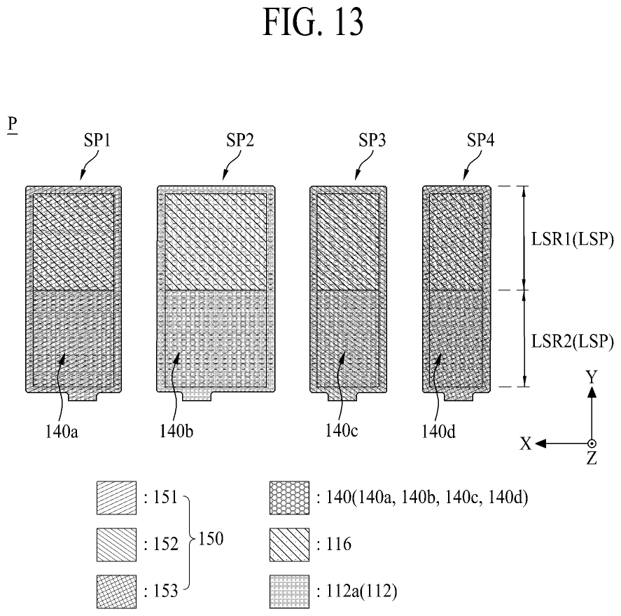

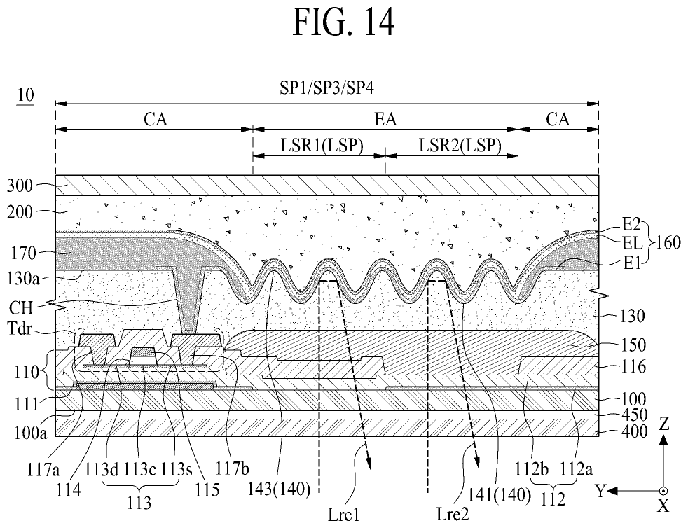

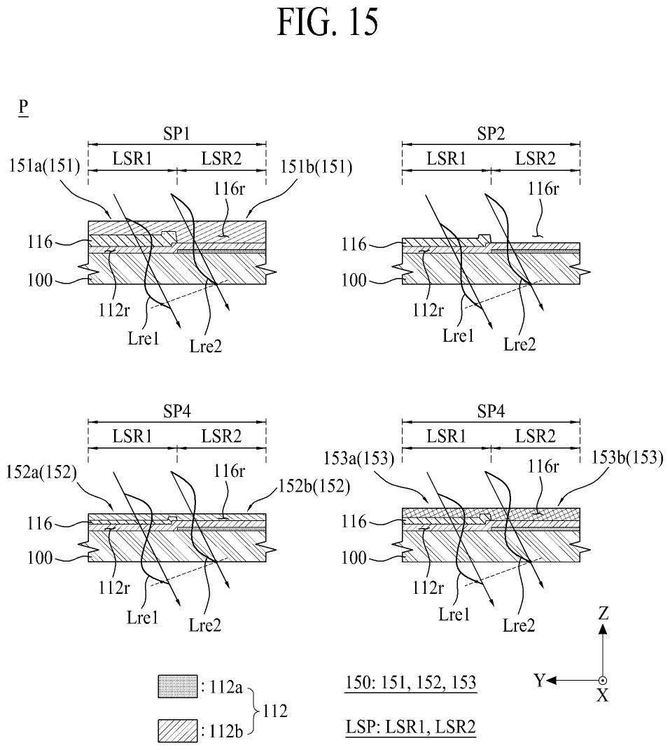

FIG. 13 is a diagram illustrating a light separation portion according to another embodiment of the present disclosure. FIG. 14 is a cross-sectional view illustrating a cross-sectional structure of first, third, and fourth subpixels illustrated in FIG. 13. FIG. 15 is a cross-sectional view illustrating a cross-sectional structure of first to fourth subpixels illustrated in FIG. 13. Here, FIGS. 13 to 15 illustrate an embodiment implemented by modifying a light separation portion described above with reference to FIGS. 7 to 9. Therefore, in the following description, descriptions of the other elements except a light separation portion and relevant elements can be the same as the descriptions of FIGS. 7 to 9, and thus, repeated descriptions thereof are omitted or will be briefly given.

Referring to FIGS. 13 to 15, a light separation portion LSP according to another embodiment (or a fourth embodiment) of the present disclosure can include one or more first light separation regions LSR1 and one or more second light separation regions LSR2, which are disposed in first to fourth subpixels (or a plurality of subpixels) SP1, SP2, SP3, and SP4 of each of a plurality of pixels P.

The first light separation region LSR1 and the second light separation region LSR2 of the light separation portion LSP at each of the first, third, and fourth subpixels (or a plurality of color subpixels) SP1, SP3, and SP4 can be formed or configured at a buffer layer 112, a passivation layer 116, and a color filter layer 150 between the substrate 100 and the light extraction pattern 140. The first light separation region LSR1 and the second light separation region LSR2 of the light separation portion LSP at the second subpixel (or a white color subpixel) SP2 can be formed or configured at the buffer layer 112 and the passivation layer 116 between the substrate 100 and the light extraction pattern 140.

The passivation layer 116 and the color filter layer 150 can be a same or substantially a same as the passivation layer 116 and the color filter layer 150 described above with reference to FIGS. 7 to 9, and thus, repeated descriptions thereof are omitted.

In each of the first to fourth subpixels SP1, SP2, SP3, and SP4, the buffer layer (or an insulation layer) 112 can include a first buffer layer 112a (or a first insulation layer) which is not disposed at the first light separation region LSR1 and is disposed at the second light separation region LSR2 and a second buffer layer 112b (or a second insulation layer) which covers the first buffer layer 112a and a region where the first buffer layer 112a is not disposed.

The buffer layer 112 and the passivation layer 116 can be configured to include materials having different refractive indexes. For example, the buffer layer 112 and the passivation layer 116 can be configured to include materials having a refractive index difference of 0.1 or more therebetween. For example, each of the first buffer layer 112a and the second buffer layer 112b of the buffer layer 112 and the passivation layer 116 can be configured to include materials having a refractive index difference of 0.1 or more between each of the first buffer layer 112a and the second buffer layer 112b and the passivation layer 116. The first buffer layer 112a and the second buffer layer 112b can be configured to include materials having different refractive indexes. For example, the first buffer layer 112a and the second buffer layer 112b can be configured to include materials having a refractive index difference of 0.1 or more therebetween.

In each of the first to fourth subpixels SP1, SP2, SP3, and SP4, the first buffer layer 112a may not be disposed at the first light separation region LSR1 and can be disposed at the second light separation region LSR2. For example, in each of the first to fourth subpixels SP1, SP2, SP3, and SP4, the first light separation region LSR1 can include a region (or a removal region) 112r from which the first buffer layer 112a has been removed, and the second light separation region LSR2 can include a region (or a disposition region) where the first buffer layer 112a is disposed.

According to an embodiment of the present disclosure, the first buffer layer 112a can be disposed at the first light separation region LSR1 and may not be disposed at the second light separation region LSR2. In this case, the passivation layer 116 can be disposed at the second light separation region LSR2 and may not be disposed at the first light separation region LSR1. As a result, the first buffer layer 112a and the passivation layer 116 can be configured to be disposed at different regions at the first light separation region LSR1 and the second light separation region LSR2.

The passivation layer 116 disposed at the one or more first light separation region LSR1 at each of the first to fourth subpixels SP1, SP2, SP3, and SP4 according to an embodiment of the present disclosure can have the same thickness, but embodiments of the present disclosure are not limited thereto. For example, the passivation layer 116 disposed at the one or more first light separation regions LSR1 at each of the first to fourth subpixels SP1, SP2, SP3, and SP4, as described above with reference to FIG. 10, can have different thicknesses.

In each of the first to fourth subpixels SP1, SP2, SP3, and SP4, first reflection light Lre1 reflected from the light extraction pattern 140 to the first light separation region LSR1 can pass through the first filter region of the color filter layer 150 and a region where the passivation layer 116 and the first buffer layer 112a are not disposed, and thus, one or more of an amplitude, a velocity, a phase, and a path of a wavelength (or an optical wave) can be changed. Second reflection light Lre2 reflected from the light extraction pattern 140 to the second light separation region LSR2 can pass through the second filter region of the color filter layer 150 and the region 116r where the passivation layer 116 is not disposed, and thus, one or more of an amplitude, a velocity, a phase, and a path of a wavelength (or an optical wave) can be changed to be different from the first reflection light Lre1. Accordingly, the reflection light Lre1 and the reflection light Lre2 can be optically divided (or separated) due to one or more of an amplitude difference, a velocity difference, a phase difference, and a path difference of a wavelength (or an optical wave), and thus, a probability of occurrence of constructive interference (or light interference) occurring between the reflection light Lre1 and the reflection light Lre2 can more decrease or a probability of occurrence of destructive interference can more increase.

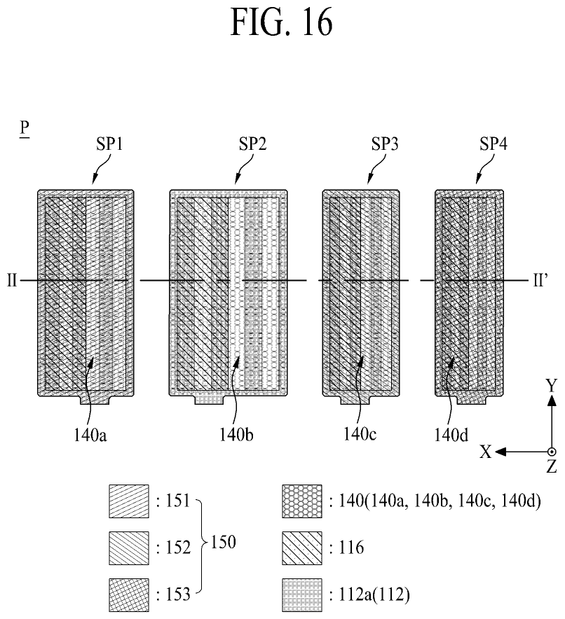

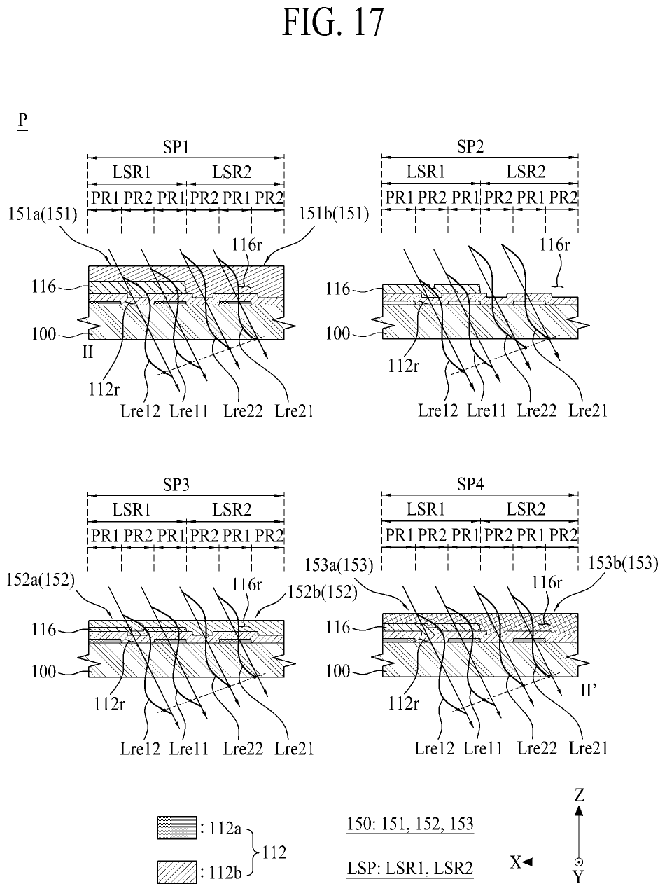

FIG. 16 is a diagram illustrating a light separation portion according to another embodiment of the present disclosure. FIG. 17 is a cross-sectional view taken along line II-II′ illustrating a light separation portion at each of first to fourth subpixels illustrated in FIG. 16. Here, FIGS. 16 and 17 illustrate an embodiment implemented by modifying a light separation portion described above with reference to FIGS. 7 to 9. Therefore, in the following description, descriptions of the other elements except a light separation portion and relevant elements can be the same as the descriptions of FIGS. 7 to 9, and thus, repeated descriptions thereof are omitted or will be briefly given.

Referring to FIGS. 16 and 17, a light separation portion LSP according to another embodiment (or a fifth embodiment) of the present disclosure can include a first light separation region LSR1, a second light separation region LSR2, a plurality of first pattern regions PR1, and a plurality of second pattern regions PR2, which are disposed at first to fourth subpixels (or a plurality of subpixels) SP1, SP2, SP3, and SP4 of each of a plurality of pixels P.

In the first to fourth subpixels SP1, SP2, SP3, and SP4, the first light separation region LSR1 and the second light separation region LSR2 can be disposed along a first direction X. For example, with respect to the first direction X, the first light separation region LSR1 can be a left region of each of the first to fourth subpixels SP1, SP2, SP3, and SP4, and the second light separation region LSR2 can be a right region of each of the first to fourth subpixels SP1, SP2, SP3, and SP4. For example, an emission area EA of each of the first to fourth subpixels SP1, SP2, SP3, and SP4 can have a left-right two-division structure (or a horizontal two-division structure) by the first light separation region LSR1 and the second light separation region LSR2. For example, the first light separation region LSR1 and the second light separation region LSR2 can have a same size (or area), but embodiments of the present disclosure are not limited thereto. For example, the first light separation region LSR1 and the second light separation region LSR2 can have different refractive indexes, but embodiments of the present disclosure are not limited thereto. For example, the first light separation region LSR1 and the second light separation region LSR2 can have a refractive index difference of 0.1 or more therebetween, but embodiments of the present disclosure are not limited thereto.

Each of the first light separation region LSR1 and the second light separation region LSR2 can be additionally divided by the plurality of first pattern regions PR1 and the plurality of second pattern regions PR2. The plurality of first pattern regions PR1 and the plurality of second pattern regions PR2 can be disposed or configured in parallel with the first light separation region LSR1 and the second light separation region LSR2. The plurality of first pattern regions PR1 and the plurality of second pattern regions PR2 can be alternately disposed along the first direction X and can extend along a second direction Y. Accordingly, each of the first light separation region LSR1 and the second light separation region LSR2 can include one or more first pattern regions PR1 and one or more second pattern regions PR2. For example, the plurality of first pattern regions PR1 and the plurality of second pattern regions PR2 can have a same size (or area), but embodiments of the present disclosure are not limited thereto. For example, the plurality of first pattern regions PR1 and the plurality of second pattern regions PR2 can be configured to be disposed at a buffer layer 112.

The first light separation region LSR1 and the second light separation region LSR2 of the light separation portion LSP at each of the first, third, and fourth subpixels (or a plurality of color subpixels) SP1, SP3, and SP4 can be formed or configured at a buffer layer 112, a passivation layer 116, and a color filter layer 150 between the substrate 100 and the light extraction pattern 140. The first light separation region LSR1 and the second light separation region LSR2 of the light separation portion LSP at the second subpixel (or a white color subpixel) SP2 can be formed or configured at the buffer layer 112 and the passivation layer 116 between the substrate 100 and the light extraction pattern 140.

The passivation layer 116 and the color filter layer 150 disposed at the first light separation region LSR1 and the second light separation region LSR2 can be a same or substantially a same as the passivation layer 116 and the color filter layer 150 described above with reference to FIGS. 13 to 15, and thus, repeated descriptions thereof are omitted.

In each of the first to fourth subpixels SP1, SP2, SP3, and SP4, the buffer layer (or an insulation layer) 112 can include a first buffer layer (or a first insulation layer) 112a which is disposed at the plurality of first pattern regions PR1 and is not disposed at the plurality of second pattern regions PR2, and a second buffer layer (or a second insulation layer) 112b which covers the first buffer layer 112a and a region (or a non-disposition region) where the first buffer layer 112a is not disposed.

The buffer layer 112 and the passivation layer 116 can be configured to include materials having different refractive indexes. For example, the buffer layer 112 and the passivation layer 116 can be configured to include materials having a refractive index difference of 0.1 or more therebetween. For example, each of the first buffer layer 112a and the second buffer layer 112b of the buffer layer 112 and the passivation layer 116 can be configured to include materials having a refractive index difference of 0.1 or more between each of the first buffer layer 112a and the second buffer layer 112b and the passivation layer 116. The first buffer layer 112a and the second buffer layer 112b can be configured to include materials having different refractive indexes. For example, the first buffer layer 112a and the second buffer layer 112b can be configured to include materials having a refractive index difference of 0.1 or more therebetween.

In each of the first to fourth subpixels SP1, SP2, SP3, and SP4, the first buffer layer 112a can be disposed at each of the plurality of first pattern regions PR1 which is at each of the first and second light separation regions LSR1 and LSR2, and may not be disposed at each of the plurality of second pattern regions PR2 which is at each of the first and second light separation regions LSR1 and LSR2. In each of the first and second light separation regions LSR1 and LSR2, each of the plurality of first pattern regions PR1 can include a region (or a disposition region) where the first buffer layer 112a is disposed, and each of the plurality of second pattern regions PR2 can include a region (or a removal region) 112r from which the first buffer layer 112a has been removed.

The first buffer layer 112a can be disposed at each of the plurality of first pattern regions PR1, and thus, can be disposed at a portion of each of the first light separation region LSR1 and the second light separation region LSR2. Except for that the first buffer layer 112a is disposed at the plurality of first pattern regions PR1 which additionally divides the first light separation region LSR1 and the second light separation region LSR2, the first buffer layer 112a can be a same or substantially a same as the first buffer layer 112a described above with reference to FIGS. 13 to 15, and thus, repeated descriptions thereof are omitted.

The first buffer layer 112a can overlap a portion of the passivation layer 116 at the first light separation region LSR1. The first buffer layer 112a disposed at one or more first pattern regions PR1 in the first light separation region LSR1 can be configured to cause a phase difference and/or a path difference between reflection lights Lre11 and Lre12 passing through the first light separation region LSR1. The first buffer layer 112a disposed at one or more first pattern regions PR1 in the second light separation region LSR2 can be configured to cause a phase difference and/or a path difference between reflection lights Lre21 and Lre22 passing through the second light separation region LSR2.

In each of the first to fourth subpixels SP1, SP2, SP3, and SP4, a 1-1 reflection light Lre11 reflected from the light extraction pattern 140 to the one or more first pattern regions PR1 of the first light separation region LSR1 can pass through the first filter region of the color filter layer 150, the passivation layer 116, and the first buffer layer 112a, and thus, one or more of an amplitude, a velocity, a phase, and a path of a wavelength (or an optical wave) can be changed. The 1-2 reflection light Lre12 reflected from the light extraction pattern 140 to the one or more second pattern regions PR2 of the first light separation region LSR1 can pass through the first filter region of the color filter layer 150, the passivation layer 116, and the region 112r where the first buffer layer 112a is not disposed, and thus, one or more of an amplitude, a velocity, a phase, and a path of a wavelength (or an optical wave) can be changed to be different from the 1-1 reflection light Lre11.

In each of the first to fourth subpixels SP1, SP2, SP3, and SP4, a 2-1 reflection light Lre21 reflected from the light extraction pattern 140 to the one or more first pattern regions PR1 of the second light separation region LSR2 can pass through the second filter region of the color filter layer 150 and the first buffer layer 112a, and thus, one or more of an amplitude, a velocity, a phase, and a path of a wavelength (or an optical wave) can be changed to be different from the 1-1 reflection light Lre11 and the 1-2 reflection light Lre12. The 2-2 reflection light Lre22 reflected from the light extraction pattern 140 to the one or more second pattern regions PR2 of the second light separation region LSR2 can pass through the second filter region of the color filter layer 150 and the region 112r where the first buffer layer 112a is not disposed, and thus, one or more of an amplitude, a velocity, a phase, and a path of a wavelength (or an optical wave) can be changed to be different from the 1-2 reflection light Lre12 and the 2-1 reflection light Lre21.

Therefore, the 1-1 and 1-2 reflection lights Lre11 and Lre12 and the 2-1 and 2-2 reflection lights Lre21 and Lre22 discharged (or extracted) to the outside of a substrate 100 through the first and second light separation regions LSR1 and LSR2 from the light extraction pattern 140 can optically and multiply divide (or separate) due to one or more of the amplitude difference, the velocity difference, the phase difference, and the path difference of the wavelength (or an optical wave), and thus, a probability of occurrence of constructive interference (or light interference) occurring between the 1-1 and 1-2 reflection lights Lre11 and Lre12 and the 2-1 and 2-2 reflection lights Lre21 and Lre22 can more decrease or a probability of occurrence of destructive interference can more increase.

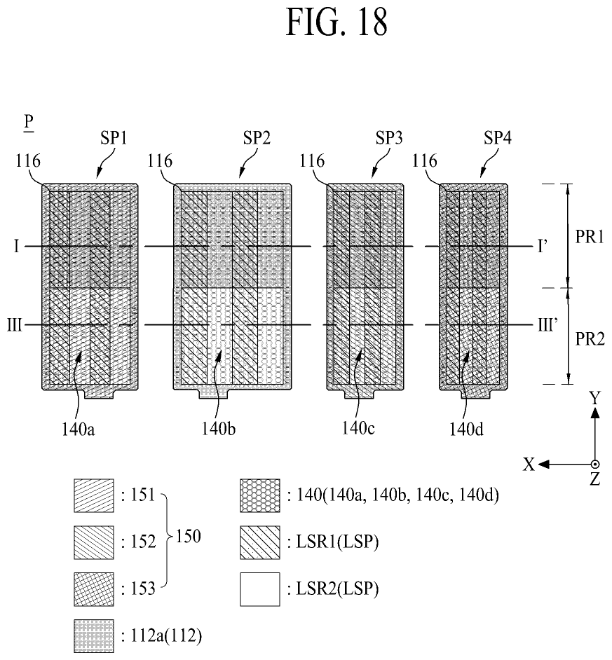

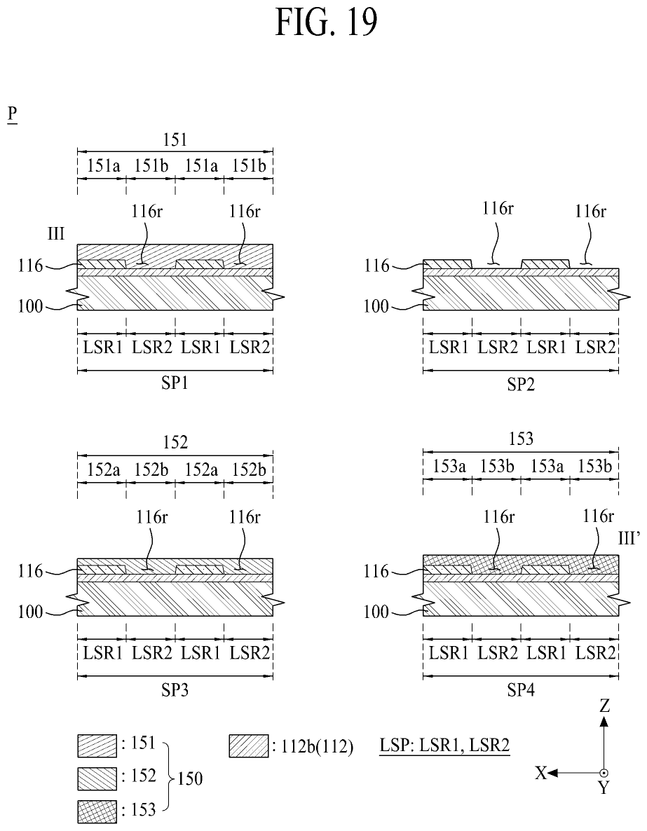

FIG. 18 is a diagram illustrating a light separation portion according to another embodiment of the present disclosure. FIG. 19 is a cross-sectional view taken along line III-III′ illustrating a light separation portion at the first to fourth subpixels illustrated in FIG. 18. Here, FIGS. 18 and 19 illustrate an embodiment implemented by modifying a light separation portion described above with reference to FIGS. 13 to 15. Therefore, in the following description, descriptions of the other elements except a light separation portion and relevant elements can be the same as the descriptions of FIGS. 11 and 12, and thus, repeated descriptions thereof are omitted or will be briefly given. A cross-sectional surface taken along line I-I′ illustrated in FIG. 18 is illustrated in FIG. 12.

Referring to FIGS. 12, 18, and 19, a light separation portion LSP according to another embodiment (or a sixth embodiment) of the present disclosure can include one or more (or a plurality of) first light separation regions LSR1, one or more (or a plurality of) second light separation regions LSR2, a first pattern region PR1, and a second pattern region PR2, which are disposed at first to fourth subpixels (or a plurality of subpixels) SP1 to SP4 of each of a plurality of pixels P.

In each of first to fourth subpixels SP1, SP2, SP3, and SP4, the one or more first light separation region LSR1 and the one or more second light separation region LSR2 can be disposed along a first direction X. For example, when the light separation portion LSP includes a plurality of first light separation regions LSR1 and a plurality of second light separation regions LSR2, the plurality of first light separation regions LSR1 and the plurality of second light separation regions LSR2 can be alternately disposed along the first direction X. For example, the one or more (or the plurality of) first light separation regions LSR1 and the one or more (or the plurality of) second light separation regions LSR2 can have a same size (or area), but embodiments of the present disclosure are not limited thereto. For example, the one or more (or the plurality of) first light separation regions LSR1 and the one or more (or the plurality of) second light separation regions LSR2 can have different refractive indexes, but embodiments of the present disclosure are not limited thereto. For example, the one or more (or the plurality of) first light separation regions LSR1 and the one or more (or the plurality of) second light separation regions LSR2 can have a refractive index difference of 0.1 or more therebetween, but embodiments of the present disclosure are not limited thereto.

Each of the first light separation region LSR1 and the second light separation region LSR2 can be additionally divided by the first pattern region PR1 and the second pattern region PR2. The first pattern region PR1 and the second pattern region PR2 can be disposed or configured to intersect with the one or more (or the plurality of) first light separation regions LSR1 and the one or more (or the plurality of) second light separation regions LSR2. The first pattern region PR1 and the second pattern region PR2 can be disposed along a second direction Y. Accordingly, each of the one or more (or the plurality of) first light separation regions LSR1 and the one or more (or the plurality of) second light separation regions LSR2 can include the first pattern region PR1 and the second pattern region PR2.

With respect to the second direction Y, the first pattern region PR1 can be an upper region (or a top region) of each of first to fourth subpixels SP1, SP2, SP3, and SP4, and the second pattern region PR2 can be a lower region (or a bottom region) of each of the first to fourth subpixels SP1, SP2, SP3, and SP4. For example, the first pattern region PR1 and the second pattern region PR2 can have a same size (or area), but embodiments of the present disclosure are not limited thereto. For example, the first pattern region PR1 and the second pattern region PR2 can be formed or configured at a buffer layer 112.

The one or more (or the plurality of) first light separation regions LSR1 and the one or more (or the plurality of) second light separation regions LSR2 at each of the first, third, and fourth subpixels (or a plurality of color subpixels) SP1, SP3, and SP4 can be formed or configured at the buffer layer 112, a passivation layer 116, and a color filter layer 150 between the substrate 100 and the light extraction pattern 140. The one or more (or the plurality of) first light separation regions LSR1 and the one or more (or the plurality of) second light separation regions LSR2 at the second subpixel (or a white color subpixel) SP2 can be formed or configured at the buffer layer 112 and the passivation layer 116 between the substrate 100 and the light extraction pattern 140.

The passivation layer 116 and the color filter layer 150 disposed at the one or more (or the plurality of) first light separation regions LSR1 and the one or more (or the plurality of) second light separation regions LSR2 can be a same or substantially a same as the passivation layer 116 and the color filter layer 150 described above with reference to FIGS. 11 and 12, and thus, repeated descriptions thereof are omitted.

In each of the first to fourth subpixels SP1, SP2, SP3, and SP4, the buffer layer (or an insulation layer) 112 can include a first buffer layer (or a first insulation layer) 112a which is disposed at the first pattern region PR1 and is not disposed at the second pattern region PR2, and a second buffer layer (or a second insulation layer) 112b which covers the first buffer layer 112a and a region (or a non-disposition region) where the first buffer layer 112a is not disposed.

The buffer layer 112 and the passivation layer 116 can be configured to include materials having different refractive indexes. For example, the buffer layer 112 and the passivation layer 116 can be configured to include materials having a refractive index difference of 0.1 or more therebetween. For example, each of the first buffer layer 112a and the second buffer layer 112b of the buffer layer 112 and the passivation layer 116 can be configured to include materials having a refractive index difference of 0.1 or more between each of the first buffer layer 112a and the second buffer layer 112b and the passivation layer 116. The first buffer layer 112a and the second buffer layer 112b can be configured to include materials having different refractive indexes. For example, the first buffer layer 112a and the second buffer layer 112b can be configured to include materials having a refractive index difference of 0.1 or more therebetween.

In each of the first to fourth subpixels SP1, SP2, SP3, and SP4, the first buffer layer 112a can be disposed at the first pattern region PR1 which is at each of the one or more (or the plurality of) first and second light separation regions LSR1 and LSR2, and may not be disposed at the second pattern region PR2 which is at each of the one or more (or the plurality of) first and second light separation regions LSR1 and LSR2. In each of the one or more (or the plurality of) first and second light separation regions LSR1 and LSR2, the first pattern region PR1 can include a region (or a disposition region) where the first buffer layer 112a is disposed, and the second pattern region PR2 can include a region (or a removal region) 112r from which the first buffer layer 112a has been removed.

The first buffer layer 112a can be disposed at the first pattern region PR1, and thus, can be disposed at a portion of each of the one or more (or the plurality of) first light separation regions LSR1 and the second light separation region LSR2. Except for that the first buffer layer 112a is disposed at the first pattern region PR1 which additionally divides the one or more (or the plurality of) first light separation regions LSR1 and the one or more (or the plurality of) second light separation regions LSR2, the first buffer layer 112a can be a same or substantially a same as the first buffer layer 112a described above with reference to FIGS. 13 to 15, and thus, repeated descriptions thereof are omitted.

The first buffer layer 112a can overlap a portion of the passivation layer 116 at the one or more (or the plurality of) first light separation regions LSR1. The first buffer layer 112a disposed at the first pattern region PR1 in the one or more (or the plurality of) first light separation regions LSR1 can be configured to cause a phase difference and/or a path difference between reflection lights passing through the one or more (or the plurality of) first light separation regions LSR1. The first buffer layer 112a disposed at the first pattern region PR1 in the one or more (or the plurality of) second light separation regions LSR2 can be configured to cause a phase difference and/or a path difference between reflection lights passing through the one or more (or the plurality of) second light separation regions LSR2.

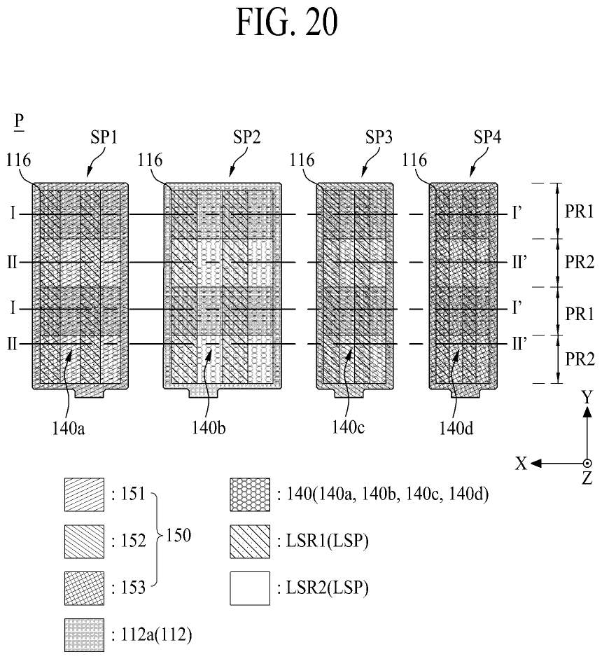

According to another embodiment of the present disclosure, in FIGS. 18 and 19, the light separation portion LSP include one first pattern region PR1 and one second pattern region PR2, but embodiments of the present disclosure are not limited thereto. For example, as illustrated in FIG. 20, the light separation portion LSP according to another embodiment of the present disclosure can include a plurality of first pattern regions PR1 and a plurality of the second pattern regions PR2.

Each of the first light separation region LSR1 and the second light separation region LSR2 can be additionally divided by the plurality of first pattern regions PR1 and the plurality of second pattern regions PR2. The plurality of first pattern regions PR1 and the plurality of second pattern regions PR2 can be disposed or configured to intersect with the one or more (or the plurality of) first light separation regions LSR1 and the one or more (or the plurality of) second light separation regions LSR2. The plurality of first pattern regions PR1 and the plurality of second pattern regions PR2 can be alternately disposed along the second direction Y. Accordingly, each of the one or more (or the plurality of) first light separation regions LSR1 and the one or more (or the plurality of) second light separation regions LSR2 can include the plurality of first pattern regions PR1 and the plurality of second pattern regions PR2.

Therefore, as described above with reference to FIGS. 16 and 17, reflection lights discharged (or extracted) to the outside of a substrate 100 through the one or more (or the plurality of) first and second light separation regions LSR1 and LSR2 from the light extraction pattern 140 can optically and multiply divide (or separate) due to one or more of an amplitude difference, a velocity difference, a phase difference, and a path difference of a wavelength (or an optical wave), and thus, a probability of occurrence of constructive interference (or light interference) occurring between the reflection lights can more decrease or a probability of occurrence of destructive interference can more increase.

FIG. 21 is a diagram illustrating a light separation portion according to another embodiment of the present disclosure. Here, FIG. 21 illustrates an embodiment implemented by modifying a light separation portion described above with reference to FIGS. 7 to 12.

Referring to FIG. 21, a light separation portion LSP according to another embodiment (or a seventh embodiment) of the present disclosure can include a plurality of first light separation regions LSR1 and a plurality of second light separation regions LSR2, which are disposed at first to fourth subpixels (or a plurality of subpixels) SP1, SP2, SP3, and SP4 of each of a plurality of pixels P.

The plurality of first light separation regions LSR1 and the plurality of second light separation regions LSR2 can be alternately disposed or configured along a first direction X and a second direction Y. For example, the plurality of first light separation regions LSR1 and the plurality of second light separation regions LSR2 can be alternately disposed or configured at an emission area of each of the first to fourth subpixels SP1, SP2, SP3, and SP4 along the first direction X and the second direction Y.

The plurality of first light separation regions LSR1 can be disposed or configured along the emission area of each of the first to fourth subpixels SP1, SP2, SP3, and SP4 to have a certain interval along the first direction X and the second direction Y. For example, the plurality of first light separation regions LSR1 can be disposed or configured in a grating pattern shape or a checkered pattern shape at the emission area of each of the first to fourth subpixels SP1, SP2, SP3, and SP4.

The plurality of second light separation regions LSR2 can be disposed or configured between the plurality of first light separation regions LSR1 to have a certain interval along the first direction X and the second direction Y.

Each of the plurality of first light separation regions LSR1 and the plurality of second light separation regions LSR2 can be configured to have a tetragonal shape. For example, each of the plurality of first light separation regions LSR1 and the plurality of second light separation regions LSR2 can have a tetragonal pattern. For example, the plurality of first light separation regions LSR1 can have a same size (or area), or can have different sizes (or areas). For example, the plurality of second light separation regions LSR2 can have a same size (or area), or can have different sizes (or areas). For example, the plurality of first light separation regions LSR1 can have a same refractive index. For example, the plurality of second light separation regions LSR2 can have a same refractive index. For example, the plurality of first light separation regions LSR1 and the plurality of second light separation regions LSR2 can have different refractive indexes, but embodiments according to present disclosure are not limited thereto. For example, the plurality of first light separation regions LSR1 and the plurality of second light separation regions LSR2 can have a refractive index difference of 0.1 or more, but embodiments according to present disclosure are not limited thereto.

Each of the plurality of first light separation regions LSR1 and the plurality of second light separation regions LSR2 can overlap or overlay a convex portion or a concave portion of a light extraction pattern 140 disposed at each of the first to fourth subpixels SP1, SP2, SP3, and SP4. Accordingly, reflection light reflected from the convex portion or the concave portion of the light extraction pattern 140 can have a different phase or light path based on the plurality of first light separation regions LSR1 and the plurality of second light separation regions LSR2.

Therefore, each of the plurality of first light separation regions LSR1 and the plurality of second light separation regions LSR2 can optically divide reflection lights reflected from the light extraction patterns 140 to more increase the irregularity or randomness of a diffraction pattern of each of the reflection lights, and thus, the occurrence of rainbow Mura where reflection light is spread in a radial shape and/or circular ring Mura where reflection light is spread in a radial shape can be better prevented or more minimized based on a diffraction characteristic of each of the reflection lights reflected from the light extraction patterns 140.

According to an embodiment of the present disclosure, the light separation portion LSP or the plurality of first light separation regions LSR1 and the plurality of second light separation regions LSR2 can be configured at a passivation layer 116 and a color filter layer 150.

Each of the plurality of first light separation regions LSR1 can include a passivation layer 116 and a first filter region of the color filter layer 150. Each of the plurality of first light separation regions LSR1 can include a region where the passivation layer 116 is disposed, and a first filter region of the color filter layer 150. Each of the plurality of second light separation regions LSR2 can include a region where the passivation layer 116 is not disposed, and a second filter region of the color filter layer 150. Each of the plurality of second light separation regions LSR2 can include a region (or a removal region) 116r from which the passivation layer 116 has been removed, and a second filter region of the color filter layer 150. The plurality of first light separation regions LSR1 and the plurality of second light separation regions LSR2 can be a same or substantially a same as the first light separation region LSR1 and the second light separation region LSR2 described above with reference to FIGS. 7 to 12 except for being respectively disposed or configured in a grating pattern shape at each of the first to fourth subpixels SP1, SP2, SP3, and SP4, and thus, repeated descriptions thereof are omitted. The descriptions of the light separation portion LSP or the first light separation region LSR1 and the second light separation region LSR2 illustrated in FIGS. 7 to 12 can be included in the descriptions of the light separation portion LSP or the plurality of first light separation regions LSR1 and the plurality of second light separation regions LSR2 illustrated in FIG. 21.

As described above, the light separation portion LSP according to another embodiment of the present disclosure can have or provide a same effect as that of the light separation portion LSP described above with reference to FIGS. 7 to 12, and can optically and multiply divide (or separate) reflection light which is reflected from the light extraction pattern 140 by the plurality of first light separation regions LSR1 and the plurality of second light separation regions LSR2, and thus, a probability of occurrence of constructive interference (or light interference) occurring between the reflection lights can more decrease or a probability of occurrence of destructive interference can more increase.

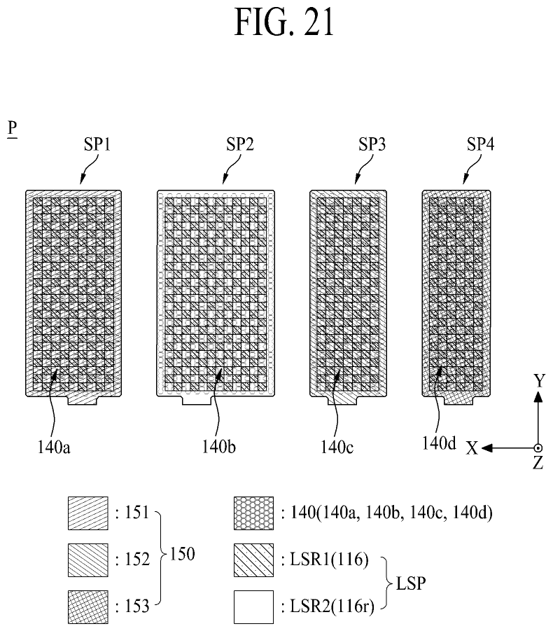

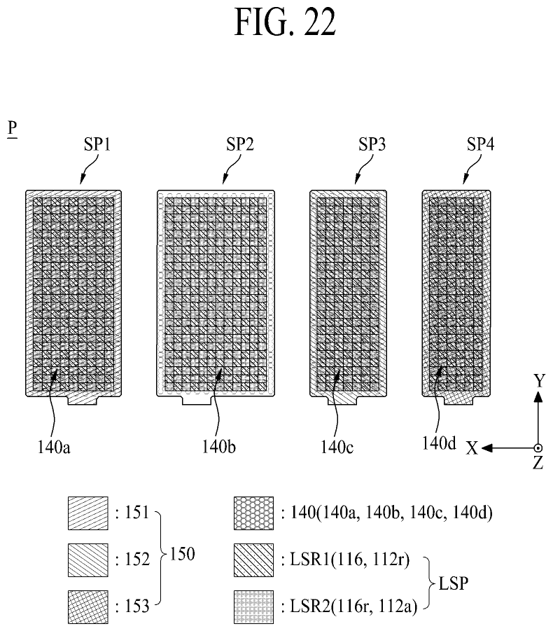

FIG. 22 is a diagram illustrating a light separation portion according to another embodiment of the present disclosure. Here, FIG. 22 illustrates an embodiment implemented by modifying the light separation portion described above with reference to FIG. 21.

Referring to FIG. 22, a light separation portion LSP according to another embodiment (or an eighth embodiment) of the present disclosure can include a plurality of first light separation regions LSR1 and a plurality of second light separation regions LSR2, which are disposed at first to fourth subpixels (or a plurality of subpixels) SP1, SP2, SP3, and SP4 of each of a plurality of pixels P.

The plurality of first light separation regions LSR1 can be disposed or configured in a grating pattern shape or a checkered pattern shape at an emission area of each of the first to fourth subpixels SP1, SP2, SP3, and SP4. The plurality of second light separation regions LSR2 can be disposed or configured between the plurality of first light separation regions LSR1 to have a certain interval along the first direction X and the second direction Y. An arrangement structure of the plurality of first light separation regions LSR1 and the plurality of second light separation regions LSR2 can be a same or substantially a same as an arrangement structure of the plurality of first light separation regions LSR1 and the plurality of second light separation regions LSR2 described above with reference to FIG. 21, and thus, repeated descriptions thereof are omitted.

The light separation portion LSP or the plurality of first light separation regions LSR1 and the plurality of second light separation regions LSR2 can be configured at a buffer layer 112, a passivation layer 116, and a color filter layer 150.

Each of the plurality of first light separation regions LSR1 can include a passivation layer 116 and a first filter region of the color filter layer 150. Each of the plurality of first light separation regions LSR1 can include a region where the passivation layer 116 is disposed, and a first filter region of the color filter layer 150. Each of the plurality of second light separation regions LSR2 can include a region where the passivation layer 116 is not disposed, and a second filter region of the color filter layer 150. Each of the plurality of second light separation regions LSR2 can include a region (or a removal region) 116r from which the passivation layer 116 has been removed, and a second filter region of the color filter layer 150. The plurality of first light separation regions LSR1 and the plurality of second light separation regions LSR2 can be a same or substantially a same as the first light separation region LSR1 and the second light separation region LSR2 described above with reference to FIGS. 7 to 12 except for being respectively disposed or configured in a grating pattern shape at each of the first to fourth subpixels SP1, SP2, SP3, and SP4, and thus, repeated descriptions thereof are omitted. The descriptions of the light separation portion LSP or the first light separation region LSR1 and the second light separation region LSR2 illustrated in FIGS. 7 to 12 can be included in the descriptions of the light separation portion LSP or the plurality of first light separation regions LSR1 and the plurality of second light separation regions LSR2 illustrated in FIG. 21.

As described above, the light separation portion LSP according to another embodiment of the present disclosure can have or provide a same effect as that of the light separation portion LSP described above with reference to FIG. 21 and the light separation portion LSP described above with reference to FIGS. 13 to 15, and can optically and multiply divide (or separate) reflection light which is reflected from the light extraction pattern 140 by the plurality of first light separation regions LSR1 and the plurality of second light separation regions LSR2, and thus, a probability of occurrence of constructive interference (or light interference) occurring between the reflection lights can more decrease or a probability of occurrence of destructive interference can more increase.

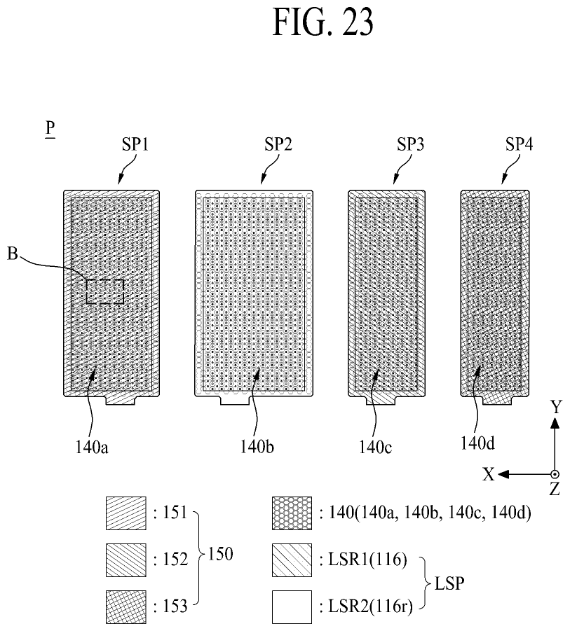

FIG. 23 is a diagram illustrating a light separation portion according to another embodiment of the present disclosure. FIG. 24 is an enlarged view of a region ‘B’ illustrated in FIG. 23. Here, FIGS. 23 and 24 illustrate an embodiment implemented by modifying the light separation portion described above with reference to FIGS. 7 to 12.

Referring to FIGS. 23 and 24, a light separation portion LSP according to another embodiment (or a ninth embodiment) of the present disclosure can include a plurality of first light separation regions LSR1 and a second light separation region LSR2, which are disposed at first to fourth subpixels (or a plurality of subpixels) SP1, SP2, SP3, and SP4 of each of a plurality of pixels P.

The plurality of first light separation regions LSR1 can be disposed to have a certain interval along a second direction Y and can be disposed to be staggered along a first direction X. For example, the plurality of first light separation regions LSR1 can be disposed to have a certain interval along a diagonal direction between the first direction X and the second direction Y. For example, each of the plurality of first light separation regions LSR1 disposed at even-numbered horizontal lines parallel to the first direction X can be disposed between the plurality of first light separation regions LSR1 disposed at adjacent odd-numbered horizontal lines along the second direction Y. Accordingly, the plurality of first light separation regions LSR1 are disposed in a zigzag shape along the first direction X.

Each of the plurality of first light separation regions LSR1 can have a same shape as that of each of a plurality of concave portions 141 in light extraction patterns 140 disposed in first to fourth subpixels SP1, SP2, SP3, and SP4 of each of a plurality of pixels P, but embodiments of the present disclosure are not limited thereto. For example, each of the plurality of first light separation regions LSR1 can have a same hexagonal shape as that of the concave portion 141, but is not limited thereto and can have a circular shape, an oval shape, or a three or more-angled polygonal shape.

Each of the plurality of first light separation regions LSR1 can have a size which is a same as or different from that of each of the plurality of concave portions 141. For example, each of the plurality of first light separation regions LSR1 can have a hexagonal shape which is less than the concave portion 141, but is not limited thereto and can have a circular shape, an oval shape, or a three or more-angled polygonal shape, which is smaller than the concave portion 141.

Each of the plurality of first light separation regions LSR1 can overlap at least a portion of a corresponding concave portion 141 of the plurality of concave portions 141. A center portion CP of each of the plurality of first light separation regions LSR1 can be disposed or aligned at a center portion CP of a corresponding concave portion 141 of the plurality of concave portions 141. Accordingly, each of the plurality of first light separation regions LSR1 can correspond to, in a one-to-one relationship, each of the plurality of concave portions 141 of the light extraction pattern 140 disposed in the emission area of each of the first to fourth subpixels SP1, SP2, SP3, and SP4. For example, the plurality of first light separation regions LSR1 can be disposed or arranged in a honeycomb structure, a hexagonal structure, or a circular structure in two-dimensions (or in a plan view).

The second light separation region LSR2 can include a region between the plurality of first light separation regions LSR1. For example, the second light separation region LSR2 can include the other region, except the plurality of first light separation regions LSR1, of the emission area of the first to fourth subpixels SP1, SP2, SP3, and SP4. Accordingly, each of the plurality of first light separation regions LSR1 can be surrounded by the second light separation region LSR2. For example, the second light separation region LSR2 can overlap or overlay a convex portion 143 of the light extraction pattern 140. The second light separation region LSR2 can overlap or overlay the convex portion 143 and the other portion, except a center portion, of each of the plurality of concave portions 141 of the light extraction pattern 140.

The plurality of first light separation regions LSR1 can have a same refractive index. For example, the plurality of first light separation regions LSR1 and the plurality of second light separation regions LSR2 can have different refractive indexes, but embodiments according to present disclosure are not limited thereto. For example, the plurality of first light separation regions LSR1 and the plurality of second light separation regions LSR2 can have a refractive index difference of 0.1 or more, but embodiments according to present disclosure are not limited thereto.

According to an embodiment of the present disclosure, reflection light reflected from the concave portion 141 of the light extraction pattern 140 can pass through each of the plurality of first light separation regions LSR1. Reflection lights reflected from the convex portion 143 of the light extraction pattern 140 can pass through the second light separation region LSR2. Accordingly, reflection light reflected from the convex portion 143 or the concave portion 141 of the light extraction pattern 140 can have a different phase or light path, based on the plurality of first light separation regions LSR1 and the second light separation region LSR2.

Therefore, each of the plurality of first light separation regions LSR1 and the second light separation region LSR2 can optically and multiply divide (or separate) reflection lights reflected from the light extraction patterns 140 to more increase the irregularity or randomness of a diffraction pattern of each of the reflection lights, and thus, the occurrence of rainbow Mura where reflection light is spread in a radial shape and/or circular ring Mura where reflection light is spread in a radial shape can be better prevented or more minimized based on a diffraction characteristic of each of the reflection lights reflected from the light extraction patterns 140.

According to an embodiment of the present disclosure, the light separation portion LSP or the plurality of first light separation regions LSR1 and the second light separation region LSR2 can be configured at a passivation layer 116 and a color filter layer 150.

Each of the plurality of first light separation regions LSR1 can include a passivation layer 116 and a first filter region of the color filter layer 150. Each of the plurality of first light separation regions LSR1 can include a region where the passivation layer 116 is disposed, and a first filter region of the color filter layer 150. Each of the plurality of second light separation regions LSR2 can include a region where the passivation layer 116 is not disposed, and a second filter region of the color filter layer 150. Each of the plurality of second light separation regions LSR2 can include a region (or a removal region) 116r from which the passivation layer 116 has been removed, and a second filter region of the color filter layer 150.

The plurality of first light separation regions LSR1 and the second light separation region LSR2 can be a same or substantially a same as the first light separation region LSR1 and the second light separation region LSR2 described above with reference to FIGS. 7 to 12 except for being respectively disposed or configured in a honeycomb structure at each of the first to fourth subpixels SP1, SP2, SP3, and SP4, and thus, repeated descriptions thereof are omitted. The descriptions of the light separation portion LSP or the first light separation region LSR1 and the second light separation region LSR2 illustrated in FIGS. 7 to 12 can be included in the descriptions of the light separation portion LSP or the plurality of first light separation regions LSR1 and the second light separation region LSR2 illustrated in FIG. 23.

In FIGS. 23 and 24, the light separation portion LSP according to another embodiment of the present disclosure has been described as including the plurality of first light separation regions LSR1 and the second light separation region LSR2, but embodiments of the present disclosure are not limited thereto. For example, the light separation portion LSP according to another embodiment of the present disclosure can include a first light separation region LSR1 and a plurality of second light separation regions LSR2. For example, the plurality of first light separation regions LSR1 described above with reference to FIGS. 23 and 24 can be changed to a plurality of second light separation regions LSR2, and the second light separation region LSR2 can be changed to a first light separation region LSR1.

As described above, the light separation portion LSP according to another embodiment of the present disclosure can have or provide a same effect as that of the light separation portion LSP described above with reference to FIGS. 7 to 12, and can optically and multiply divide (or separate) reflection light which is reflected from the light extraction pattern 140 by the plurality of first light separation regions LSR1 and the plurality of second light separation regions LSR2, and thus, a probability of occurrence of constructive interference (or light interference) occurring between the reflection lights can more decrease or a probability of occurrence of destructive interference can more increase.

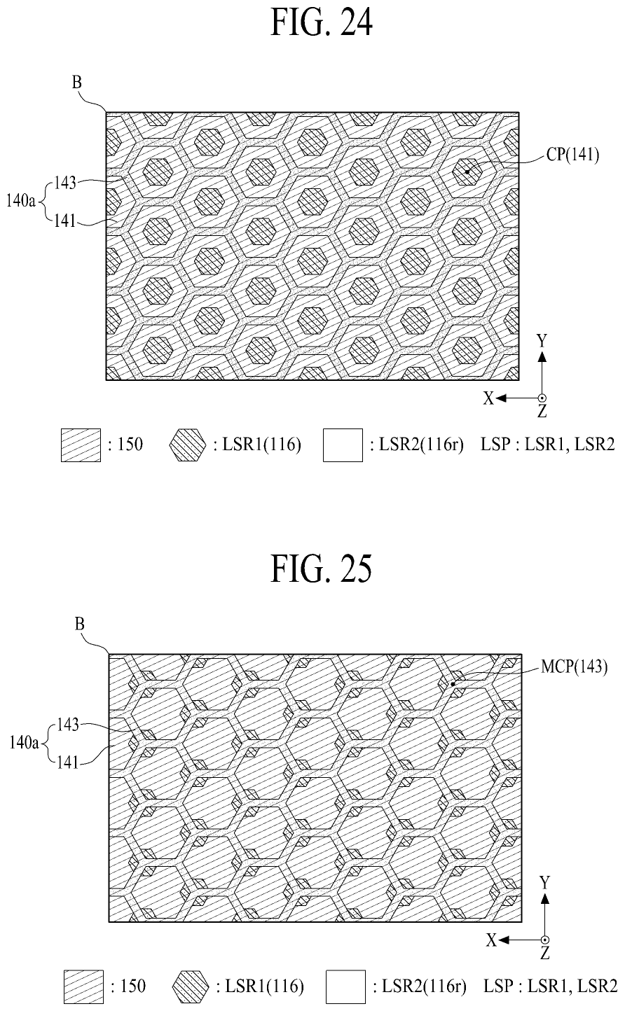

FIG. 25 is another enlarged view of a region ‘B’ illustrated in FIG. 23. Here, FIG. 25 illustrates an embodiment implemented by changing a position of each of a plurality of first light separation regions in the light separation portion described above with reference to FIGS. 23 and 24. Therefore, in the following description, except for a position of each of a plurality of first light separation regions, descriptions of the other elements can be the same as the descriptions of FIGS. 23 and 24, and thus, repeated descriptions can be omitted or will be briefly given.

Referring to FIG. 25, in a light separation portion LSP according to another embodiment of the present disclosure, each of a plurality of first light separation regions LSR1 can be disposed or configured to overlap or overlay a convex portion 143 of a light extraction pattern 140.

According to an embodiment of the present disclosure, a center portion of each of the plurality of first light separation regions LSR1 can be disposed or configured to overlap or overlay the convex portion 143 of the light extraction pattern 140. The center portion of each of the plurality of first light separation regions LSR1 can be disposed or configured to overlap or overlay the convex portion 143 between three adjacent concave portions 141 of the light extraction pattern 140. For example, the center portion of each of the plurality of first light separation regions LSR1 can be disposed or configured to overlap or overlay a center portion MCP of the convex portion 143 between three adjacent concave portions 141 of the light extraction pattern 140.

According to an embodiment of the present disclosure, each of the plurality of first light separation regions LSR1 can be disposed or configured to overlap or overlay the concave portion 141 having a hexagonal shape or one or more of corner portions of the convex portion 143 having a hexagonal shape surrounding one concave portion 141. For example, the center portion of each of the plurality of first light separation regions LSR1 can be disposed or configured to overlap or overlay the concave portion 141 having a hexagonal shape or the center portion MCP of three corner portions spaced apart from one another among first to sixth corner portions of the convex portion 143.

The second light separation region LSR2 can include a region between the plurality of first light separation regions LSR1. For example, the second light separation region LSR2 can include the other region, except the plurality of first light separation regions LSR1, of an emission area of each of first to fourth subpixels SP1, SP2, SP3, and SP4 of each of a plurality of pixels P. Accordingly, each of the plurality of first light separation regions LSR1 can be surrounded by the second light separation region LSR2.

The plurality of first light separation regions LSR1 described above with reference to FIG. 25 can be changed to a plurality of second light separation regions LSR2, and the second light separation region LSR2 can be changed to a first light separation region LSR1.

As described above, the light separation portion LSP according to another embodiment of the present disclosure can have or provide a same effect as that of the light separation portion LSP described above with reference to FIGS. 23 and 24.

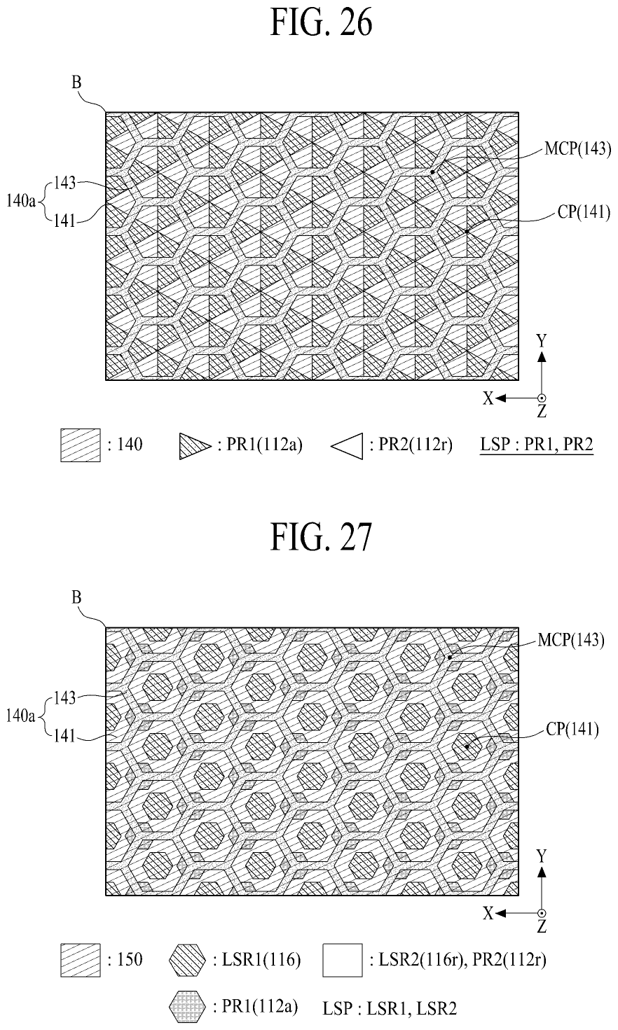

FIG. 26 is an enlarged view of a region ‘B’ illustrated in FIG. 23. Here, FIG. 26 illustrates an embodiment implemented by changing a shape and a position of each of a plurality of first light separation regions at the light separation portion described above with reference to FIGS. 23 and 24. Therefore, in the following description, except for a shape and a position of each of a plurality of first light separation regions, descriptions of the other elements can be the same as the descriptions of FIGS. 23 and 24, and thus, repeated descriptions can be omitted or will be briefly given.

Referring to FIG. 26, a light separation portion LSP according to another embodiment of the present disclosure can include a plurality of first light separation regions LSR1 and a plurality of second light separation regions LSR2.

Each of the plurality of first light separation regions LSR1 can have a triangular shape.

The plurality of first light separation regions LSR1 can be disposed to have a certain interval along a second direction Y and can be disposed to be staggered along a first direction X. For example, the plurality of first light separation regions LSR1 can be disposed to have a certain interval along a diagonal direction between the first direction X and the second direction Y. For example, each of the plurality of first light separation regions LSR1 disposed at even-numbered horizontal lines parallel to the first direction X can be disposed between the plurality of first light separation regions LSR1 disposed at adjacent odd-numbered horizontal lines along the second direction Y. Accordingly, the plurality of first light separation regions LSR1 are disposed in a zigzag shape along the first direction X.

Each of the plurality of first light separation regions LSR1 can be disposed or configured to overlap or overlay a portion of a concave portion 141 and a portion of a convex portion 143 of a light extraction pattern 140.

According to an embodiment of the present disclosure, a center portion of each of the plurality of first light separation regions LSR1 can be disposed or configured to overlap or overlay the convex portion 143 of the light extraction pattern 140. The center portion of each of the plurality of first light separation regions LSR1 can be disposed or configured to overlap or overlay the convex portion 143 between three adjacent concave portions 141 of the light extraction pattern 140. For example, the center portion of each of the plurality of first light separation regions LSR1 can be disposed or configured to overlap or overlay a center portion MCP of the convex portion 143 between three adjacent concave portions 141 of the light extraction pattern 140.

According to an embodiment of the present disclosure, each of the plurality of first light separation regions LSR1 can be disposed or configured to overlap or overlay the concave portion 141 having a hexagonal shape or one or more of corner portions of the convex portion 143 having a hexagonal shape surrounding one concave portion 141. For example, the center portion of each of the plurality of first light separation regions LSR1 can be disposed or configured to overlap or overlay the concave portion 141 having a hexagonal shape or the center portion MCP of three corner portions spaced apart from one another among first to sixth corner portions of the convex portion 143. For example, the center portion of each of the plurality of first light separation regions LSR1 can be disposed or configured to overlap or overlay the concave portion 141 having the hexagonal shape or the center portion MCP of first, third, and fifth corner portions of the convex portion 143.

Each of the plurality of second light separation regions LSR2 can have a triangular shape. The plurality of second light separation regions LSR2 can include a region between the plurality of first light separation regions LSR1. For example, the second light separation region LSR2 can include the other region, except the plurality of first light separation regions LSR1, of an emission area of each of first to fourth subpixels SP1, SP2, SP3, and SP4 of each of a plurality of pixels P. Accordingly, each of the plurality of second light separation regions LSR2 can be surrounded by three first light separation regions LSR1. For example, the plurality of first light separation regions LSR1 and the plurality of second light separation regions LSR2 can be alternately disposed or configured along each of the first direction X, the second direction Y, and a diagonal direction.

Each of the plurality of second light separation regions LSR2 can be disposed or configured to overlap or overlay a convex portion 143 different from the plurality of first light separation regions LSR1 of convex portions 143 of the light extraction pattern 140. For example, a center portion of each of the plurality of second light separation regions LSR2 can be disposed or configured to overlap or overlay the convex portion 143 between three adjacent concave portions 141 of the light extraction pattern 140. For example, the center portion of each of the plurality of second light separation regions LSR2 can be disposed or configured to overlap or overlay a center portion MCP of the convex portion 143 between three adjacent concave portions 141 of the light extraction pattern 140. For example, the center portion of each of the plurality of second light separation regions LSR2 can be disposed or configured to overlap or overlay the concave portion 141 having a hexagonal shape or a center portion MCP of second, fourth, and fifth corner portions of the convex portion 143 having a hexagonal shape.

According to an embodiment of the present disclosure, vertex portions of each of the plurality of first light separation regions LSR1 having a triangular shape can be positioned or aligned at a center portions CP of each of the three adjacent concave portions 141. Vertex portions of each of the plurality of second light separation regions LSR2 having a triangular shape can be positioned or aligned at a center portions CP of each of the three adjacent concave portions 141. Accordingly, three adjacent first light separation regions LSR1 of the plurality of first light separation regions LSR1 and three adjacent second light separation regions LSR2 of the plurality of second light separation regions LSR2 can have a hexagonal shape, and vertex portions at which three adjacent first light separation regions LSR1 contact three adjacent second light separation regions LSR2 can be positioned or aligned at center portions CP of the concave portions 141. Therefore, reflection light reflected from one concave portion 141 can be optically and multiply divided (or separated) by three first light separation regions LSR1 and three second light separation regions LSR2.

The plurality of first light separation regions LSR1 described above with reference to FIG. 26 can be changed to the plurality of second light separation regions LSR2, and the plurality of second light separation regions LSR2 can be changed to the plurality of first light separation regions LSR1.

As described above, the light separation portion LSP according to another embodiment of the present disclosure can have or provide a same effect as that of the light separation portion LSP described above with reference to FIGS. 23 and 24.

FIG. 27 is a diagram illustrating a light separation portion according to another embodiment of the present disclosure. Here, FIG. 27 illustrates an embodiment implemented by modifying the light separation portion described above with reference to FIGS. 23 and 24.

Referring to FIG. 27, a light separation portion LSP according to another embodiment (or a tenth embodiment) of the present disclosure can include a plurality of first light separation regions LSR1, a second light separation region LSR2, a plurality of first pattern regions PR1, and a second pattern region PR2, which are disposed at first to fourth subpixels (or a plurality of subpixels) SP1, SP2, SP3, and SP4 of each of a plurality of pixels P.

An arrangement structure of the plurality of first light separation regions LSR1 and the second light separation region LSR2 can be a same or substantially a same as an arrangement structure of the plurality of first light separation regions LSR1 and the second light separation region LSR2 described above with reference to FIGS. 23 and 24, and thus, repeated descriptions thereof are omitted.

The plurality of first pattern regions PR1 can be disposed at the second light separation region LSR2 to be spaced apart from each other. The plurality of first pattern regions PR1 can be disposed between the plurality of first light separation regions LSR1 of the second light separation region LSR2. For example, each of the plurality of first pattern regions PR1 can be disposed between three first light separation regions LSR1 of the second light separation regions LSR2.

Each of the plurality of first pattern regions PR1 can be disposed or configured to overlap or overlay a convex portion 143 of a light extraction pattern 140.

According to another embodiment of the present disclosure, a center portion of each of the plurality of first pattern regions PR1 can be disposed or configured to overlap or overlay the convex portion 143 of the light extraction pattern 140. The center portion of each of the plurality of first pattern regions PR1 can be disposed or configured to overlap or overlay the convex portion 143 between three adjacent concave portions 141 of the light extraction pattern 140. For example, the center portion of each of the plurality of first pattern regions PR1 can be disposed or configured to overlap or overlay a center portion MCP of the convex portion 143 between three adjacent concave portions 141 of the light extraction pattern 140.

According to an embodiment of the present disclosure, each of the plurality of first pattern regions PR1 can be disposed or configured to overlap or overlay the concave portion 141 having a hexagonal shape or one or more of corner portions of the convex portion 143 having a hexagonal shape surrounding one concave portion 141. For example, the center portion of each of the plurality of first pattern regions PR1 can be disposed or configured to overlap or overlay the concave portion 141 having a hexagonal shape or the center portion MCP of three corner portions spaced apart from one another among first to sixth corner portions of the convex portion 143.

The second pattern region PR2 can include a region between the plurality of first pattern regions PR1. For example, the second pattern region PR2 can include the other region, except the plurality of first pattern regions PR1, of an emission area of each of first to fourth subpixels SP1, SP2, SP3, and SP4 of each of a plurality of pixels P. Accordingly, each of the plurality of first pattern regions PR1 can be surrounded by the second pattern region PR2.

The plurality of first pattern regions PR1 and the second pattern region PR2 can be configured at a first buffer layer 112a.

According to an embodiment of the present disclosure, the first buffer layer 112a can be disposed at each of the plurality of first pattern regions PR1, and may not be disposed at the second pattern region PR2. Each of the plurality of first pattern regions PR1 can include the first buffer layer 112a or a region (or a disposition region) where the first buffer layer 112a is disposed. The second pattern region PR2 can include a region (or a non-disposition region) where the first buffer layer 112a is not disposed or a region (or a removal region) 112r from which the first buffer layer 112a has been removed. Accordingly, reflection lights reflected from the convex portion 143 of the light extraction pattern 140 can be optically divided (or separated) by the plurality of first pattern regions PR1.

According to another embodiment of the present disclosure, the first buffer layer 112a can be not disposed at each of the plurality of first pattern regions PR1, and can be disposed at the second pattern region PR2. Each of the plurality of first pattern regions PR1 can include a region (or a disposition region) where the first buffer layer 112a is disposed or a region (or a removal region) 112r from which the first buffer layer 112a has been removed. Accordingly, reflection lights reflected from the convex portion 143 of the light extraction pattern 140 can be optically divided (or separated) by the plurality of first pattern regions PR1.

As described above, the light separation portion LSP according to another embodiment of the present disclosure can have or provide a same effect as that of the light separation portion LSP described above with reference to FIGS. 23 and 24, and can optically and multiply divide (or separate) reflection light which is reflected from the light extraction pattern 140 by the plurality of first light separation regions LSR1, the second light separation region LSR2, the plurality of first pattern regions PR1, and the second pattern region PR2, and thus, a probability of occurrence of constructive interference (or light interference) occurring between the reflection lights can more decrease or a probability of occurrence of destructive interference can more increase.

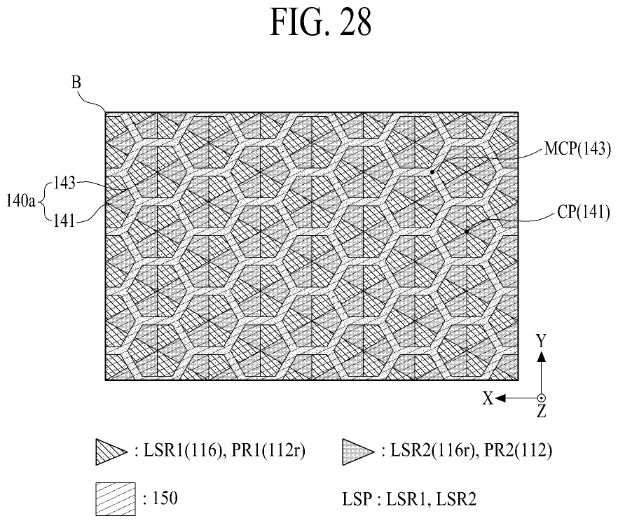

FIG. 28 is a diagram illustrating a light separation portion according to another embodiment of the present disclosure. Here, FIG. 28 illustrates an embodiment implemented by modifying the light separation portion described above with reference to FIG. 26.

Referring to FIG. 28, a light separation portion LSP according to another embodiment (or an eleventh embodiment) of the present disclosure can include a plurality of first light separation regions LSR1, a second light separation region LSR2, a plurality of first pattern regions PR1, and a plurality of second pattern regions PR2, which are disposed at first to fourth subpixels (or a plurality of subpixels) SP1, SP2, SP3, and SP4 of each of a plurality of pixels P.

An arrangement structure of the plurality of first light separation regions LSR1 and the plurality of second light separation regions LSR2 can be a same or substantially a same as an arrangement structure of the plurality of first light separation regions LSR1 and the plurality of second light separation regions LSR2 described above with reference to FIG. 26, and thus, repeated descriptions thereof are omitted.

Each of the plurality of first pattern regions PR1 can correspond to or overlap with each of the plurality of first light separation regions LSR1. Each of the plurality of first pattern regions PR1 can be a plurality of first light separation regions LSR1. Each of the plurality of second pattern regions PR2 can correspond to or overlap with each of the plurality of second light separation regions LSR2. Each of the plurality of second pattern regions PR2 can be a plurality of second light separation regions LSR2.

The plurality of first pattern regions PR1 and the plurality of second pattern regions PR2 can be configured at the first buffer layer 112a.

According to an embodiment of the present disclosure, the first buffer layer 112a may not be disposed at each of the plurality of first pattern regions PR1, and can be disposed at the plurality of second pattern regions PR2. Each of the plurality of first pattern regions PR1 can include a region (or a non-disposition region) where the first buffer layer 112a is not disposed or a region (or a removal region) 112r from which the first buffer layer 112a has been removed. The plurality of second pattern regions PR2 can include the first buffer layer 112a or a region (or a disposition region) where the first buffer layer 112a is disposed. Accordingly, reflection lights reflected from a portion of the concave portion 141 and the convex portion 143 of the light extraction pattern 140 can be optically divided (or separated) by the plurality of second pattern regions PR2.

According to another embodiment of the present disclosure, the first buffer layer 112a can be disposed at each of the plurality of first pattern regions PR1, and can be disposed at the plurality of second pattern regions PR2. Each of the plurality of first pattern regions PR1 can include the first buffer layer 112a or a region (or a disposition region) where the first buffer layer 112a is disposed. Each of the plurality of second pattern regions PR2 can include a region (or a non-disposition region) where the first buffer layer 112a is not disposed or a region (or a removal region) 112r from which the first buffer layer 112a has been removed. Accordingly, reflection lights reflected from the convex portion 143 of the light extraction pattern 140 can be optically divided (or separated) by the plurality of first pattern regions PR1.

As described above, the light separation portion LSP according to another embodiment of the present disclosure can have or provide a same effect as that of the light separation portion LSP described above with reference to FIG. 26, and can optically and multiply divide (or separate) reflection light which is reflected from the light extraction pattern 140 by the plurality of first light separation regions LSR1, the plurality of second light separation regions LSR2, the plurality of first pattern regions PR1, and the plurality of second pattern regions PR2, and thus, a probability of occurrence of constructive interference (or light interference) occurring between the reflection lights can more decrease or a probability of occurrence of destructive interference can more increase.

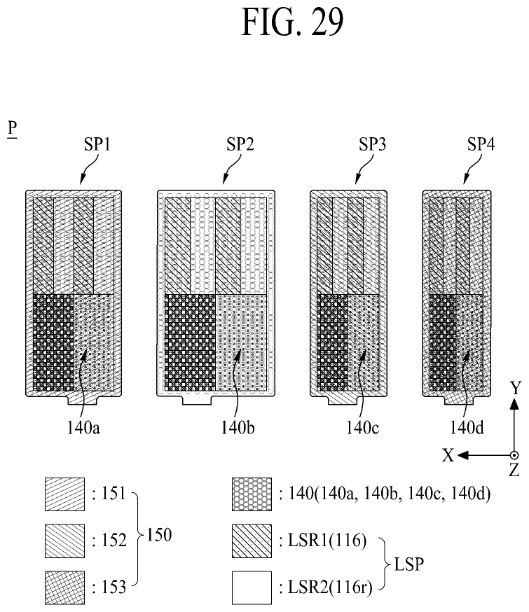

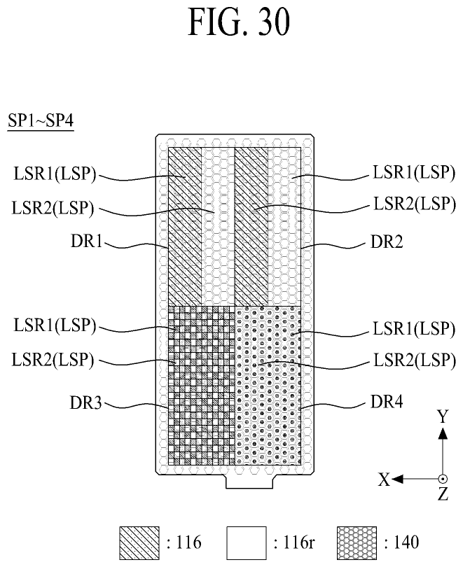

FIG. 29 is a diagram illustrating a light separation portion according to another embodiment of the present disclosure. FIG. 30 is a diagram illustrating the enlargement of the subpixel illustrated in FIG. 29. FIGS. 29 and 30 illustrate an embodiment implemented by modifying the light separation portion described above with reference to FIGS. 7 to 12.

Referring to FIGS. 29 and 30, a light separation portion LSP according to another embodiment (or a twelfth embodiment) of the present disclosure can be disposed or configured at each of a plurality of division regions DR1, DR2, DR3, and DR4 which is disposed at first to fourth subpixels (or a plurality of subpixels) SP1, SP2, SP3, and SP4 of each of a plurality of pixels P. For example, the light separation portion LSP can include can be disposed or configured at each of first to fourth division regions DR1, DR2, DR3, and DR4 which is disposed at the first to fourth subpixels (or a plurality of subpixels) SP1, SP2, SP3, and SP4 of each of a plurality of pixels P.

Each of the first to fourth subpixels (or the plurality of subpixels) SP1, SP2, SP3, and SP4 of each of the plurality of pixels P according to an embodiment of the present disclosure can include the plurality of division regions DR1, DR2, DR3, and DR4. For example, an emission area of each of the first to fourth subpixels SP1, SP2, SP3, and SP4 can include the plurality of division regions DR1, DR2, DR3, and DR4. For example, the emission area of each of the first to fourth subpixels SP1, SP2, SP3, and SP4 can include two or more division regions DR1, DR2, DR3, and DR4. For example, each of the first to fourth subpixels SP1, SP2, SP3, and SP4 can include the first to fourth division regions DR1, DR2, DR3, and DR4. For example, the emission area of each of the first to fourth subpixels SP1, SP2, SP3, and SP4 can include the first to fourth division regions DR1, DR2, DR3, and DR4.

The first to fourth division regions DR1, DR2, DR3, and DR4 can be separated or spatially separated from each other within the emission area of each of the first to fourth subpixels SP1, SP2, SP3, and SP4. The first to fourth division regions DR1, DR2, DR3, and DR4 can be disposed in parallel along a first direction X and a second direction Y within the second subpixel SP2. For example, each the first to fourth division regions DR1, DR2, DR3, and DR4 can be disposed in a lattice pattern shape within the emission area of each of the first to fourth subpixels SP1, SP2, SP3, and SP4. For example, the first to fourth division regions DR1, DR2, DR3, and DR4 can have a rectangular shape. For example, the first to fourth division regions DR1, DR2, DR3, and DR4 can have a rectangular shape which extends along the second direction Y. For example, the emission area each of the first to fourth subpixels SP1, SP2, SP3, and SP4 can have a vertical-horizontal division structure (or a four-division lattice pattern structure or a four-division tetragonal structure) by the first to fourth division regions DR1, DR2, DR3, and DR4. The first to fourth division regions DR1, DR2, DR3, and DR4 can have a same size (or area), but embodiments of the present disclosure are not limited thereto.

Each of the first and second division regions DR1 and DR2 can be an upper region (or a top region) of each of the first to fourth subpixels SP1, SP2, SP3, and SP4, and each of the third and fourth division regions DR3 and DR4 can be a lower region (or a bottom region) of each of the first to fourth subpixels SP1, SP2, SP3, and SP4.

With respect to the first direction X, a first light separation region LSR1 of the first division region DR1 can be a left region of the first division region DR1, and a second light separation region LSR2 of the first division region DR1 can be a right region of the first division region DR1.

With respect to the second direction Y, a first light separation region LSR1 of the second division region DR2 can be a left region of the second division region DR2, and a second light separation region LSR2 of the second division region DR2 can be a right region of the second division region DR2.

The light separation portion LSP can include a first light separation region LSR1 and a second light separation region LSR2 disposed at each of the first and second division regions DR1 and DR2 of each of the first to fourth subpixels SP1, SP2, SP3, and SP4.

The first light separation region LSR1 and the second light separation region LSR2 of each of the first and second division regions DR1 and DR2 can have a same size (or area), or can have different sizes (or areas). For example, in each of the first and second division regions DR1 and DR2, the first light separation region LSR1 and the second light separation region LSR2 can have different refractive indexes, but embodiments of the present disclosure are not limited thereto. For example, in each of the first and second division regions DR1 and DR2, the first light separation region LSR1 and the second light separation region LSR2 can have a refractive index difference of 0.1 or more therebetween, but embodiments of the present disclosure are not limited thereto.

The light separation portion LSP or the first light separation region LSR1 and the second light separation region LSR2 disposed at each of the first and second division regions DR1 and DR2 can be configured at a passivation layer 116 and a color filter layer 150.

According to an embodiment of the present disclosure, in each of the first and second division regions DR1 and DR2, the first light separation region LSR1 can include a passivation layer 116 and a first filter region of the color filter layer 150. The first light separation region LSR1 can include a region where the passivation layer 116 is disposed, and a first filter region of the color filter layer 150. The second light separation region LSR2 can include a region where the passivation layer 116 is not disposed, and a second filter region of the color filter layer 150. The second light separation region LSR2 can include a region (or a removal region) 116r from which the passivation layer 116 has been removed, and a second filter region of the color filter layer 150.

The first light separation region LSR1 and the second light separation region LSR2 can be a same or substantially a same as the first light separation region LSR1 and the second light separation region LSR2 described above with reference to FIGS. 7 to 12 except for being respectively disposed or configured at each of the first and second division regions DR1 and DR2 of each of the first to fourth subpixels SP1, SP2, SP3, and SP4, and thus, repeated descriptions thereof are omitted. The descriptions of the light separation portion LSP or the first light separation region LSR1 and the second light separation region LSR2 illustrated in FIGS. 7 to 12 can be included in the descriptions of the light separation portion LSP or the first light separation region LSR1 and the second light separation region LSR2 of each of the first and second division regions DR1 and DR2 illustrated in FIGS. 29 and 30.

According to another embodiment of the present disclosure, any one of the first light separation region LSR1 and the second light separation region LSR2 of the first division region DR1 can be omitted, and any one of the first light separation region LSR1 and the second light separation region LSR2 of the second division region DR2 can be omitted. For example, the second light separation region LSR2 can be omitted and the first division region DR1 can be configured with only the first light separation region LSR1, and thus, all of the first division region DR1 can be configured with only the first light separation region LSR1. For example, the first light separation region LSR1 can be omitted and the second division region DR2 can be configured with only the second light separation regions LSR2, and thus, all of the second division region DR2 can be configured with only the second light separation regions LSR2.

According to another embodiment of the present disclosure, the first light separation region LSR1 and the second light separation region LSR2 of each of the first and second division regions DR1 and DR2 can be changed to the first light separation region LSR1 and the second light separation region LSR2 described above with reference to FIGS. 13 to 21. The plurality of first light separation regions LSR1 and the plurality of second light separation regions LSR2 illustrated in FIGS. 13 to 21 can be a same or substantially a same as the plurality of first light separation regions LSR1 and the second light separation region LSR2 except for being respectively disposed or configured at each of the first and second division regions DR1 and DR2 of each of the first to fourth subpixels SP1, SP2, SP3, and SP4, and thus, repeated descriptions thereof are omitted. The descriptions of the plurality of first light separation regions LSR1 and the plurality of second light separation regions LSR2 illustrated in FIGS. 13 to 21 can be included in the descriptions of the first light separation region LSR1 and the second light separation region LSR2 of each of the first and second division regions DR1 and DR2 illustrated in FIGS. 29 and 30.

The light separation portion LSP can include a plurality of first light separation regions LSR1 and a plurality of second light separation regions LSR2, which are disposed at the third division region DR3 of each of the first to fourth subpixels SP1, SP2, SP3, and SP4.

The plurality of first light separation regions LSR1 at the third division region DR3 can be disposed or configured at the third division region DR3 to have a certain interval along the first direction X and the second direction Y. For example, the plurality of first light separation regions LSR1 at the third division region DR3 can be disposed or configured in a grating pattern shape or a checkered pattern shape. The plurality of second light separation regions LSR2 at the third division region DR3 can be disposed or configured between the plurality of first light separation regions LSR1 to have a certain interval along the first direction X and the second direction Y. For example, in the third division region DR3, the plurality of first light separation regions LSR1 and the plurality of second light separation regions LSR2 can have different refractive indexes, but embodiments of the present disclosure are not limited thereto. For example, in the third division region DR3, the plurality of first light separation regions LSR1 and the plurality of second light separation regions LSR2 can have a refractive index difference of 0.1 or more therebetween, but embodiments of the present disclosure are not limited thereto.

In the third division region DR3, each of the plurality of first light separation regions LSR1 can be disposed or configured in a grating pattern shape or a checkered pattern shape. The plurality of second light separation regions LSR2 can be disposed or configured between the plurality of first light separation regions LSR1 to have a certain interval along the first direction X and the second direction Y. An arrangement structure of the plurality of first light separation regions LSR1 and the plurality of second light separation regions LSR2 can be a same or substantially a same as the plurality of first light separation regions LSR1 and the plurality of second light separation regions LSR2 described above with reference to FIG. 21 except for being disposed at the third division region DR3, and thus, repeated descriptions thereof are omitted.

According to another embodiment of the present disclosure, in the third division region DR3, the plurality of first light separation regions LSR1 and the plurality of second light separation regions LSR2 can be changed to the first light separation region LSR1 and the second light separation region LSR2 described above with reference to FIG. 22. The plurality of first light separation regions LSR1 and the plurality of second light separation regions LSR2 illustrated in FIG. 22 can be a same or substantially a same as the plurality of first light separation regions LSR1 and the plurality of second light separation regions LSR2 except for being respectively disposed or configured at the third division region DR3 of each of the first to fourth subpixels SP1, SP2, SP3, and SP4, and thus, repeated descriptions thereof are omitted. The descriptions of the plurality of first light separation regions LSR1 and the plurality of second light separation regions LSR2 illustrated in FIG. 22 can be included in the descriptions of the plurality of first light separation regions LSR1 and the plurality of second light separation regions LSR2 of the third division region DR3 illustrated in FIGS. 29 and 30.

The light separation portion LSP can include a plurality of first light separation regions LSR1 and a plurality of second light separation regions LSR2, which are disposed at the fourth division region DR4 of each of the first to fourth subpixels SP1, SP2, SP3, and SP4.

The plurality of first light separation regions LSR1 at the fourth division region DR4 can be disposed in parallel to have a certain interval along the second direction Y and can be disposed to be staggered with one another along the first direction X. For example, the plurality of first light separation regions LSR1 can be disposed to have a certain interval along a diagonal direction between the first direction X and the second direction Y. The second light separation region LSR2 at the fourth division region DR4 can include a region between the plurality of first light separation regions LSR1. For example, the second light separation region LSR2 can include the other region, except the plurality of first light separation regions LSR1, of the fourth division region DR4. For example, in the fourth division region DR4, the plurality of first light separation regions LSR1 and the second light separation region LSR2 can have different refractive indexes, but embodiments of the present disclosure are not limited thereto. For example, in the fourth division region DR4, the plurality of first light separation regions LSR1 and the second light separation pattern region LSR2 can have a refractive index difference of 0.1 or more therebetween, but embodiments of the present disclosure are not limited thereto.

In the fourth division region DR4, each of the plurality of first light separation regions LSR1 can be disposed or configured in a honeycomb structure. The second light separation region LSR2 can be disposed or configured between the plurality of first light separation regions LSR1 to have a certain interval along the first direction X and the second direction Y. An arrangement structure of the plurality of first light separation regions LSR1 and the second light separation region LSR2 can be a same or substantially a same as the plurality of first light separation regions LSR1 and the second light separation region LSR2 described above with reference to FIGS. 23 and 24 except for being disposed at the fourth division region DR4, and thus, repeated descriptions thereof are omitted.

According to another embodiment of the present disclosure, the plurality of first light separation regions LSR1 and the second light separation region LSR2 at the fourth division region DR4 can be changed to the plurality of first light separation regions LSR1 and the second light separation region LSR2 described above with reference to FIGS. 27 and 28. The plurality of first light separation regions LSR1 and the second light separation region LSR2 illustrated in FIGS. 25 to 28 can be a same or substantially a same as can be a same or substantially a same as the plurality of first light separation regions LSR1 and the second light separation region LSR2 except for being respectively disposed or configured at the fourth division region DR4 of each of the first to fourth subpixels SP1, SP2, SP3, and SP4, and thus, repeated descriptions thereof are omitted. The descriptions of the plurality of first light separation regions LSR1 and the second light separation region LSR2 illustrated in FIGS. 25 to 28 can be included in the descriptions of the plurality of first light separation regions LSR1 and the second light separation region LSR2 of the fourth division region DR4 illustrated in FIGS. 29 and 30.

As described above, the light separation portion LSP according to another embodiment of the present disclosure can include the plurality of first light separation regions LSR1 and the plurality of second light separation regions LSR2, which are configured at each of the plurality of division regions DR1, DR2, DR3, and DR4 at the first to fourth subpixels (or the plurality of subpixels) SP1, SP2, SP3, and SP4 of each of the plurality of pixels P, and thus, can optically divide reflection light reflected from the light extraction pattern 140 at each of the plurality of division regions DR1, DR2, DR3, and DR4 to increase the irregularity or randomness of a diffraction pattern of the reflection light, and thus, the occurrence of rainbow Mura where reflection light is spread in a radial shape and/or circular ring Mura where reflection light is spread in a radial shape can be better prevented or more minimized based on a diffraction characteristic of each of the reflection lights reflected from the light extraction patterns 140.

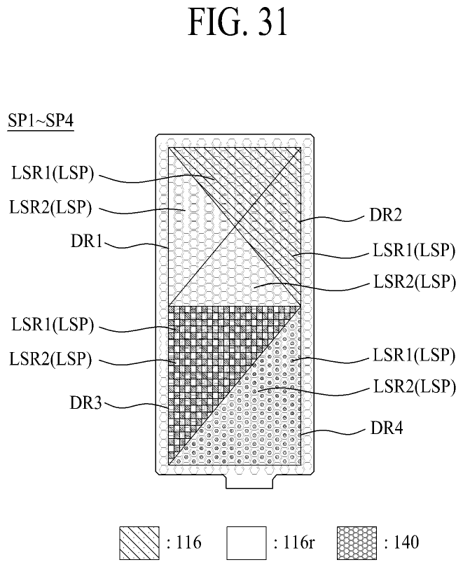

FIG. 31 is another diagram illustrating the enlargement of the subpixel illustrated in FIG. 29. Here, FIG. 31 illustrates an embodiment implemented by modifying a division region described above with reference to FIGS. 29 and 30. Therefore, in the following description, the descriptions of the other elements except the division region can be the same as the descriptions of FIGS. 29 and 30, and thus, repeated descriptions are omitted or will be briefly given.

Referring to FIG. 31, first to fourth division regions (or a plurality of division regions) DR1, DR2, DR3, and DR4 according to another embodiment of the present disclosure can be disposed along one or more direction of a first direction X, a second direction Y crossing the first direction X, and a diagonal direction between the first direction X and the second direction Y within an emission area of each of first to fourth subpixels SP1, SP2, SP3, and SP4. For example, the first to fourth division regions DR1, DR2, DR3, and DR4 can be disposed along the second direction Y and the diagonal direction within the emission area of each of first to fourth subpixels SP1, SP2, SP3, and SP4.

According to another embodiment of the present disclosure, each of the first to fourth division regions DR1, DR2, DR3, and DR4 can have a triangular shape. For example, each of the first to fourth division regions DR1, DR2, DR3, and DR4 can have a same size (or area) or different sizes (or area), but embodiments of the present disclosure are not limited thereto. For example, the emission area of each of first to fourth subpixels SP1, SP2, SP3, and SP4 can have a diagonal division structure (or a four-division triangular structure) by the first to fourth division regions DR1, DR2, DR3, and DR4. The first to fourth division regions DR1, DR2, DR3, and DR4 can have a same size (or area) or different sizes (or area).

The light separation portion LSP can include one or more first pattern region PR1 and one or more second pattern region PR2 disposed at each of the first and second division regions DR1 and DR2 of each of the first to fourth subpixels SP1, SP2, SP3, and SP4. For example, the light separation portion LSP can include a first light separation region LSR1 and a second light separation region LSR2 disposed at each of the first and second division regions DR1 and DR2 of each of the first to fourth subpixels SP1, SP2, SP3, and SP4.

Each of the first light separation region LSR1 and the second light separation region LSR2 of each of the first and second division regions DR1 and DR2 can have a triangular shape. The first light separation region LSR1 and the second light separation region LSR2 of each of the first and second division regions DR1 and DR2 can have a same size (or area), or can have different sizes (or areas).

Except for that the first light separation region LSR1 and the second light separation region LSR2 of each of the first and second division regions DR1 and DR2 are disposed or configured at each of the first and second division regions DR1 and DR2 having the triangular shape, the first light separation region LSR1 and the second light separation region LSR2 can be a same as or substantially a same as the first pattern region PR1 and the second pattern region PR2 described above with reference to FIGS. 29 and 30, and thus, repeated descriptions thereof are omitted. The descriptions of the light separation portion LSP or the first light separation region LSR1 and the second light separation region LSR2 illustrated in FIGS. 29 and 30 can be included in the descriptions of the first light separation region LSR1 and the second light separation region LSR2 at each of the first and second division regions DR1 and DR2 illustrated in FIG. 31.

According to another embodiment of the present disclosure, any one of the first light separation region LSR1 and the second light separation region LSR2 of the first division region DR1 can be omitted, and any one of the first light separation region LSR1 and the second light separation region LSR2 of the second division region DR2 can be omitted. For example, the second light separation region LSR2 can be omitted and the first division region DR1 can be configured with only the first light separation region LSR1, and thus, all of the first division region DR1 can be configured with only the first light separation region LSR1. For example, the first light separation region LSR1 can be omitted and the second division region DR2 can be configured with only the second light separation region LSR2, and thus, all of the second division region DR2 can be configured with only the second light separation region LSR2.

The light separation portion LSP can include one or more first light separation regions LSR1 and one or more second light separation regions LSR2, which are disposed at the third division region DR3 of each of the first to fourth subpixels SP1, SP2, SP3, and SP4. For example, the light separation portion LSP can include a plurality of first light separation regions LSR1 and a plurality of second light separation regions LSR2, which are disposed at the third division region DR3 of each of the first to fourth subpixels SP1, SP2, SP3, and SP4.

The plurality of first light separation regions LSR1 at the third division region DR3 can be disposed or configured in a grating pattern shape or a checkered pattern shape. The plurality of second light separation regions LSR2 at the third division region DR3 can be disposed or configured between the plurality of first light separation regions LSR1 to have a certain interval along the first direction X and the second direction Y.

Except for that the plurality of first light separation regions LSR1 and the plurality of second light separation regions LSR2 at the third division region DR3 are disposed or configured at each of the first and second division regions DR1 and DR2 having the triangular shape, the plurality of first light separation regions LSR1 and the plurality of second light separation regions LSR2 can be a same as or substantially a same as the plurality of first light separation regions LSR1 and the plurality of second light separation regions LSR2 described above with reference to FIGS. 29 and 30, and thus, repeated descriptions thereof are omitted. The descriptions of the light separation portion LSP or the plurality of first light separation regions LSR1 and the plurality of second light separation regions LSR2 illustrated in FIGS. 29 and 30 can be included in the descriptions of the plurality of first light separation regions LSR1 and the plurality of second light separation regions LSR2 at the third division region DR3 illustrated in FIG. 31.

The light separation portion LSP can include one or more first light separation regions LSR1 and one or more second light separation regions LSR2, which are disposed at the fourth division region DR4 of each of the first to fourth subpixels SP1, SP2, SP3, and SP4. For example, the light separation portion LSP can include a plurality of first light separation regions LSR1 and a second light separation region LSR2, which are disposed at the fourth division region DR4 of each of the first to fourth subpixels SP1, SP2, SP3, and SP4.

The plurality of first light separation regions LSR1 of the fourth division region DR4 can be disposed in parallel to have a certain interval along the second direction Y and can be disposed to be staggered with one another along the first direction X. The second light separation region LSR2 of the fourth division region DR4 can include a region between the plurality of first light separation regions LSR1.

Except for that the plurality of first light separation regions LSR1 and the second light separation region LSR2 at the fourth division region DR4 are disposed or configured at each of the fourth division region DR4 having the triangular shape, the plurality of first light separation regions LSR1 and the second light separation region LSR2 can be a same as or substantially a same as the plurality of first light separation regions LSR1 and the second light separation region LSR2 described above with reference to FIGS. 29 and 30, and thus, repeated descriptions thereof are omitted. The descriptions of the light separation portion LSP or the plurality of first light separation regions LSR1 and the second light separation region LSR2 illustrated in FIGS. 29 and 30 can be included in the descriptions of the plurality of first light separation regions LSR1 and the second light separation region LSR2 at the fourth division region DR4 illustrated in FIG. 31.

As described above, the light separation portion LSP according to another embodiment of the present disclosure can have or provide a same effect as that of the light separation portion LSP described above with reference to FIGS. 29 and 30.

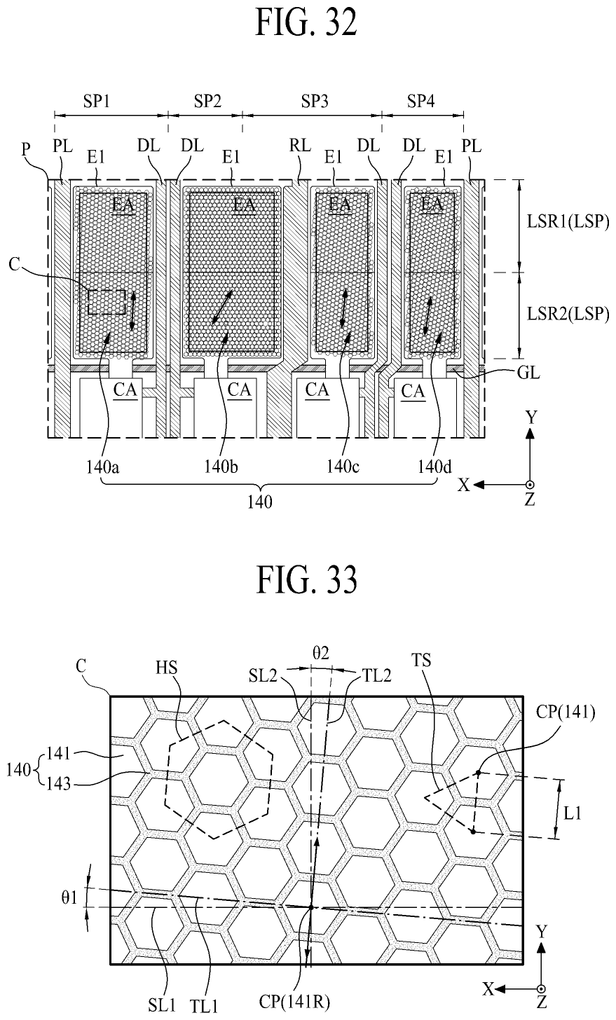

FIG. 32 is a plan view illustrating a pixel according to another embodiment of the present disclosure. Here, FIG. 32 illustrates an embodiment implemented by modifying the light extraction pattern described above with reference to FIGS. 1 to 31. Therefore, in the following description, the descriptions of the other elements except a light extraction pattern and relevant elements can be the same as the descriptions of FIGS. 1 to 31, and thus, repeated descriptions are omitted or will be briefly given. In FIG. 32, a bidirectional arrow illustrated in a subpixel represents a rotation angle (or a rotation direction) of a light extraction pattern.

Referring to FIG. 32, each of first to fourth subpixels SP1, SP2, SP3, and SP4 of each of a plurality of pixels P according to another embodiment of the present disclosure can include a light extraction pattern 140.

The light extraction pattern 140 configured at each of the first to fourth subpixels SP1, SP2, SP3, and SP4 can rotate (or horizontally rotate) or reversely rotate (or horizontally and reversely rotate) with respect to a reference point within a corresponding emission area EA. For example, the reference point can be an arbitrary point or one point of the emission area EA.

One or more of light extraction patterns 140 configured at each of the first to fourth subpixels SP1, SP2, SP3, and SP4 can be rotated or reversely rotated by different angles. For example, the first to fourth light extraction patterns 140a, 140b, 140c, and 140d can be rotated or reversely rotated by different angles. For example, the light extraction patterns 140 configured at each of the first to fourth subpixels SP1, SP2, SP3, and SP4 at one pixel P can be rotated by different angles from each other. For example, rotation angles of light extraction patterns 140 disposed at adjacent pixel P can be different from each other.

According to an embodiment of the present disclosure, external light can be reflected by a rotated light extraction pattern 140 of each of the first to fourth subpixels SP1, SP2, SP3, and SP4. The rotated light extraction pattern 140 can change a diffraction path of incident light to a vertical direction and can generate a diffraction pattern (or a diffraction pattern distribution) having maximum intensity in a specific order instead of a 0th diffraction order, and thus, diffraction patterns (or diffraction pattern distributions) occurring due to the constructive interference of reflection light reflected from the light extraction pattern 140 can be offset or minimized. Constructive interference between diffraction patterns (or diffraction pattern distributions) can be offset due to the irregularity or randomness of a rotation angle of the light extraction pattern 140.

The light extraction pattern 140 can include first to fourth light extraction patterns 140a, 140b, 140c, and 140d.

The first light extraction pattern 140a can be disposed or configured at the first subpixel SP1 of each of the plurality of pixels P. The second light extraction pattern 140b can be disposed or configured at the second subpixel SP2 of each of the plurality of pixels P. The third light extraction pattern 140c can be disposed or configured at the third subpixel SP3 of each of the plurality of pixels P. The fourth light extraction pattern 140d can be disposed or configured at the fourth subpixel SP4 of each of the plurality of pixels P.

Each of the first to fourth light extraction patterns 140a, 140b, 140c, and 140d can be rotated or reversely rotated with respect to a reference point within a corresponding emission area EA. One or more of the first to fourth light extraction patterns 140a, 140b, 140c, and 140d can be rotated or reversely rotated by different angles. For example, the first to fourth light extraction patterns 140a, 140b, 140c, and 140d can be rotated or reversely rotated by different angles form each other. For example, the first to fourth light extraction patterns 140a, 140b, 140c, and 140d which is disposed at each of the first to fourth subpixels SP1, SP2, SP3, and SP4 at one pixel P can be rotated by different angles form each other. For example, rotation angles of each of the first to fourth subpixels SP1, SP2, SP3, and SP4 can differ from each other by pixel units. For example, rotation angles of light extraction patterns 140a, 140b, 140c, and 140d disposed at a same adjacent subpixels SP1, SP2, SP3, and SP4 can differ from each other. For example, some of the light extraction patterns 140 can be rotated by a same rotation angles based on the number of pixels P disposed at the display area. For example, the light extraction patterns 140 which have rotated by a same rotation angles can be separated from one another by an interval corresponding to the plurality of pixels P, at the display area.

According to another embodiment of the present disclosure, the irregularity or randomness of a diffraction pattern of reflection light reflected form the light extraction pattern 140 can increase based on a rotation angle of the light extraction pattern 140 and can more increase due to a phase difference and/or a light path difference between reflection lights caused by the first light separation region LSR1 and the second light separation region LSR2 of the light separation portion LSP.

The light extraction patterns 140a, 140b, 140c, and 140d described above with reference to FIGS. 1 to 31 can be changed to the rotated light extraction patterns 140a, 140b, 140c, and 140d described above with reference to FIG. 32.

Therefore, the organic light emitting display apparatus or the display panel according to another embodiment of the present disclosure can include the first light separation region LSR1 and the second light separation region LSR2 and the light extraction patterns 140a, 140b, 140c, and 140d which have rotated with respect to an arbitrary reference point in the subpixels SP1, SP2, SP3, and SP4, and thus, the irregularity or randomness of a diffraction pattern of reflection light reflected from the light extraction pattern 140 can more increase. Accordingly, the occurrence of rainbow Mura where reflection light is spread in a radial shape and/or circular ring Mura where reflection light is spread in a radial shape can be better prevented or more minimized based on the diffraction characteristic of reflection light reflected from the light extraction pattern 140 of the display area. For example, a black visibility characteristic or a black color (or black rising) phenomenon caused by the reflection of external light can be reduced in a non-driving or off state of the organic light emitting display apparatus or the display panel 10, thereby implementing true black.

FIG. 33 is an enlarged view of a region ‘C’ illustrated in FIG. 32. Here, FIG. 33 is a diagram illustrating a rotation structure of a light extraction pattern illustrated in FIG. 32. Therefore, in the following description, the descriptions of the other elements except a rotation structure of a light extraction pattern can be the same as the descriptions of FIG. 4, and thus, repeated descriptions are omitted or will be briefly given.

Referring to FIGS. 32 and 33, the light extraction pattern 140 or each of first to fourth light extraction patterns 140a, 140b, 140c, and 140d according to another embodiment of the present disclosure can be configured to be rotated (or horizontally rotate) or reversely rotated (or horizontally and reversely rotate) with respect to the arbitrary reference point within an emission area EA (or a subpixel area) of each of the first to fourth subpixels SP1, SP2, SP3, and SP4. For example, when the concave portion 141 or the convex portions 143 has a planar structure having a hexagonal shape (or a honeycomb shape), a rotation angle of the light extraction pattern 140 can be set to within a range of 0 degrees to 60 degrees. For example, the arbitrary reference point can be an arbitrary position within the emission area EA (or a subpixel area) of each of the first to fourth subpixels SP1, SP2, SP3, and SP4 in the pixel P, or can be a center portion CP of any one of the plurality of concave portions 141.

According to an embodiment of the present disclosure, when the concave portion 141 or the convex portions 143 has a planar structure having a hexagonal shape (or a honeycomb shape), a case where the light extraction pattern 140 rotates by 60 degrees, 120 degrees, 180 degrees, 240 degrees, 300 degrees, or 360 degrees with respect to the arbitrary reference point can be configured to be equal to a case where the light extraction pattern 140 does not rotate with respect to the arbitrary reference point. Accordingly, when the concave portion 141 has a planar structure having a hexagonal shape (or a honeycomb shape), a rotation angle of the light extraction pattern 140 can be greater than 0 degrees and less than 60 degrees.

According to a rotation structure (or rotation arrangement) of the light extraction pattern 140, when a center portion CP of an arbitrary reference concave portion 141R of a plurality of concave portions 141 disposed along a first direction X is positioned at or aligned with a first straight line SL1 parallel to the first direction X, a center portion CP of each of a plurality of other concave portions 141 adjacent to the reference concave portion 141R may not be positioned at or aligned with the first straight line SL1.

According to a rotation structure (or rotation arrangement) of the light extraction pattern 140, when a center portion CP of an arbitrary reference concave portion 141R of a plurality of concave portions 141 disposed along a second direction Y is positioned at or aligned with a second straight line SL2 parallel to the second direction Y, a center portion CP of each of a plurality of other concave portions 141 adjacent to the reference concave portion 141R may not be positioned at or aligned with the second straight line SL2.

According to an embodiment of the present disclosure, the center portion CP of each of the plurality of concave portions 141 disposed at the first direction X can be positioned or aligned at the first tilt line TL1 intersecting with the first straight line SL1. Furthermore, the center portion CP of each of the plurality of concave portions 141 disposed at the second direction Y can be positioned or aligned at the second tilt line TL2 intersecting with the second straight line SL2.

The first tilt line TL1 can be sloped or inclined by a first angle θ1 from the first straight line SL1. For example, the first angle θ1 can be more than 0 degrees and less than 60 degrees (0 degrees≤θ1<60 degrees) or greater than 0 degrees and smaller than 60 degrees (0 degrees<θ1≤60 degrees). The first tilt line TL1 according to an embodiment of the present disclosure can be sloped or inclined from the first straight line SL1 and can pass through a center portion CP of rotated concave portions 141, and thus, the first tilt line TL1 can be a first center connection line or a first center extension line. The first tilt line TL1 according to another embodiment of the present disclosure can be sloped or inclined from the first straight line SL1 and can pass through ends of rotated concave portions 141, and thus, the first tilt line TL1 can be a first end connection line or a first end extension line.

According to an embodiment of the present disclosure, when the plurality of concave portions 141 are arranged in a honeycomb structure, the first tilt line TL1 according to an embodiment of the present disclosure can be sloped or inclined from the first straight line SL1 and can pass through two vertexes facing each other and a center portion CP at each of the plurality of concave portions 141. Furthermore, the first tilt line TL1 according to another embodiment of the present disclosure can be sloped or inclined from the first straight line SL1 and can pass through any one of first to sixth sides of each of the plurality of concave portions 141. For example, an angle between the first tilt line TL1 and a side intersecting with the first tilt line TL1 among the first to sixth sides of each of the plurality of concave portions 141 can be 60 degrees.

The second tilt line TL2 can be sloped or inclined by a second angle θ2 from a second straight line SL2. For example, the second angle θ2 can be more than 0 degrees and less than 60 degrees (0 degrees≤θ2<60 degrees) or greater than 0 degrees and smaller than 60 degrees (0 degrees<θ2≤60 degrees). For example, the second angle θ2 can be equal to a first angle θ1. The second tilt line TL2 according to an embodiment of the present disclosure can be sloped or inclined from the second straight line SL2 and can pass through a center portion CP of rotated concave portions 141, and thus, the second tilt line TL2 can be a second center connection line or a second center extension line. The second tilt line TL1 according to another embodiment of the present disclosure can be sloped or inclined from the second straight line SL2 and can pass through ends of rotated concave portions 141, and thus, the second tilt line TL2 can be a second end connection line or a second end extension line.

According to an embodiment of the present disclosure, when the plurality of concave portions 141 are arranged in a honeycomb structure, the second tilt line TL2 according to an embodiment of the present disclosure can be sloped or inclined from the second straight line SL2 and can pass through the center portion CP and a center of each of two sides facing each other in each of the plurality of concave portions 141. Furthermore, the second tilt line TL2 according to another embodiment of the present disclosure can be sloped or inclined from the second straight line SL2 and can pass through one of first to sixth vertexes of each of the plurality of concave portions 141. For example, an angle between the second tilt line TL2 and a side intersecting with the second tilt line TL2 among the first to sixth sides of each of the plurality of concave portions 141 can be 30 degrees or 90 degrees.

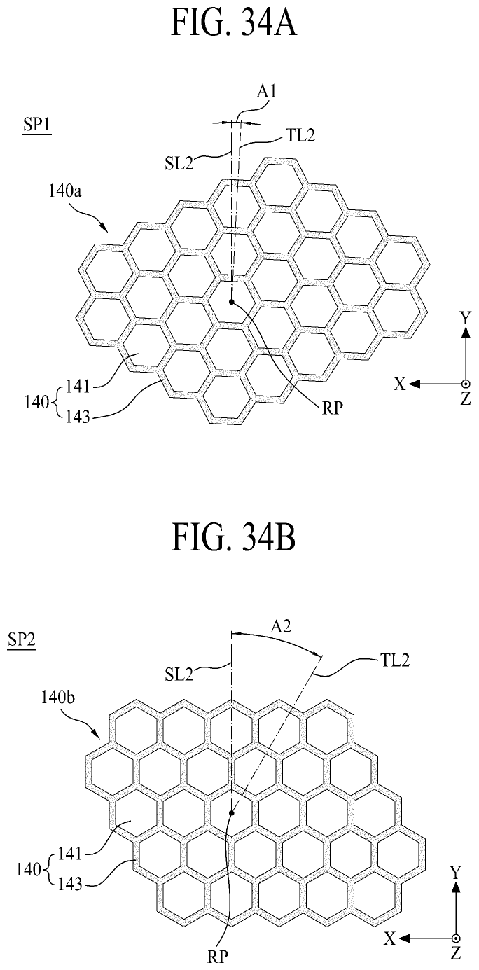

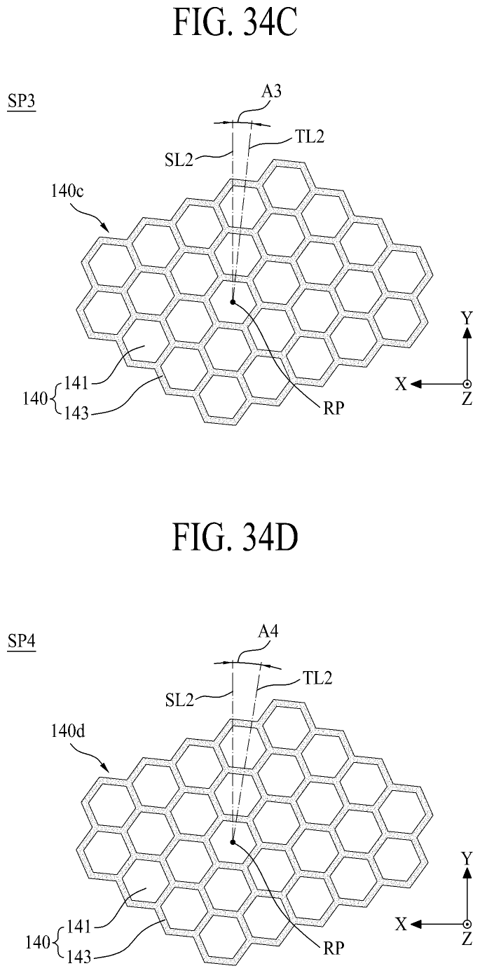

FIG. 34A is a diagram illustrating a rotation structure of a first light extraction pattern illustrated in FIG. 32. FIG. 34B is a diagram illustrating a rotation structure of a second light extraction pattern illustrated in FIG. 32. FIG. 34C is a diagram illustrating a rotation structure of a third light extraction pattern illustrated in FIG. 32. FIG. 34D is a diagram illustrating a rotation structure of a fourth light extraction pattern illustrated in FIG. 32.

Referring to FIG. 34A, a first light extraction pattern 140a at a first subpixel SP1 can be rotated by a rotation angle A1 of 3 degrees with respect to an arbitrary reference point RP. For example, a rotation angle A1 of the first light extraction pattern 140a can be an angle between a second straight line SL2 and a second tilt line TL2.

Referring to FIG. 34B, a second light extraction pattern 140b at a second subpixel SP2 can be rotated by a rotation angle A2 of 30 degrees with respect to an arbitrary reference point RP. For example, a rotation angle A2 of the second light extraction pattern 140b can be an angle between the second straight line SL2 and the second tilt line TL2.

Referring to FIG. 34C, a third light extraction pattern 140c at a third subpixel SP3 can be rotated by a rotation angle A3 of 6 degrees with respect to an arbitrary reference point RP. For example, a rotation angle A3 of the third light extraction pattern 140c can be an angle between the second straight line SL2 and the second tilt line TL2.

Referring to FIG. 34D, a fourth light extraction pattern 140d at a fourth subpixel SP4 can be rotated by a rotation angle A4 of 9 degrees with respect to an arbitrary reference point RP. For example, a rotation angle A4 of the fourth light extraction pattern 140d can be an angle between the second straight line SL2 and the second tilt line TL2.

As described above, according to another embodiment of the present disclosure, each of the first to fourth subpixels SP1, SP2, SP3, and SP4 can include the first to fourth light extraction patterns 140a, 140b, 140c, and 140d, the first light separation region LSR1, and the second light separation region LSR2 which are rotated by different rotation angles, and thus, the regularity of reflection light reflected by the first to fourth light extraction patterns 140a, 140b, 140c, and 140d can more decrease or the randomness of the reflection light can more increase, thereby more preventing or more minimizing the occurrence of rainbow Mura where reflected light is spread in a radial shape and/or circular ring Mura where reflected light is spread in a radial shape. Accordingly, a black visibility characteristic or a black color (or black rising) phenomenon caused by the reflection of external light can be more reduced in a non-driving or off state.

An organic light emitting display apparatus according to an embodiment of the present disclosure will be described below.

An organic light emitting display apparatus according to an embodiment of the present disclosure can comprise a plurality of pixels each including a plurality of color subpixels and a white subpixel each including an emission area on a substrate, a planarization layer including a light extraction pattern which is at the emission area of each of the plurality of color subpixels and the white subpixel and includes a plurality of concave portions and a convex portion, a light emitting device layer on the light extraction pattern, a color filter layer between the substrate and the light extraction pattern to overlap the emission area of each of the plurality of color subpixels, and a light separation portion between the substrate and the light extraction pattern to overlap the emission area of each of the plurality of color subpixels, the color filter layer can comprise a first filter region and a second filter region having different thicknesses at the light separation portion.

According to one or more embodiments of the present disclosure, the first filter region at each of the plurality of color subpixels can have different thicknesses, and the second filter region at each of the plurality of color subpixels can have different thicknesses.

According to one or more embodiments of the present disclosure, the organic light emitting display apparatus can further comprise a passivation layer between the color filter layer of each of the plurality of color subpixels and the substrate and between the light extraction pattern of the white subpixel and the substrate, the passivation layer can comprise a first surface adjacent to the substrate and a second surface opposite to the first surface, and each of the first filter region and the second filter region of the color filter layer can contact the second surface of the passivation layer.

According to one or more embodiments of the present disclosure, the light separation portion can comprise a first light separation region and a second light separation region configured between the substrate and the light extraction pattern to overlap the emission area of each of the plurality of color subpixels, the first filter region of the color filter layer can be configured at the first light separation region to have a first thickness, and the second filter region of the color filter layer can be configured at the second light separation region to have a second thickness which is thicker than the first thickness.

According to one or more embodiments of the present disclosure, the first light separation region and the second light separation region can be disposed along one or more directions of a first direction, a second direction intersecting with the first direction, and a diagonal direction between the first direction and the second direction.

According to one or more embodiments of the present disclosure, the organic light emitting display apparatus can further comprise a passivation layer between the color filter layer of each of the plurality of color subpixels and the substrate and between the light extraction pattern of the white subpixel and the substrate, the light separation portion can comprise the first light separation region and the second light separation region additionally configured between the substrate and the light extraction pattern to overlap the emission area of the white subpixel, and the passivation layer can be disposed at the first light separation region and is not disposed at the second light separation region.

According to one or more embodiments of the present disclosure, the first light separation region of each of the plurality of color subpixels can comprise the passivation layer and the first filter region of the color filter layer, the second light separation region of each of the plurality of color subpixels can comprise a region where the passivation layer is not disposed and the second filter region of the color filter layer, the first light separation region of the white subpixel can comprise the passivation layer, and the second light separation region of the white subpixel can comprise a region where the passivation layer is not disposed.

According to one or more embodiments of the present disclosure, the passivation layer disposed at the second light separation region of each of the plurality of color subpixels and the white subpixel can be different thicknesses.

According to one or more embodiments of the present disclosure, the first filter region at each of the plurality of color subpixels can have different thicknesses, and the second filter region at each of the plurality of color subpixels can have different thicknesses.

According to one or more embodiments of the present disclosure, the organic light emitting display apparatus can further comprise an insulation layer between the substrate and the passivation layer, the insulation layer can comprise a first insulation layer disposed at the second light separation region, the first insulation layer not being disposed at the first light separation region, and a second insulation layer covering the first insulation layer and a region where the first insulation layer is not disposed.

According to one or more embodiments of the present disclosure, the insulation layer and the passivation layer can have different refractive indexes.

According to one or more embodiments of the present disclosure, the first insulation layer and the second insulation layer can have a refractive index difference of 0.1 or more.

According to one or more embodiments of the present disclosure, the organic light emitting display apparatus can further comprise an insulation layer between the substrate and the passivation layer, the light separation portion can further comprise a plurality of first pattern regions and a plurality of second pattern regions parallel to each of the first light separation region and the second light separation region, and the insulation layer can comprise a first insulation layer disposed at the plurality of second pattern regions, the first insulation layer not being disposed at the plurality of first pattern regions, and a second insulation layer covering the first insulation layer and a region where the first insulation layer is not disposed.

According to one or more embodiments of the present disclosure, the first light separation region can comprise one or more first pattern regions of the plurality of first pattern regions and one or more second pattern regions of the plurality of second pattern regions, and the second light separation region can comprise one or more first pattern regions of the plurality of first pattern regions and one or more second pattern regions of the plurality of second pattern regions.

According to one or more embodiments of the present disclosure, the light separation portion can be additionally configured between the substrate and the light extraction pattern to overlap the emission area of the white subpixel, the light separation portion can comprise a plurality of first light separation regions, configured between the substrate and the light extraction pattern to overlap the emission area of each of the plurality of color subpixels and the white subpixel, and a plurality of second light separation regions between the plurality of first light separation regions, and in each of the plurality of color subpixels, the first filter region of the color filter layer can be disposed at the plurality of first light separation regions to have a first thickness, and the second filter region of the color filter layer is disposed at the plurality of second light separation regions to have a second thickness which is thicker than the first thickness.

According to one or more embodiments of the present disclosure, the organic light emitting display apparatus can further comprise a passivation layer between the color filter layer of each of the plurality of color subpixels and the substrate and between the light extraction pattern of the white subpixel and the substrate, the passivation layer can be disposed at the plurality of first light separation regions and may not be disposed at the plurality of second light separation regions.

According to one or more embodiments of the present disclosure, the organic light emitting display apparatus can further comprise an insulation layer between the substrate and the passivation layer, the light separation portion can comprise one or more first pattern regions and one or more second pattern regions intersecting with the plurality of first light separation regions and the plurality of second light separation regions, and the insulation layer can comprise a first insulation layer disposed at the one or more first pattern regions, the first insulation layer not being disposed at the one or more second pattern regions; and a second insulation layer covering the first insulation layer and a region where the first insulation layer is not disposed.

According to one or more embodiments of the present disclosure, the plurality of first light separation regions can be disposed in a lattice pattern shape.

According to one or more embodiments of the present disclosure, the organic light emitting display apparatus can further comprise an insulation layer between the substrate and the passivation layer, the insulation layer can comprise a first insulation layer disposed at the plurality of second pattern regions, the first insulation layer not being disposed at the plurality of first pattern regions; and a second insulation layer covering the first insulation layer and a region where the first insulation layer is not disposed.

According to one or more embodiments of the present disclosure, the light separation portion can be additionally configured between the substrate and the light extraction pattern to overlap the emission area of the white subpixel, the light separation portion can comprise a plurality of first light separation regions, configured between the substrate and the light extraction pattern to overlap the emission area of each of the plurality of color subpixels and the white subpixel, and a second light separation region between the plurality of first light separation regions, and in each of the plurality of color subpixels, the first filter region of the color filter layer can be disposed at the plurality of first light separation regions to have a first thickness, and the second filter region of the color filter layer can be disposed at the second light separation region to have a second thickness which is thicker than the first thickness.

According to one or more embodiments of the present disclosure, each of the plurality of first light separation regions can comprise a circular shape, an oval shape, a three or more-angled polygonal shape, or a same shape as a shape of the concave portion, or each of the plurality of first light separation regions can have a same size as a size of the concave portion, or can have a size which is smaller than a size of the concave portion.

According to one or more embodiments of the present disclosure, the organic light emitting display apparatus can further comprise a passivation layer between the color filter layer of each of the plurality of color subpixels and the substrate and between the light extraction pattern of the white subpixel and the substrate, the passivation layer can be disposed at the plurality of first light separation regions and may not be disposed at the plurality of second light separation regions.

According to one or more embodiments of the present disclosure, the organic light emitting display apparatus can further comprise an insulation layer between the substrate and the passivation layer, the light separation portion can comprise a plurality of first pattern regions disposed at the second light separation region and a second pattern region including a region between the plurality of first pattern regions, and the insulation layer can comprise a first insulation layer disposed at the plurality of first pattern regions, the first insulation layer not being disposed at the second pattern region; and a second insulation layer covering the first insulation layer and a region where the first insulation layer is not disposed.

According to one or more embodiments of the present disclosure, the emission area of each of the plurality of color subpixels and the white subpixel can comprise a plurality of division regions, the light separation portion can be configured at each of the plurality of division regions, and the color filter layer can comprise a first filter region and a second filter region having different thicknesses at the light separation portion of each of the plurality of division regions.

According to one or more embodiments of the present disclosure, the plurality of division regions can be disposed along one or more directions of a first direction, a second direction intersecting with the first direction, and a diagonal direction between the first direction and the second direction.

According to one or more embodiments of the present disclosure, each of the plurality of division regions can include a tetragonal shape or a triangular shape.

According to one or more embodiments of the present disclosure, the light separation portion can comprise one or more first light separation regions and one or more second light separation regions configured at each of the plurality of division regions.

According to one or more embodiments of the present disclosure, the organic light emitting display apparatus can further comprise a passivation layer between the color filter layer of each of the plurality of color subpixels and the substrate and between the light extraction pattern of the white subpixel and the substrate, the passivation layer can be disposed at the one or more first light separation regions and may not be disposed at the one or more second light separation regions.

According to one or more embodiments of the present disclosure, the organic light emitting display apparatus can further comprise an insulation layer between the substrate and the passivation layer, the insulation layer can comprise a first insulation layer disposed at the one or more second light separation regions, the first insulation layer not being disposed at the one or more first light separation regions; and a second insulation layer covering the first insulation layer and a region where the first insulation layer is not disposed.

According to one or more embodiments of the present disclosure, the light extraction patterns at each of the plurality of color subpixels and the white subpixel can have a structure which has rotated about a reference point within a corresponding emission area, and one or more of the light extraction patterns at each of the plurality of color subpixels and the white subpixel can have rotated by different angles.

According to one or more embodiments of the present disclosure, a rotation angle of the light extraction pattern at each of the plurality of color subpixels and the white subpixel can differ from each other by pixel units.

According to one or more embodiments of the present disclosure, each of the plurality of concave portions or the convex portion can have a planar structure having a hexagonal shape or a honeycomb shape, and a rotation angle of the light extraction pattern can be greater than 0 degrees and smaller than 60 degrees.

The organic light emitting display apparatus according to an embodiment of the present disclosure can be applied to various electronic apparatuses. For example, the organic light emitting display apparatus according to an embodiment of the present disclosure can be applied to mobile devices, video phones, smart watches, watch phones, wearable devices, foldable devices, rollable devices, bendable devices, flexible devices, curved devices, electronic organizers, electronic books, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, TVs, wall paper display apparatuses, signage apparatuses, game machines, notebook computers, monitors, cameras, camcorders, and home appliances, or the like.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the appended claims and their equivalents.

What is claimed is:

1. An organic light emitting display apparatus comprising:
a plurality of pixels on a substrate, each pixel including a plurality of color subpixels and a white subpixel, each sub-pixel including an emission area;
a planarization layer including a light extraction pattern, wherein the light extraction pattern is disposed at the emission area of each of the plurality of color subpixels and the white subpixel, and includes a plurality of concave portions and a convex portion;
a light emitting device layer on the light extraction pattern;
a color filter layer disposed between the substrate and the light extraction pattern to overlap the emission area of each of the plurality of color subpixels; and
a light separation portion disposed between the substrate and the light extraction pattern to overlap the emission area of each of the plurality of color subpixels,
wherein the color filter layer comprises a first filter region and a second filter region having different thicknesses at the light separation portion.

2. The organic light emitting display apparatus of claim 1, wherein:
the first filter region at each of the plurality of color subpixels has different thicknesses, and
the second filter region at each of the plurality of color subpixels has different thicknesses.

3. The organic light emitting display apparatus of claim 1, further comprising a passivation layer disposed between the color filter layer of each of the plurality of color subpixels and the substrate and between the light extraction pattern of the white subpixel and the substrate,
wherein the passivation layer comprises a first surface adjacent to the substrate and a second surface opposite to the first surface, and
wherein each of the first filter region and the second filter region of the color filter layer contacts the second surface of the passivation layer.

4. The organic light emitting display apparatus of claim 1, wherein:
the light separation portion comprises a first light separation region and a second light separation region disposed between the substrate and the light extraction pattern to overlap the emission area of each of the plurality of color subpixels,
the first filter region of the color filter layer is disposed at the first light separation region to have a first thickness, and
the second filter region of the color filter layer is disposed at the second light separation region to have a second thickness which is thicker than the first thickness.

5. The organic light emitting display apparatus of claim 4, wherein at least one of the first light separation region and the second light separation region is disposed along one or more directions among a first direction, a second direction intersecting with the first direction, and a diagonal direction extending between the first direction and the second direction.

6. The organic light emitting display apparatus of claim 4, further comprising a passivation layer disposed between the color filter layer of each of the plurality of color subpixels and the substrate and between the light extraction pattern of the white subpixel and the substrate,
wherein the light separation portion comprises the first light separation region and the second light separation region additionally disposed between the substrate and the light extraction pattern to overlap the emission area of the white subpixel, and
wherein the passivation layer is disposed at the first light separation region and is not disposed at the second light separation region.

7. The organic light emitting display apparatus of claim 6, wherein:
the first light separation region of each of the plurality of color subpixels comprises the passivation layer and the first filter region of the color filter layer,
the second light separation region of each of the plurality of color subpixels comprises a region where the passivation layer is not disposed and the second filter region of the color filter layer,
the first light separation region of the white subpixel comprises the passivation layer, and
the second light separation region of the white subpixel comprises a region where the passivation layer is not disposed.

8. The organic light emitting display apparatus of claim 6, wherein the passivation layer disposed at the second light separation region of each of the plurality of color subpixels and the white subpixel has different thicknesses.

9. The organic light emitting display apparatus of claim 8, wherein:
the first filter region at each of the plurality of color subpixels has different thicknesses, and
the second filter region at each of the plurality of color subpixels has different thicknesses.

10. The organic light emitting display apparatus of claim 6, further comprising an insulation layer disposed between the substrate and the passivation layer,
wherein the insulation layer comprises:
a first insulation layer disposed at the second light separation region, the first insulation layer not being disposed at the first light separation region; and
a second insulation layer covering the first insulation layer and a region where the first insulation layer is not disposed.

11. The organic light emitting display apparatus of claim 10, wherein the insulation layer and the passivation layer have different refractive indexes.

12. The organic light emitting display apparatus of claim 10, wherein the first insulation layer and the second insulation layer have a refractive index difference of about 0.1 or more.

13. The organic light emitting display apparatus of claim 6, further comprising an insulation layer disposed between the substrate and the passivation layer,
wherein the light separation portion further comprises a plurality of first pattern regions and a plurality of second pattern regions parallel to at least one of the first light separation region and the second light separation region, and
wherein the insulation layer comprises:
a first insulation layer disposed at the plurality of second pattern regions, the first insulation layer not being disposed at the plurality of first pattern regions; and
a second insulation layer covering the first insulation layer and a region where the first insulation layer is not disposed.

14. The organic light emitting display apparatus of claim 13, wherein:
the first light separation region comprises one or more first pattern regions among the plurality of first pattern regions and one or more second pattern regions among the plurality of second pattern regions, and
the second light separation region comprises one or more first pattern regions among the plurality of first pattern regions and one or more second pattern regions among the plurality of second pattern regions.

15. The organic light emitting display apparatus of claim 1, wherein:
the light separation portion is additionally disposed between the substrate and the light extraction pattern to overlap the emission area of the white subpixel,
the light separation portion comprises a plurality of first light separation regions disposed between the substrate and the light extraction pattern to overlap the emission area of each of the plurality of color subpixels and the white subpixel, and a plurality of second light separation regions disposed between the plurality of first light separation regions, and
in each of the plurality of color subpixels, the first filter region of the color filter layer is disposed at the plurality of first light separation regions to have a first thickness, and the second filter region of the color filter layer is disposed at the plurality of second light separation regions to have a second thickness which is thicker than the first thickness.

16. The organic light emitting display apparatus of claim 15, further comprising a passivation layer disposed between the color filter layer of each of the plurality of color subpixels and the substrate and between the light extraction pattern of the white subpixel and the substrate,
wherein the passivation layer is disposed at the plurality of first light separation regions and is not disposed at the plurality of second light separation regions.

17. The organic light emitting display apparatus of claim 16, further comprising an insulation layer disposed between the substrate and the passivation layer,
wherein the light separation portion comprises one or more first pattern regions and one or more second pattern regions intersecting with the plurality of first light separation regions and the plurality of second light separation regions, and
wherein the insulation layer comprises:
a first insulation layer disposed at the one or more first pattern regions, the first insulation layer not being disposed at the one or more second pattern regions; and
a second insulation layer covering the first insulation layer and a region where the first insulation layer is not disposed.

18. The organic light emitting display apparatus of claim 16, wherein the plurality of first light separation regions are disposed in a lattice pattern shape.

19. The organic light emitting display apparatus of claim 18, further comprising an insulation layer disposed between the substrate and the passivation layer,
wherein the insulation layer comprises:
a first insulation layer disposed at the plurality of second pattern regions, the first insulation layer not being disposed at the plurality of first pattern regions; and
a second insulation layer covering the first insulation layer and a region where the first insulation layer is not disposed.

20. The organic light emitting display apparatus of claim 1, wherein:
the light separation portion is additionally disposed between the substrate and the light extraction pattern to overlap the emission area of the white subpixel,
the light separation portion comprises a plurality of first light separation regions disposed between the substrate and the light extraction pattern to overlap the emission area of each of the plurality of color subpixels and the white subpixel, and a second light separation region disposed between the plurality of first light separation regions, and
in each of the plurality of color subpixels, the first filter region of the color filter layer is disposed at the plurality of first light separation regions to have a first thickness, and the second filter region of the color filter layer is disposed at the second light separation region to have a second thickness which is thicker than the first thickness.

21. The organic light emitting display apparatus of claim 20, wherein:
each of the plurality of first light separation regions comprises a circular shape, an oval shape, a three or more-angled polygonal shape, or a same shape as a shape of the concave portion, or
each of the plurality of first light separation regions has a same size as a size of the concave portion, or has a size which is smaller than a size of the concave portion.

22. The organic light emitting display apparatus of claim 21, further comprising a passivation layer disposed between the color filter layer of each of the plurality of color subpixels and the substrate and between the light extraction pattern of the white subpixel and the substrate,
wherein the passivation layer is disposed at the plurality of first light separation regions and is not disposed at the plurality of second light separation regions.

23. The organic light emitting display apparatus of claim 22, further comprising an insulation layer disposed between the substrate and the passivation layer,
wherein the light separation portion comprises a plurality of first pattern regions disposed at the second light separation region and a second pattern region including a region between the plurality of first pattern regions, and
wherein the insulation layer comprises:
a first insulation layer disposed at the plurality of first pattern regions, the first insulation layer not being disposed at the second pattern region; and
a second insulation layer covering the first insulation layer and a region where the first insulation layer is not disposed.

24. The organic light emitting display apparatus of claim 1, wherein:
the emission area of each of the plurality of color subpixels and the white subpixel comprises a plurality of division regions,
the light separation portion is disposed at each of the plurality of division regions, and
the color filter layer comprises a first filter region and a second filter region having different thicknesses at the light separation portion of each of the plurality of division regions.

25. The organic light emitting display apparatus of claim 24, wherein the plurality of division regions are disposed along one or more directions among a first direction, a second direction intersecting with the first direction, and a diagonal direction extending between the first direction and the second direction.

26. The organic light emitting display apparatus of claim 24, wherein each of the plurality of division regions includes a tetragonal shape or a triangular shape.

27. The organic light emitting display apparatus of claim 24, wherein the light separation portion comprises one or more first light separation regions and one or more second light separation regions disposed at each of the plurality of division regions.

28. The organic light emitting display apparatus of claim 27, further comprising a passivation layer disposed between the color filter layer of each of the plurality of color subpixels and the substrate and between the light extraction pattern of the white subpixel and the substrate,
wherein the passivation layer is disposed at the one or more first light separation regions and is not disposed at the one or more second light separation regions.

29. The organic light emitting display apparatus of claim 28, further comprising an insulation layer disposed between the substrate and the passivation layer,
wherein the insulation layer comprises:
a first insulation layer disposed at the one or more second light separation regions, the first insulation layer not being disposed at the one or more first light separation regions; and
a second insulation layer covering the first insulation layer and a region where the first insulation layer is not disposed.

30. The organic light emitting display apparatus of claim 1, wherein:
the light extraction patterns at each of the plurality of color subpixels and the white subpixel have a structure which is rotated about a reference point within a corresponding emission area, and
one or more of the light extraction patterns at each of the plurality of color subpixels and the white subpixel are rotated by different angles.

31. The organic light emitting display apparatus of claim 30, wherein a rotation angle of the light extraction pattern at each of the plurality of color subpixels and the white subpixel differs from each other by pixel units.

32. The organic light emitting display apparatus of claim 30, wherein:
each of the plurality of concave portions or the convex portion has a planar structure having a hexagonal shape or a honeycomb shape; and
a rotation angle of the light extraction pattern is greater than 0 degrees and smaller than 60 degrees.
